(19) United States
(12) Patent Application Publication
(10) Pub. No.: US 2019/0341246 A1
(43) Pub. Date: Nov. 7, 2019

(54) Chemical Liquid for Forming Water Repellent Protective Film

(71) Applicant: Central Glass Company, Limited, Ube-shi, Yamaguchi (JP)

(72) Inventors: Yuzo OKUMURA, Ube-shi, Yamaguchi (JP); Yuki FUKUI, Ube-shi, Yamaguchi (JP); Hiroki FUKAZAWA, Tsu-shi, Mie (JP); Soichi KUMON, Matsusaka-shi, Mie (JP)

(21) Appl. No.: 16/479,330

(22) PCT Filed: Jan. 15, 2018
(86) PCT No.: PCT/JP2018/000745

§ 371 Date: Jul. 19, 2019

(30) Foreign Application Priority Data
Feb. 20, 2017 (JP) 2017-028704
Dec. 22, 2017 (JP) 2017-245680

(51) Int. Cl. H01L 21/02; C09D 7/62; C09D 7/20; C09D 127/06

(52) U.S. Cl. CPC H01L 21/02057; C09D 127/06; C09D 7/20; C09D 7/62

(57) ABSTRACT

According to the present invention, there is provided a water-repellent protective film-forming chemical liquid containing: a first solvent being at least one kind selected from the group consisting of an ether solvent and a hydrocarbon solvent; a second solvent being a glycol ether; a silylation agent represented by the following general formula [1]; and a base represented by the following general formula [2] and/or the following general formula [3], wherein the concentration of the second solvent in the chemical liquid is 1 to 30 mass %, wherein the concentration of the silylation agent in the chemical liquid is 2 to 15 mass %, wherein the concentration of the base in the chemical liquid is 0.05 to 2 mass %, and wherein the mass ratio of the silylation agent to the base is 4.5 or greater.

(R¹)ₐ(H)_{b}Si(OCOR²)_{4-a-b} [1]

(R³)_{c}(H)_{d}Si(X)_{4-c-d} [2]

[(R⁴)ₑ(H)_{f}Si]₂NH [3]

### FIELD OF THE INVENTION

The present invention relates to a chemical liquid used, in the process of cleaning a wafer by the use of a cleaning machine whose liquid contact part contains a vinyl chloride resin, for forming a water-repellent protective film to prevent collapse of an uneven pattern on a surface of the wafer.

### BACKGROUND ART

There is a wafer cleaning machine of the type having a part (referred to as “liquid contact part”) which contains a vinyl chloride and with which a treatment liquid (also referred to as “surface treatment liquid”) for surface treatment of wafers comes into contact. In this type of wafer cleaning machine, it is required that the vinyl chloride resin is not deteriorated by the treatment liquid. Examples of the wafer cleaning machine with such a vinyl chloride resin-containing liquid contact part are those in which a part brought into contact with a treatment liquid within a cleaning treatment chamber is partially or wholly made of a vinyl chloride resin and those in which any other part brought into contact with a treatment liquid, such as a tank, pipe, connection member, nozzle or the like, is partially or wholly made of a vinyl chloride resin.

On the other hand, it is required that semiconductor devices for network applications and digital home appliances attain higher performance, higher functionality and lower power consumption. The fine processing of circuit patterns has accordingly been pursued. With the fine processing of circuit patterns, however, the occurrence of pattern collapses is becoming a problem. The manufacturing of the semiconductor device makes great use of a cleaning process to remove particles and metal impurities. Eventually, the cleaning process occupies 30 to 40% of the entire semiconductor manufacturing process. The pattern collapse is a phenomenon in which the pattern collapses due to the passage of a gas-liquid interface through the pattern after washing or rinsing in the cleaning process when the aspect ratio of the pattern becomes high with the fine patterning of the semiconductor device. The design of the pattern has to be changed in order to prevent pattern collapse. Further, the occurrence of pattern collapse leads to a deterioration in manufacturing yield. It is thus demanded to develop a technique for preventing pattern collapse in the cleaning process.

The formation of a water-repellent protective film on a surface of the pattern is known as an effective technique for preventing collapse of the pattern. This water repelling treatment needs to be performed without drying the surface of the pattern. The water-repellent protective film is hence formed by retaining a water-repellent protective film-forming chemical liquid as one kind of the aforementioned treatment liquid on the surface of the pattern.

Patent Document 1 discloses a surface treatment liquid for effectively preventing collapse of an inorganic pattern or resin pattern on a substrate, which contains a silylation agent and a silylation heterocyclic compound, and a surface treatment method using the surface treatment liquid.

The present applicant has disclosed in Patent Document 2 a water-repellent protective film-forming chemical liquid used, in the process of cleaning a wafer by means of a wafer cleaning machine whose liquid contact part contains a vinyl chloride resin, for forming a water-repellent protective film on an unevenly patterned surface of the wafer without causing deterioration of the vinyl chloride resin although the disclosed chemical liquid is different in composition from the surface treatment liquid of Patent Document 1. Also disclosed is a wafer cleaning method using the chemical liquid. More specifically, the water-repellent protective film-forming chemical liquid contains a monoalkoxysilane represented by (R)_{α}Si(H)_{3-α}(OR′), a sulfonic acid represented by R″—S(═O)₂OH and a diluent solvent, wherein the diluent solvent contains 80 to 100 mass % of an alcohol based on the total 100 mass % of the diluent solvent. Herein, R is each independently at least one group selected from monovalent hydrocarbon groups of 1 to 18 carbon atoms in which a part or all of hydrogen atoms may be substituted with fluorine; R′ is a monovalent hydrocarbon group in which a part or all of hydrogen atoms may be substituted with fluorine; a is an integer of 1 to 3; and R″ is each independently a group selected from the group consisting of a monovalent hydrocarbon group of 1 to 18 carbon atoms in which a part or all of hydrogen atoms may be substituted with fluorine and a hydroxy group.

### PRIOR ART DOCUMENTS

### Patent Documents

Patent Document 1: Japanese Laid-Open Patent Publication No. 2011-049468

Patent Document 2: Japanese Laid-Open Patent Publication No. 2016-066785

### SUMMARY OF THE INVENTION

### Problems to be Solved by the Invention

It is herein assumed that a wafer having on a surface thereof a fine uneven pattern which at least partially contains a silicon element is cleaned by means of a wafer cleaning machine whose liquid contact part contains a vinyl chloride resin. In the case where a surface treatment liquid disclosed in Example 1 or 19 of Patent Document 1 is used in this cleaning process, there occurs discoloring of the vinyl chloride resin. The occurrence of such discoloring becomes a cause of degradation of the vinyl chloride resin, which leads to a deterioration of the vinyl chloride resin. Further, some of surface treatment liquids disclosed in Patent Document 1 cause swelling of the vinyl chloride resin, or readily cause deposition of solid matter due to the mixing of a protic solvent such as water or alcohol into the treatment liquid. For these reasons, the surface treatment liquids are in need of improvements.

In view of the foregoing, it is an object of the present invention to provide a water-repellent protective film-forming chemical liquid (hereinafter sometimes simply referred to as “chemical liquid”) capable of, when used in the process of cleaning a wafer which has on a surface thereof a fine uneven pattern at least partially containing a silicon element (hereinafter sometimes simply referred to as “wafer”) by means of a wafer cleaning machine whose liquid contact part contains a vinyl chloride resin, preventing the above-mentioned pattern collapse problem and achieving, with good balance, suppression of swelling or discoloring of the vinyl chloride resin by the chemical liquid and suppression of solid matter deposition in the chemical liquid. It is also an object of the present invention to provide a method for cleaning a wafer with the use of the chemical liquid while preventing pattern collapse of the wafer.

### Means for Solving the Problems

According to the present invention, there is provided a water-repellent protective film-forming chemical liquid used, in a process of cleaning a wafer by means of a wafer cleaning machine, for forming a water-repellent protective film on a surface of the wafer, the wafer having on the surface thereof a fine uneven pattern which at least partially contains a silicon element, the wafer cleaning machine having a liquid contact part which contains a vinyl chloride resin, the water-repellent protective film-forming chemical liquid comprising:
(I) a first solvent being at least one kind selected from the group consisting of an ether solvent and a hydrocarbon solvent;
(II) a second solvent being a glycol ether;
(III) a silylation agent represented by the following general formula [1]; and
(IV) a base represented by the following general formula [2] and/or the following general formula [3],
wherein a concentration of the second solvent (II) in the chemical liquid is 1 to 30 mass % based on the total amount of the chemical liquid,
wherein a concentration of the silylation agent (III) in the chemical liquid is 2 to 15 mass % based on the total amount of the chemical liquid,
wherein a concentration of the base (IV) in the chemical liquid is 0.05 to 2 mass % based on the total amount of the chemical liquid, and
wherein a mass ratio of the silylation agent (III) to the base (IV) is 4.5 or greater,

(R¹)ₐ(H)_{b}Si(OCOR²)_{4-a-b} [1]

where R¹ is each independently selected from monovalent hydrocarbon groups of 1 to 18 carbon atoms in which a part or all of hydrogen atoms may be substituted with fluorine; R² is an alkyl group of 1 to 6 carbon atoms in which a part or all of hydrogen atoms are substituted with fluorine; a is an integer of 1 to 3; b is an integer of 0 to 2; and the sum of a and b is 1 to 3,

(R³)_{c}(H)_{d}Si(X)_{4-c-d} [2]

where R³ is each independently selected from monovalent hydrocarbon groups of 1 to 18 carbon atoms in which a part or all of hydrogen atoms may be substituted with fluorine; X is an monovalent organic group having a nitrogen atom bonded to silicon; c is an integer of 1 to 3; d is an integer of 0 to 2; the sum of c and d is 1 to 3,

[(R⁴)ₑ(H)_{f}Si]₂NH [3]

where R⁴ is each independently selected from monovalent hydrocarbon groups of 1 to 18 carbon atoms in which a part or all of hydrogen atoms may be substituted with fluorine; e is an integer of 1 to 3; f is an integer of 0 to 2; and the sum of e and f is 3.

The second solvent (II) is preferably a glycol ether represented by the following general formula [4]

R⁵O—(CₘH₂ₘO)ₙ—R⁶ [4]

where R⁵ and R⁶ are each independently selected from alkyl groups of 1 to 4 carbon atoms; m is an integer of 2 to 4; n is an integer of 1 to 4.

The ether solvent as the first solvent (I) is preferably an ether represented by the following general formula [5]

R⁷—O—R⁸ [5]

where R⁷ and R⁸ are each independently selected from hydrocarbon groups of 1 to 8 carbon atoms; and the total number of carbon atoms in one molecule of the ether is 4 to 16.

Further, the hydrocarbon solvent is preferably a hydrocarbon of 6 to 14 carbon atoms.

The silylation agent (III) is preferably a silylation agent represented by the following general formula [6]

R⁹Si(CH₃)₂—OCOCₚF₂ₚ₊₁ [6]

where R⁹ is a hydrogen atom, or an alkyl group of 1 to 12 carbon atoms in which a part or all of hydrogen atoms may be substituted with fluorine; and p is an integer of 1 to 6.

Preferably, X in the general formula [2] is a monovalent cyclic organic group having a nitrogen atom bonded to silicon.

The base (IV) is preferably a base represented by the following general formula [7] and/or the following general formula [8]

R¹⁰Si(CH₃)₂—Y [7]

where R¹⁰ is a hydrogen atom, or an alkyl group of 1 to 12 carbon atoms in which a part or all of hydrogen atoms may be substituted with fluorine; and Y is an imidazole group in which hydrogen may be substituted with methyl, or a pyrrolidyl group,

[R¹¹Si(CH₃)₂]₂NH [8]

where R¹¹ is each independently a hydrogen atom, or an alkyl group of 1 to 12 carbon atoms in which a part or all of hydrogen atoms may be substituted with fluorine.

It is preferable that the concentration of the second solvent (II) in the chemical liquid is 2 to 20 mass % based on the total amount of the chemical liquid.

It is preferable that the concentration of the base (IV) in the chemical liquid is 0.1 to 1.5 mass % based on the total amount of the chemical liquid.

The chemical liquid according to the present invention may preferably further comprise an amide compound represented by the following general formula [9]

(R¹²)_{g}(H)ₕSi[N(H)—C(═O)—R¹³]_{4-g-h} [9]

where R¹² is each independently selected from hydrocarbon groups of 1 to 18 carbon atoms in which a part or all of hydrogen atoms may be substituted with fluorine; R¹³ is an alkyl group of 1 to 6 carbon atoms in which a part or all of hydrogen atoms are substituted with fluorine; g is an integer of 1 to 3; his an integer of 0 to 2; and the sum of g and his 1 to 3.

There is also provided according to the present invention a method for cleaning a wafer, comprising: forming a water-repellent protective film by supplying the above water-repellent protective film-forming chemical liquid to a surface of the water and retaining the chemical liquid at least in recess portions of the surface of the wafer.

It is preferable to, after the formation of the water-repellent protective film, remove the water-repellent protective film-forming chemical liquid from the recess portions by drying. It is also preferable to, after the formation of the water-repellent protective film, replace the water-repellent protective film-forming chemical liquid in the recess portions with a cleaning liquid which is different from the water-repellent protective film-forming chemical liquid, and then, remove the cleaning liquid from the recess portions by drying.

After the drying, the water-repellent protective film may be removed by performing at least one treatment selected from the group consisting of heating treatment, light irradiation treatment, ozone exposure treatment, plasma irradiation treatment and corona discharge treatment on the surface of the wafer.

### Effects of the Invention

The water-repellent protective film-forming chemical liquid according to the present invention is capable of forming a water-repellent protective film (hereinafter sometimes simply referred to as “protective film”) on an unevenly patterned surface of the wafer while achieving, with good balance, suppression of swelling or discoloring of the vinyl chloride resin used in the liquid contact part of the wafer cleaning machine and suppression of deposition of solid matter in the chemical liquid. The protective film formed from the water-repellent protective film-forming chemical liquid according to the present invention has high water repellency to lower a capillary force on the fine uneven pattern surface of the wafer and thereby exert a pattern collapse prevention effect. The use of such a chemical liquid leads to an improvement in the cleaning process during the manufacturing of the wafer with the fine uneven pattern without causing a deterioration in throughput. Consequently, the method of manufacturing the wafer with the fine uneven pattern by using the water-repellent protective film-forming chemical liquid according to the present invention is high in productivity.

It is expected that the aspect ratio of wafer circuit patterns will become increasingly higher for high densification of semiconductor devices. The water-repellent protective film-forming chemical liquid according to the present invention is applicable to the cleaning of uneven patterns with e.g. an aspect ratio of 7 or higher and enables a cost reduction in the manufacturing of higher-density semiconductor devices. Furthermore, the water-repellent protective film-forming chemical liquid according to the present invention is usable in conventional machines without large changes to the liquid contact parts and the like and thus is applicable to the manufacturing of various semiconductor devices.

### BRIEF DESCRIPTION OF DRAWINGS

FIG. 1 is a schematic perspective view of a wafer 1 having on a surface thereof a fine uneven pattern 2.

FIG. 2 is a view showing a part of a-a′ cross section of FIG. 1.

FIG. 3 is a schematic view showing a state where a water repellent protective film forming chemical liquid 8 is retained in recess portions 4 of the pattern during cleaning process.

FIG. 4 is a schematic view showing a state where a liquid is retained in the recess portions 4 on which a protective film has been formed.

FIG. 5 is a plot of the contact angle retention rate after the surface treatment with respect to the amount of water added to the chemical liquid in each of Examples 21-1, 1-4 and 4-5.

FIG. 6 is a plot of the contact angle retention rate after the surface treatment with respect to the amount of water added to the chemical liquid in each of Examples 21-2, 9-1 and 9-6.

FIG. 7 is a plot of the contact angle retention rate after the surface treatment with respect to the amount of water added to the chemical liquid in each of Examples 21-3, 8-3 and 9-7.

### DETAILED DESCRIPTION OF EMBODIMENTS

1. Water-Repellent Protective Film-Forming Chemical Liquid

The water-repellent protective film-forming chemical liquid according to the present invention contains the following components:
(I) a first solvent being at least one kind selected from the group consisting of an ether solvent and a hydrocarbon solvent;
(II) a second solvent being a glycol ether;
(III) a silylation agent represented by the above general formula [1]; and
(IV) a base represented by the above general formula [2] and/or the above general formula [3].

(I) First Solvent

The first solvent is at least one kind selected from the group consisting of an ether solvent and a hydrocarbon solvent. The use of the first solvent allows dissolution of the silylation agent and the base without causing swelling of vinyl chloride resin.

Specific examples of the hydrocarbon solvent are n-hexane, n-heptane, n-octane, n-nonane, n-decane, n-undecane, n-dodecane, n-tetradecane, n-hexadecane, n-octadecane, n-eicosane, branched hydrocarbons with the corresponding carbon numbers, cyclohexane, methylcyclohexane, decalin, benzene, toluene, (ortho-, meta- or para-) xylene, (orth-, meta- or para-) diethylbenzene, and the like. The smaller the carbon number of the hydrocarbon, the higher the volatility of the hydrocarbon, the lower the flash point of the hydrocarbon. The hydrocarbon solvent with too small carbon number is thus not preferable in terms of the safety and ease of liquid preparation. On the other hand, the greater the carbon number of the hydrocarbon, the higher the viscosity of the hydrocarbon. Thus, the hydrocarbon solvent with too great carbon number is also not preferable in terms of the ease of handling. For these reasons, the hydrocarbon solvent is preferably of 6 to 14 carbon atoms. More preferably, the hydrocarbon solvent is a saturated hydrocarbon of 8 to 12 carbon atoms. Particularly preferred are: n-octane; n-nonane; n-decane; n-undecane; n-dodecane; branched hydrocarbons with the corresponding carbon numbers, such as isododecane; cyclohexane; methylcyclohexane; and decalin. These hydrocarbons may have a substituent and may have a branched structure.

Similarly, the ether solvent with too small carbon number is not preferable in terms of the safety; and the ether solvent with too great carbon number is not preferable in terms of the ease of handling. For these reasons, the ether solvent is preferably an ether represented by the above general formula [5]. Specific examples of the ether solvent are: di-n-propyl ether; ethyl n-butyl ether; di-n-butyl ether; ethyl n-amyl ether; di-n-amyl ether; ethyl n-hexyl ether; di-n-hexyl ether; di-n-octyl ether; branched hydrocarbon-containing ethers with the corresponding carbon numbers, such as diisoamyl ether; methyl cyclopentyl ether; diphenyl ether; and the like. In terms of the oxidation resistance, ethyl t-butyl ether and methyl cyclopentyl ether are preferred. Further, di-n-butyl ether, di-n-amyl ether, diisoamyl ether, di-n-hexyl ether and di-n-octyl ether are preferred in terms of the ease of liquid preparation and high flash point.

(II) Second Solvent

The second solvent is a glycol ether. The use of the second solvent suppresses deposition of solid matter in the chemical liquid caused due to the mixing of water from the air during long-term storage of the chemical liquid in a container or due to the mixing of a protic solvent such as water or alcohol into the chemical liquid during surface treatment with the chemical liquid.

The glycol ether is preferably a glycol ether represented by the above general formula [4]. Specific examples of the glycol ether are ethylene glycol dimethyl ether, ethylene glycol diethyl ether, ethylene glycol dibutyl ether, diethylene glycol dimethyl ether, diethylene glycol ethyl methyl ether, diethylene glycol diethyl ether, diethylene glycol butyl methyl ether, diethylene glycol dibutyl ether, triethylene glycol dimethyl ether, triethylene glycol diethyl ether, triethylene glycol dibutyl ether, triethylene glycol butyl methyl ether, tetraethylene glycol dimethyl ether, tetraethylene glycol diethyl ether, tetraethylene glycol dibutyl ether, propylene glycol dimethyl ether, propylene glycol diethyl ether, propylene glycol dibutyl ether, dipropylene glycol dimethyl ether, dipropylene glycol methyl propyl ether, dipropylene glycol diethyl ether, dipropylene glycol dibutyl ether, tripropylene glycol dimethyl ether, tripropylene glycol diethyl ether, tripropylene glycol dibutyl ether, tetrapropylene glycol dimethyl ether and butylene glycol dimethyl ether. From the viewpoint of suppressing deposition of solid matter and in terms of the environmental load, particularly preferred are propylene glycol dimethyl ether, propylene glycol diethyl ether, propylene glycol dibutyl ether, dipropylene glycol dimethyl ether, dipropylene glycol methyl propyl ether, dipropylene glycol diethyl ether, dipropylene glycol dibutyl ether, tripropylene glycol dimethyl ether and tripropylene glycol diethyl ether.

It is important that the concentration of the second solvent (II) in the chemical liquid is 1 to 30 mass % based on the total amount of the chemical liquid. When the concentration of the second solvent is less than 1 mass %, it is likely that deposition of solid matter will occur due to the mixing of a protic solvent such as water or alcohol into the chemical liquid during preparation or replacement of the chemical liquid. When the concentration of the second solvent exceeds 30 mass %, the vinyl chloride resin is significantly swollen by contact with the chemical liquid. The concentration of the second solvent is preferably 2 to 20 mass %, more preferably 3 to 15 mass %, from the viewpoint of suppressing swelling of vinyl chloride resin and deposition of solid matter.

The chemical liquid according to the present invention may contain an organic solvent other than the first and second solvents. From the viewpoint of suppressing swelling or discoloring of vinyl chloride resin and deposition of solid matter and/or in terms of the water repellency imparting effect, the other solvent is preferably contained in an amount of less than 5 mass % based on the total 100 mass % of the water-repellent protective film-forming chemical liquid. The amount of the other solvent contained is preferably less than 2 mass %, more preferably less than 1 mass %.

Examples of the organic solvent other than the first and second solvents are esters, ketones, halogen-containing solvents, carbonate solvents and polyhydric alcohol derivatives having acetate groups but no OH groups.

(III) Silylation Agent

In the above general formula [1], R¹ is a water-repellent functional group. A water-repellent protective film is formed on a surface of a wafer by reacting —OCOR² group in the above general formula [1] with a silanol group on the wafer surface and fixing the water-repellent functional group on the wafer surface. When the silylation agent is used in combination with the base represented by the above general formula [2] and/or the above general formula [3], it is possible for the chemical liquid to exert a water repellency imparting effect by rapid reaction of the silylation agent and the wafer surface.

Preferably, R¹ is an alkyl group in which a part or all of hydrogen atoms may be substituted with fluorine. More preferably, R¹ is a linear alkyl group so that, when the protective film is formed on the unevenly patterned surface, higher water repellency and lower wettability are imparted to the patterned surface.

Specific examples of the silylation agent represented by the general formula [1] are: trifluoroacetoxysilane such as CH₃Si(OCOCF₃)₃, C₂H₅Si(OCOCF₃)₃, C₃H₇Si(OCOCF₃)₃, C₄H₉Si(OCOCF₃)₃, C₅H₁₁Si(OCOCF₃)₃, C₆H₁₃Si(OCOCF₃)₃, C₇H₁₅Si(OCOCF₃)₃, C₈H₁₇Si(OCOCF₃)₃, C₉H₁₉Si(OCOCF₃)₃, C₁₀H₂₁Si(OCOCF₃)₃, C₁₁H₂₃Si(OCOCF₃)₃, C₁₂H₂₅Si(OCOCF₃)₃, C₁₃H₂₇Si(OCOCF₃)₃, C₁₄H₂₉Si(OCOCF₃)₃, C₁₅H₃₁Si(OCOCF₃)₃, C₁₆H₃₃Si(OCOCF₃)₃, C₁₇H₃₅Si(OCOCF₃)₃, C₁₈H₃₇Si(OCOCF₃)₃, (CH₃)₂Si(OCOCF₃)₂, C₂H₅Si(CH₃)(OCOCF₃)₂, (C₂H₅)₂Si(OCOCF₃)₂, C₃H₇Si(CH₃)(OCOCF₃)₂, (C₃H₇)₂Si(OCOCF₃)₂, C₄H₉Si(CH₃)(OCOCF₃)₂, (C₄H₉)₂Si(OCOCF₃)₂, C₅H₁₁Si(CH₃)(OCOCF₃)₂, C₆H₁₃Si(CH₃)(OCOCF₃)₂, C₇H₁₅Si(CH₃)(OCOCF₃)₂, C₈H₁₇Si(CH₃)(OCOCF₃)₂, C₉H₁₉Si(CH₃)(OCOCF₃)₂, C₁₀H₂₁Si(CH₃)(OCOCF₃)₂, C₁₁H₂₃Si(CH₃)(OCOCF₃)₂, C₁₂H₂₅Si(CH₃)(OCOCF₃)₂, C₁₃H₂₇Si(CH₃)(OCOCF₃)₂, C₁₄H₂₉Si(CH₃)(OCOCF₃)₂, C₁₅H₃₁Si(CH₃)(OCOCF₃)₂, C₁₆H₃₃Si(CH₃)(OCOCF₃)₂, C₁₇H₃₅Si(CH₃)(OCOCF₃)₂, C₁₈H₃₇Si(CH₃)(OCOCF₃)₂, (CH₃)₃SiOCOCF₃, C₂H₅Si(CH₃)₂OCOCF₃, (C₂H₅)₂Si(CH₃)OCOCF₃, (C₂H₅)₃SiOCOCF₃, C₃H₇Si(CH₃)₂OCOCF₃, (C₃H₇)₂Si(CH₃)OCOCF₃, (C₃H₇)₃SiOCOCF₃, C₄H₉Si(CH₃)₂OCOCF₃, (C₄H₉)₃SiOCOCF₃, C₅H₁₁Si(CH₃)₂OCOCF₃, C₆H₁₃Si(CH₃)₂OCOCF₃, C₇H₁₅Si(CH₃)₂OCOCF₃, C₈H₁₇Si(CH₃)₂OCOCF₃, C₉H₁₉Si(CH₃)₂OCOCF₃, C₁₀H₂₁Si(CH₃)₂OCOCF₃, C₁₁H₂₃Si(CH₃)₂OCOCF₃, C₁₂H₂₅Si(CH₃)₂OCOCF₃, C₁₃H₂₇Si(CH₃)₂OCOCF₃, C₁₄H₂₉Si(CH₃)₂OCOCF₃, C₁₅H₃₁Si(CH₃)₂OCOCF₃, C₁₆H₃₃Si(CH₃)₂OCOCF₃, C₁₇H₃₅Si(CH₃)₂OCOCF₃, C₁₈H₃₇Si(CH₃)₂OCOCF₃, (CH₃)₂Si(H)OCOCF₃, CH₃Si(H)₂OCOCF₃, (C₂H₅)₂Si(H)OCOCF₃, C₂H₅Si(H)₂OCOCF₃, C₂H₅Si(CH₃)(H)OCOCF₃, (C₃H₇)₂Si(H)OCOCF₃, C₃H₇Si(H)₂OCOCF₃, CF₃CH₂CH₂Si(OCOCF₃)₃, C₂F₅CH₂CH₂Si(OCOCF₃)₃, C₃F₇CH₂CH₂Si(OCOCF₃)₃, C₄F₉CH₂CH₂Si(OCOCF₃)₃, C₅F₁₁CH₂CH₂Si(OCOCF₃)₃, C₆F₁₃CH₂CH₂Si(OCOCF₃)₃, C₇F₁₅CH₂CH₂Si(OCOCF₃)₃, C₈F₁₇CH₂CH₂Si(OCOCF₃)₃, CF₃CH₂CH₂Si(CH₃)(OCOCF₃)₂, C₂F₅CH₂CH₂Si(CH₃)(OCOCF₃)₂, C₃F₇CH₂CH₂Si(CH₃)(OCOCF₃)₂, C₄F₉CH₂CH₂Si(CH₃)(OCOCF₃)₂, C₅F₁₁CH₂CH₂Si(CH₃)(OCOCF₃)₂, C₆F₁₃CH₂CH₂Si(CH₃)(OCOCF₃)₂, C₇F₁₅CH₂CH₂Si(CH₃)(OCOCF₃)₂, C₈F₁₇CH₂CH₂Si(CH₃)(OCOCF₃)₂, CF₃CH₂CH₂Si(CH₃)₂OCOCF₃, C₂F₅CH₂CH₂Si(CH₃)₂OCOCF₃, C₃F₇CH₂CH₂Si(CH₃)₂OCOCF₃, C₄F₉CH₂CH₂Si(CH₃)₂OCOCF₃, C₅F₁₁CH₂CH₂Si(CH₃)₂OCOCF₃, C₆F₁₃CH₂CH₂Si(CH₃)₂OCOCF₃, C₇F₁₅CH₂CH₂Si(CH₃)₂OCOCF₃, C₈F₁₇CH₂CH₂Si(CH₃)₂OCOCF₃, CF₃CH₂CH₂Si(CH₃)(H)OCOCF₃; and those obtained by replacing —OCOCF₃ group of the above trifluoroacetoxysilane with —OCOR² group other than —OCOCF₃ group (where R² is an alkyl group of 1 to 6 carbon atoms in which a part or all of hydrogen atoms are substituted with fluorine).

In terms of the water repellency imparting effect, R² in —OCOR² group is preferably an alkyl group in which all of hydrogen atoms are substituted with fluorine. The alkyl group is preferably of 1 to 4 carbon atoms, more preferably 1 carbon atom.

The number of —OCOR² groups as expressed by 4-a-b in the general formula [1] is preferably 1 so that it is possible to uniformly form the protective film.

Further, b in the general formula [1] is preferably 0 so that it is possible to easily maintain water repellency in the after-mentioned cleaning step after the formation of the protective film.

The combination of two CH₃ groups and one linear alkyl group is preferred as le so that it is possible to uniformly form the protective film. The combination of three CH₃ groups is particularly preferred as R¹.

The silylation agent represented by the general formula [1] may be produced by reaction, for example, by reaction of a silicon compound represented by the following general formula [10] with a corresponding fluorine-containing carboxylic acid or fluorine-containing carboxylic acid anhydride.

(R¹)ₐ(H)_{b}Si(Z)_{4-a-b} [10]

In the general formula [10], R¹, a and b have the same meanings as in the general formula [1]; and Z is a monovalent organic group having a nitrogen atom bonded to silicon.

The silicon compound represented by the general formula [10] is preferably used in an amount of 0.8 to 1.5 molar times, more preferably 0.9 to 1.3 molar times, still more preferably 0.95 to 1.1 molar times, that of the fluorine-containing carboxylic acid or fluorine-containing carboxylic acid anhydride. The protective film-forming chemical liquid according to the present invention may be obtained by adding an excessive amount of the above silicon compound to the corresponding fluorine-containing carboxylic acid or fluorine-containing carboxylic acid anhydride so as to form the silylation agent represented by the general formula [1] through the reaction of the silicon compound with the carboxylic acid or carboxylic acid anhydride and allow the excess of the silicon compound left unconsumed by the reaction to make, as the base (IV), a contribution to the formation of the protective film. In this case, the amount of the above silicon compound used is preferably 1.01 to 1.5 molar times, more preferably 1.02 to 1.3 molar times, still more preferably 1.03 to 1.1 molar times, that of the fluorine-containing carboxylic acid or fluorine-containing carboxylic acid anhydride.

As long as the silylation agent represented by the general formula [1] is obtained, there can be utilized any reaction other than the reaction of the above silicon compound with the corresponding fluorine-containing carboxylic acid or fluorine-containing carboxylic acid anhydride.

The Z group in the general formula [10] may contain silicon, sulfur, halogen etc.

in addition to hydrogen, carbon, nitrogen and oxygen. Specific examples of the Z group are: isocyanate; amino; dialkylamino; isothiocyanate; azide; acetamide; —N(CH₃)COCH₃; —N(CH₃)COCF₃; —N═C(CH₃)OSi(CH₃)₃; —N═C(CF₃)OSi(CH₃)₃; —NHCO—OSi(CH₃)₃; —NH—CO—NH—Si(CH₃)₃; imidazole in which any of hydrogen atoms may be substituted with methyl; oxazolidinone; morpholine; pyrrolidyl; —NH—CO—Si(CH₃)₃; —NH—Si(H)ₛ(R¹)ₜ (where R¹ is a monovalent hydrocarbon group of 1 to 18 carbon atoms in which a part or all of hydrogen atoms may be substituted with fluorine; s is an integer of 0 to 2; t is an integer of 1 to 3; and the sum of s and t is 3); and the like.

Among others, the silicon compound represented by the general formula [10] is preferably a disilazane. As the Z group, —NH—Si(CH₃)₃, —NH—Si(CH₃)₂(H), —NH—Si(CH₃)₂(C₄H₉), —NH—Si(CH₃)₂(C₆H₁₃), —NH—Si(CH₃)₂(C₈H₁₇) and —NH—Si(CH₃)₂(C₁₀H₂₁) are preferred. More preferred are —NH—Si(CH₃)₃, —NH—Si(CH₃)₂(C₄H₉), —NH—Si(CH₃)₂(C₆H₁₃) and —NH—Si(CH₃)₂(C₈H₁₇). Particularly preferred is —NH—Si(CH₃)₃.

In the case where the silylation agent represented by the general formula [1] is produced by the above reaction, a perfluorocarboxylic acid or perfluorocarboxylic acid anhydride is preferred as the corresponding fluorine-containing carboxylic acid or fluorine-containing carboxylic acid anhydride in terms of the water repellency imparting effect. Among others, a perfluorocarboxylic acid anhydride is particularly preferred.

In terms of the storage stability of the chemical liquid, the silylation agent represented by the general formula [1] is preferably a compound obtained by reaction of a disilazane with a perfluorocarboxylic acid anhydride.

For example, when hexamethyldisilazane as the silicon compound and trifluoroacetic anhydride as the fluorine-containing carboxylic acid anhydride are mixed together, the trifluoroacetic anhydride immediately reacts with the hexamethyldisilazane to form trimethylsilyl trifluoroacetate as one kind of the silylation agent represented by the general formula [1].

When tetramethyldisilazane as the silicon compound and trifluoroacetic anhydride as the fluorine-containing carboxylic acid anhydride are mixed together, the trifluoroacetic anhydride immediately reacts with the tetramethyldisilazane to form dimethylsilyl trifluoroacetate as one kind of the silylation agent represented by the general formula [1].

When 1,3-dibutyltetramethyldisilazane as the silicon compound and trifluoroacetic anhydride as the fluorine-containing carboxylic acid anhydride are mixed together, the trifluoroacetic anhydride immediately reacts with the 1,3-dibutyltetramethyldisilazane to form butyldimethylsilyl trifluoroacetate as one kind of the silylation agent represented by the general formula [1].

When 1,3-dioctyltetramethyldisilazane as the silicon compound and trifluoroacetic anhydride as the fluorine-containing carboxylic acid anhydride are mixed together, the trifluoroacetic anhydride immediately reacts with the 1,3-dioctyltetramethyldisilazane to form octyldimethylsilyl trifluoroacetate as one kind of the silylation agent represented by the general formula [1].

When octyldimethyl(dimethylamino)silane as the silicon compound and trifluoroacetic anhydride as the fluorine-containing carboxylic acid anhydride are mixed together, the trifluoroacetic anhydride immediately reacts with the octyldimethyl(dimethylamino)silane to form octyldimethylsilyl trifluoroacetate as one kind of the silylation agent represented by the general formula [1].

In addition to the silylation agent represented by the general formula [1], a silane compound may be obtained as a by-product of the reaction and contained in the water-repellent protective film-forming chemical liquid according to the present invention. The silane compound may form a part of the protective film.

It is important that the concentration of the silylation agent (III) in the chemical liquid is 2 to 15 mass % based on the total amount of the chemical liquid. When the concentration of the silylation agent is less than 2 mass %, the concentration of the base (IV) becomes inevitably low by satisfaction of the (III)/(IV) mass ratio of 4.5 or greater so that the chemical liquid cannot exert a sufficient water repellency imparting effect. When the concentration of the silylation agent exceeds 15 mass %, the flash point of the chemical liquid becomes high. The use of such a chemical liquid is not favorable in terms of the safety. The concentration of the silylation agent is preferably 3 to 12 mass %, more preferably 4 to 11 mass %.

(IV) Base

The base represented by the above general formula [2] and/or the above general formula [3] serves to promote reaction of —OCOR² group of the silylation agent represented by the general formula [1] with a silanol group of the wafer surface. The base itself may form a part of the protective film.

Specific examples of the base represented by the general formula [2] are: aminosilane such as CH₃Si(NH₂)₃, C₂H₅Si(NH₂)₃, C₃H₇Si(NH₂)₃, C₄H₉Si(NH₂)₃, C₅H₁₁Si(NH₂)₃, C₆H₁₃Si(NH₂)₃, C₇H₁₅Si(NH₂)₃, C₈H₁₇Si(NH₂)₃, C₉H₁₉Si(NH₂)₃, C₁₀H₂₁Si(NH₂)₃, C₁₁H₂₃Si(NH₂)₃, C₁₂H₂₅Si(NH₂)₃, C₁₃H₂₇Si(NH₂)₃, C₁₄H₂₉Si(NH₂)₃, C₁₅H₃₁Si(NH₂)₃, C₁₆H₃₃Si(NH₂)₃, C₁₇H₃₅Si(NH₂)₃, C₁₈H₃₇Si(NH₂)₃, (CH₃)₂Si(NH₂)₂, C₂H₅Si(CH₃)(NH₂)₂, (C₂H₅)₂Si(NH₂)₂, C₃H₇Si(CH₃)(NH₂)₂, (C₃H₇)₂Si(NH₂)₂, C₄H₉Si(CH₃)(NH₂)₂, (C₄H₉)₂Si(NH₂)₂, C₅H₁₁Si(CH₃)(NH₂)₂, C₆H₁₃Si(CH₃)(NH₂)₂, C₇H₁₅Si(CH₃)(NH₂)₂, C₈H₁₇Si(CH₃)(NH₂)₂, C₉H₁₉Si(CH₃)(NH₂)₂, C₁₀H₂₁Si(CH₃)(NH₂)₂, C₁₁H₂₃Si(CH₃)(NH₂)₂, C₁₂H₂₅Si(CH₃)(NH₂)₂, C₁₃H₂₇Si(CH₃)(NH₂)₂, C₁₄H₂₉Si(CH₃)(NH₂)₂, C₁₅H₃₁Si(CH₃)(NH₂)₂, C₁₆H₃₃Si(CH₃)(NH₂)₂, C₁₇H₃₅Si(CH₃)(NH₂)₂, C₁₈H₃₇Si(CH₃)(NH₂)₂, (CH₃)₃SiNH₂, C₂H₅Si(CH₃)₂NH₂, (C₂H₅)₂Si(CH₃)NH₂, (C₂H₅)₃SiNH₂, C₃H₇Si(CH₃)₂NH₂, (C₃H₇)₂Si(CH₃)NH₂, (C₃H₇)₃SiNH₂, C₄H₉Si(CH₃)₂NH₂, (C₄H₉)₃SiNH₂, C₅H₁₁Si(CH₃)₂NH₂, C₆H₁₃Si(CH₃)₂NH₂, C₇H₁₅Si(CH₃)₂NH₂, C₈H₁₇Si(CH₃)₂NH₂, C₉H₁₉Si(CH₃)₂NH₂, C₁₀H₂₁Si(CH₃)₂NH₂, C₁₁H₂₃Si(CH₃)₂NH₂, C₁₂H₂₅Si(CH₃)₂NH₂, C₁₃H₂₇Si(CH₃)₂NH₂, C₁₄H₂₉Si(CH₃)₂NH₂, C₁₅H₃₁Si(CH₃)₂NH₂, C₁₆H₃₃Si(CH₃)₂NH₂, C₁₇H₃₅Si(CH₃)₂NH₂, C₁₈H₃₇Si(CH₃)₂NH₂, (CH₃)₂Si(H)NH₂, CH₃Si(H)₂NH₂, (C₂H₅)₂Si(H)NH₂, C₂H₅Si(H)₂NH₂, C₂H₅Si(CH₃)(H)NH₂, (C₃H₇)₂Si(H)NH₂, C₃H₇Si(H)₂NH₂, CF₃CH₂CH₂Si(NH₂)₃, C₂F₅CH₂CH₂Si(NH₂)₃, C₃F₇CH₂CH₂Si(NH₂)₃, C₄F₉CH₂CH₂Si(NH₂)₃, C₅F₁₁CH₂CH₂Si(NH₂)₃, C₆F₁₃CH₂CH₂Si(NH₂)₃, C₇F₁₅CH₂CH₂Si(NH₂)₃, C₈F₁₇CH₂CH₂Si(NH₂)₃, CF₃CH₂CH₂Si(CH₃)(NH₂)₂, C₂F₅CH₂CH₂Si(CH₃)(NH₂)₂, C₃F₇CH₂CH₂Si(CH₃)(NH₂)₂, C₄F₉CH₂CH₂Si(CH₃)(NH₂)₂, C₅F₁₁CH₂CH₂Si(CH₃)(NH₂)₂, C₆F₁₃CH₂CH₂Si(CH₃)(NH₂)₂, C₇F₁₅CH₂CH₂Si(CH₃)(NH₂)₂, C₈F₁₇CH₂CH₂Si(CH₃)(NH₂)₂, CF₃CH₂CH₂Si(CH₃)₂NH₂, C₂F₅CH₂CH₂Si(CH₃)₂NH₂, C₃F₇CH₂CH₂Si(CH₃)₂NH₂, C₄F₉CH₂CH₂Si(CH₃)₂NH₂, C₅F₁₁CH₂CH₂Si(CH₃)₂NH₂, C₆F₁₃CH₂CH₂Si(CH₃)₂NH₂, C₇F₁₅CH₂CH₂Si(CH₃)₂NH₂, C₈F₁₇CH₂CH₂Si(CH₃)₂NH₂, CF₃CH₂CH₂Si(CH₃)(H)NH₂; those obtained by replacing —NH₂ group of the above aminosilane with an isocyanate group, monoalkylamino group, dialkylamino group, isothiocyanate group, azide group, acetamide group, —N(CH₃)COCH₃ group, —N(CH₃)COCF₃, —N═C(CH₃)OSi(CH₃)₃, —N═C(CF₃)OSi(CH₃)₃, —NHCO—OSi(CH₃)₃, —NH—CO—NH—Si(CH₃)₃, —NH—CO—Si(CH₃)₃, imidazole group in which any of hydrogen atoms may be substituted with methyl, oxazolidinone group, morpholine group, pyrrolidyl group etc. In terms of good balance between water repellency imparting effect and suppression of solid matter deposition in the chemical liquid, preferred are those with a monovalent cyclic organic group having a nitrogen atom bonded to silicon. Particularly preferred are those having an imidazole group in which any of hydrogen atoms may be substituted with methyl or a pyrrolidyl group.

Specific examples of the base represented by the general formula [3] are [(CH₃)₃Si]₂NH, [(CH₃)₂Si(H)]₂NH, [C₂H₅Si(CH₃)₂]₂NH, [(C₂H₅)₂Si(CH₃)]₂NH, [(C₂H₅)₃Si]₂NH, [C₃H₇Si(CH₃)₂]₂NH, [(C₃H₇)₂Si(CH₃)]₂NH, [(C₃H₇)₃Si]₂NH, [C₄H₉(CH₃)₂Si]₂NH, [C₅H₁₁(CH₃)₂Si]₂NH, [C₆H₁₃(CH₃)₂Si]₂NH, [C₇H₁₅(CH₃)₂Si]₂NH, [C₈H₁₇(CH₃)₂Si]₂NH, [C₉H₁₉(CH₃)₂Si]₂NH, [C₁₀H₂₁(CH₃)₂Si]₂NH, [C₁₁H₂₃(CH₃)₂Si]₂NH, [C₁₂H₂₅(CH₃)₂Si]₂NH, [C₁₃H₂₇(CH₃)₂Si]₂NH, [C₁₄H₂₉(CH₃)₂Si]₂NH, [C₁₅H₃₁(CH₃)₂Si]₂NH, [C₁₆H₃₃(CH₃)₂Si]₂NH, [C₁₇H₃₅(CH₃)₂Si]₂NH, [C₁₈H₃₇(CH₃)₂Si]₂NH, [CF₃C₂H₄(CH₃)₂Si]₂NH, [C₂F₅C₂H₄(CH₃)₂Si]₂NH, [C₄F₉C₂H₄(CH₃)₂Si]₂NH, [C₆F₁₃C₂H₄(CH₃)₂Si]₂NH, [C₈F₁₇C₂H₄(CH₃)₂Si]₂NH, [C₃H₇(C₂H₅)₂Si]₂NH, [C₄H₉(C₂H₅)₂Si]₂NH, [C₅H₁₁(C₂H₅)₂Si]₂NH, [C₆H₁₃(C₂H₅)₂Si]₂NH, [C₇H₁₅(C₂H₅)₂Si]₂NH, [C₈H₁₇(C₂H₅)₂Si]₂NH, [C₉H₁₉(C₂H₅)₂Si]₂NH, [C₁₀H₂₁(C₂H₅)₂Si]₂NH, [C₁₁H₂₃(C₂H₅)₂Si]₂NH, [C₁₂H₂₅(C₂H₅)₂Si]₂NH, [C₁₃H₂₇(C₂H₅)₂Si]₂NH, [C₁₄H₂₉(C₂H₅)₂Si]₂NH, [C₁₅H₃₁(C₂H₅)₂Si]₂NH, [C₁₆H₃₃(C₂H₅)₂Si]₂NH, [C₁₇H₃₅(C₂H₅)₂Si]₂NH, [C₁₈H₃₇(C₂H₅)₂Si]₂NH, and the like.

In terms of the reaction promoting effect (by extension, water repellency imparting effect), the combination of two methyl groups and one alkyl group is preferred as R³ in the general formula [2] and R⁴ in the general formula [3]. In other words, the base (IV) is preferably a base represented by the above general formula [7] and/or the above general formula [8].

It is important that the concentration of the base (IV) in the chemical liquid is 0.05 to 2 mass % based on the total amount of the chemical liquid. When the concentration of the base is 0.05 mass % or more, the chemical liquid exerts its reaction promoting effect (and by extension, water repellency imparting effect). When the concentration of the base is 2 mass % or less, it is less likely that the vinyl chloride resin will be significantly discolored by contact with the chemical liquid. The concentration of the base is preferably 0.08 to 1.5 mass %, more preferably 0.1 to 1.0 mass %.

Furthermore, it is important that the mass ratio of the silylation agent (III) to the base (IV) is 4.5 or greater. When the mass ratio is 4.5 or greater, it is less likely that the vinyl chloride resin will be significantly discolored by contact with the chemical liquid and is less likely that deposition of solid matter will be occur. The mass ratio is preferably 5 or greater, more preferably 8 or greater, so that deposition of solid matter is made less likely to occur.

Other Components

The water-repellent protective film-forming chemical liquid according to the present invention may contain additives, such as polymerization inhibitor, chain transfer agent, antioxidant etc., in order to improve the stability of the chemical liquid.

The chemical liquid according to the present invention may preferably contain an amide compound represented by the above general formula [9] so that it is possible for the chemical liquid to easily maintain its water repellency imparting effect even when water is mixed into the chemical liquid.

In terms of the above-mentioned effect, the amount of the amide compound contained is preferably 0.1 mass % or more based on the total 100 mass % of the chemical liquid. It is not preferable to contain the amide compound in an excessive amount on the fear that excessive amide compound may remain as an impurity on the wafer surface and from the viewpoint of cost. The upper limit of the amount of the amide compound contained is preferably 30 mass % based on the total 100 mass % of the chemical liquid.

Specific examples of the amide compound represented by the general formula [9] are: N-alkyl silyltrifluoroacetamide such as CH₃Si[N(H)C(═O)CF₃]₃, C₂H₅Si[N(H)C(═O)CF₃]₃, C₃H₇Si[N(H)C(═O)CF₃]₃, C₄H₉Si[N(H)C(═O)CF₃]₃, C₅H₁₁Si[N(H)C(═O)CF₃]₃, C₆H₁₃Si[N(H)C(═O)CF₃]₃, C₇H₁₅Si[N(H)C(═O)CF₃]₃, C₈H₁₇Si[N(H)C(═O)CF₃]₃, C₉H₁₉Si[N(H)C(═O)CF₃]₃, C₁₀H₂₁Si[N(H)C(═O)CF₃]₃, C₁₁H₂₃Si[N(H)C(═O)CF₃]₃, C₁₂H₂₅Si[N(H)C(═O)CF₃]₃, C₁₃H₂₇Si[N(H)C(═O)CF₃]₃, C₁₄H₂₉Si[N(H)C(═O)CF₃]₃, C₁₅H₃₁Si[[N(H)C(═O)CF₃]₃, C₁₆H₃₃Si[N(H)C(═O)CF₃]₃, C₁₇H₃₅Si[N(H)C(═O)CF₃]₃, C₁₈H₃₇Si[N(H)C(═O)CF₃]₃, (CH₃)₂Si[N(H)C(═O)CF₃]₂, C₂H₅Si(CH₃)[N(H)C(═O)CF₃]₂, (C₂H₅)₂Si[N(H)C(═O)CF₃]₂, C₃H₇Si(CH₃)N(H)C(═O)CF₃]₂, (C₃H₇)₂Si[N(H)C(═O)CF₃]₂, C₄H₉Si(CH₃)[N(H)C(═O)CF₃]₂, (C₄H₉)₂Si[N(H)C(═o)CF₃]₂, C₅H₁₁Si(CH₃)[N(H)C(═O)CF₃]₂, C₆H₁₃Si(CH₃)[N(H)C(═O)CF₃]₂, C₇H₁₅Si(CH₃)[N(H)C(═O)CF₃]₂, C₈H₁₇Si(CH₃)[N(H)C(═O)CF₃]₂, C₉H₁₉Si(CH₃)[N(H)C(═O)CF₃]₂, C₁₀H₂₁Si(CH₃)[N(H)C(═O)CF₃]₂, C₁₁H₂₃Si(CH₃)[N(H)C(═O)CF₃]₂, C₁₂H₂₅Si(CH₃)[N(H)C(═O)CF₃]₂, C₁₃H₂₇Si(CH₃)[N(H)C(═O)CF₃]₂, C₁₄H₂₉Si(CH₃)[N(H)C(═O)CF₃]₂, C₁₅H₃₁Si(CH₃)[N(H)C(═O)CF₃]₂, C₁₆H₃₃Si(CH₃)[N(H)C(═O)CF₃]₂, C₁₇H₃₅Si(CH₃)[N(H)C(═O)CF₃]₂, C₁₈H₃₇Si(CH₃)[N(H)C(═O)CF₃]₂, (CH₃)₃SiN(H)C(═O)CF₃, C₂H₅Si(CH₃)₂N(H)C(═O)CF₃, (C₂H₅)₂Si(CH₃)N(H)C(═O)CF₃, (C₂H₅)₃SiN(H)C(═O)CF₃, C₃H₇Si(CH₃)₂N(H)C(═O)CF₃, (C₃H₇)₂Si(CH₃)N(H)C(═O)CF₃, (C₃H₇)₃SiN(H)C(═O)CF₃, C₄H₉Si(CH₃)₂N(H)C(═O)CF₃, (C₄H₉)₃SiN(H)C(═O)CF₃, C₅H₁₁Si(CH₃)₂N(H)C(═O)CF₃, C₆H₁₃Si(CH₃)₂N(H)C(═O)CF₃, C₇H₁₅Si(CH₃)₂N(H)C(═O)CF₃, C₈H₁₇Si(CH₃)₂N(H)C(═O)CF₃, C₉H₁₉Si(CH₃)₂N(H)C(═O)CF₃, C₁₀H₂₁Si(CH₃)₂N(H)C(═O)CF₃, C₁₁H₂₃Si(CH₃)₂N(H)C(═O)CF₃, C₁₂H₂₅Si(CH₃)₂N(H)C(═O)CF₃, C₁₃H₂₇Si(CH₃)₂N(H)C(═O)CF₃, C₁₄H₂₉Si(CH₃)₂N(H)C(═O)CF₃, C₁₅H₃₁Si(CH₃)₂N(H)C(═O)CF₃, C₁₆H₃₃Si(CH₃)₂N(H)C(═O)CF₃, C₁₇H₃₅Si(CH₃)₂N(H)C(═O)CF₃, C₁₈H₃₇Si(CH₃)₂N(H)C(═O)CF₃, (CH₃)₂Si(H)N(H)C(═O)CF₃, CH₃Si(H)₂N(H)C(═O)CF₃, (C₂H₅)₂Si(H)N(H)C(═O)CF₃, C₂H₅Si(H)₂N(H)C(═O)CF₃, C₂H₅Si(CH₃)(H)N(H)C(═O)CF₃, (C₃H₇)₂Si(H)N(H)C(═O)CF₃, C₃H₇Si(H)₂N(H)C(═O)CF₃, CF₃CH₂CH₂Si[N(H)C(═O)CF₃]₃, C₂F₅CH₂CH₂Si[N(H)C(═O)CF₃]₃, C₃F₇CH₂CH₂Si[N(H)C(═O)CF₃]₃, C₄F₉CH₂CH₂Si[N(H)C(═O)CF₃]₃, C₅F₁₁CH₂CH₂Si[N(H)C(═O)CF₃]₃, C₆F₁₃CH₂CH₂Si[N(H)C(═O)CF₃]₃, C₇F₁₅CH₂CH₂Si[N(H)C(═O)CF₃]₃, C₈F₁₇CH₂CH₂Si[N(H)C(═O)CF₃]₃, CF₃CH₂CH₂Si(CH₃)[N(H)C(═O)CF₃]₂, C₂F₅CH₂CH₂Si(CH₃)[N(H)C(═O)CF₃]₂, C₃F₇CH₂CH₂Si(CH₃)[N(H)C(═O)CF₃]₂, C₄F₉CH₂CH₂Si(CH₃)[N(H)C(═O)CF₃]₂, C₅F₁₁CH₂CH₂Si(CH₃)[N(H)C(═O)CF₃]₂, C₆F₁₃CH₂CH₂Si(CH₃)[N(H)C(═O)CF₃]₂, C₇F₁₅CH₂CH₂Si(CH₃)[N(H)C(═O)CF₃]₂, C₈F₁₇CH₂CH₂Si(CH₃)[N(H)C(═O)CF₃]₂, CF₃CH₂CH₂Si(CH₃)₂N(H)C(═O)CF₃, C₂F₅CH₂CH₂Si(CH₃)₂N(H)C(═O)CF₃, C₃F₇CH₂CH₂Si(CH₃)₂N(H)C(═O)CF₃, C₄F₉CH₂CH₂Si(CH₃)₂N(H)C(═O)CF₃, C₅F₁₁CH₂CH₂Si(CH₃)₂N(H)C(═O)CF₃, C₆F₁₃CH₂CH₂Si(CH₃)₂N(H)C(═O)CF₃, C₇F₁₅CH₂CH₂Si(CH₃)₂N(H)C(═O)CF₃, C₈F₁₇CH₂CH₂Si(CH₃)₂N(H)C(═O)CF₃, CF₃CH₂CH₂Si(CH₃)(H)N(H)C(═O)CF₃; and those obtained by replacing —N(H)C(═O)CF₃ group of the above N-alkylsilyltrifluoroacetamide with —N(H)C(═O)R¹³ group other than N(H)C(═O)CF₃ (where R¹³ is an alkyl group of 1 to 6 carbon atoms in which a part or all of hydrogen atoms are substituted with fluorine).

Further, R¹³ in —N(H)C(═O)R¹³ group is preferably an alkyl group in which all of hydrogen atoms are substituted with fluorine so that the chemical liquid can easily exert a greater water repellency imparting effect even when water is mixed into the chemical liquid. The alkyl group is preferably of 1 to 4 carbon atoms, more preferably 1 carbon atom.

The number of —N(H)C(═O)R¹³ group as expressed by 4-g-h in the general formula [9] is preferably 1 so that, even when water is mixed into the chemical liquid, it is possible to uniformly form the protective film.

Further, h in the general formula [9] is preferably 0 so that it is possible to easily maintain water repellency in the after-mentioned cleaning step after the formation of the protective film even when water is mixed into the chemical liquid.

The combination of two CH₃ groups and one linear alkyl group is preferred as R¹² so that, even when water is mixed in the chemical liquid, it is possible to uniformly form the protective film. The combination of three CH₃ groups is particularly preferred as R¹².

The amide compound represented by the general formula [9] may be produced by reaction. For example, the reaction of hexamethyldisilazane and trifluoroacetic anhydride leads to not only the production of trimethylsilyl trifluoroacetate as the silylation agent represented by the general formula [1] but also the by-production of N-trimethylsilyl trifluoroacetamide as the amide compound. As long as the amide compound represented by the general formula [9] is obtained, there can be utilized any reaction other than the above reaction.

Further, it is preferable that the total amount of water in starting raw materials of the chemical liquid is 2000 mass ppm or less based on the total amount of the raw materials. When the total amount of water in the raw materials exceeds 2000 mass ppm, the effects of the silylation agent and the base may be lowered so that it becomes difficult to form the protective film in a short time. For this reason, it is preferable that the total amount of water in the raw materials of the chemical liquid is as less as possible. The total amount of water in the raw materials of the chemical liquid is more preferably 500 mass ppm or less, still more preferably 200 mass ppm or less. The less amount of water is preferred in view of the fact that the more amount of water present, the more likely the storage stability of the chemical liquid is to be deteriorated. The total amount of water in the raw materials of the chemical liquid is particularly preferably 100 mass ppm or less, more particularly preferably 50 mass ppm or less. Although it is preferable that the total amount of water in the raw materials of the chemical liquid is as less as possible, the total amount of water in the raw materials of the chemical liquid may be 0.1 mass ppm or more as long as within the above range. Consequently, it is preferable that the silylation agent, the base and the first and second solvents contained in the chemical liquid are low in water content.

It is also preferable that, in a particle measurement made in a liquid phase of the chemical liquid by a light scattering type in-liquid particle detector, the number of particles of diameter larger than 0.2 μm is 100 or less per 1 mL of the chemical liquid. When the number of particles of diameter larger than 0.2 μm exceeds 100 per 1 mL of the chemical liquid, there unfavorably occurs a risk of damage to the pattern by the particles. This can lead to a deterioration in device yield and reliability. When the number of particles of diameter larger than 0.2 μm is 100 or less per 1 mL of the chemical liquid, it is favorably possible to omit or reduce the cleaning of the wafer surface with a solvent or water after the formation of the protective film. Although it is preferable that the number of particles of diameter larger than 0.2 μm in the chemical liquid is as less as possible, the number of particles of diameter larger than 0.2 μm may be 1 or more per 1 mL of the chemical liquid as long as within the above range. In the present invention, the particle measurement in the liquid phase of the chemical liquid can be made by a commercially available measurement device on the basis of a laser light scattering type in-liquid particle measuring method using a laser as a light source. The particle diameter means a light scattering equivalent diameter with reference to a PSL (polystyrene latex) standard particle.

Herein, the term “particles” include not only particles such as dust, dirt, organic solid matter and inorganic solid matter contained as impurities in the raw materials, but also particles such as dust, dirt, organic solid matter and inorganic solid matter introduced as contaminants during preparation of the chemical liquid, and refer to particles finally present without being dissolved in the chemical liquid.

Furthermore, it is preferable that the amount of respective Na, Mg, K, Ca, Mn, Fe, Cu, Li, Al, Cr, Ni, Zn and Ag elements (as metal impurity) in the chemical liquid is 0.1 mass ppb or less based on the total amount of the chemical liquid. When the amount of the metal impurity element in the chemical liquid is more than 0.1 mass ppb based on the total amount of the chemical liquid, there unfavorably occurs a risk of increase in device junction leakage current. This can lead to a deterioration in device yield or reliability. When the amount of the metal impurity element in the chemical liquid is 0.1 mass ppb or less based on the total amount of the chemical liquid, it is favorably possible to omit or reduce the cleaning of the wafer surface (that is, the surface of the protective film) with a solvent or water after the formation of the protective film. For this reason, it is preferable that the amount of the metal impurity in the chemical liquid is as less as possible. The amount of the metal impurity element in the chemical liquid may however be 0.001 mass ppb or more as long as within the above range.

The chemical liquid according to the present invention may be provided as a single-liquid type kit in which the first solvent (I), the second solvent (II), the silylation agent (III) and the base (IV) have been mixed together, or a two-liquid type kit provided with a first solution of the silylation agent in a mixed solvent of the first and second solvents and a second solution of the base in the mixed solvent and used by mixing of the first and second solutions.

2. Water-Repellent Protective Film

In the present invention, the term “water-repellent protective film” refers to a film formed on a wafer surface to decrease the wettability of the wafer surface and impart water repellency to the wafer surface. Further, the term “water repellency” as used herein means to decrease a surface energy of an article surface and thereby reduce an interaction such as hydrogen bond or intermolecular force (at an interface) between water or another liquid and the article surface. The water repellency shows a great interaction reducing effect against water, but shows a certain interaction reducing effect against a mixed liquid of water and a liquid other than water or against a liquid other than water. The contact angle of the liquid to the article surface can be increased with reduction of the interaction. Herein, the water-repellent protective film may be formed of the silylation agent or formed of a reaction product containing the silylation agent as a main component. The water-repellent protect film may contain the base or a component derived from the base.

3. Wafer

As the wafer, there can be used a wafer having on a surface thereof a film which contains a silicon element in the form of silicon, silicon oxide, silicon nitride or the like, or a wafer having an uneven pattern whose surface at least partially contains a silicon element in the form of silicon, silicon oxide, silicon nitride or the like. Even in the case of using a wafer composed of a plurality of components containing at least silicon element, the protective film can be formed on a surface of such silicon element-containing component. The wafer composed of a plurality of components may be those in which silicon element-containing component such as silicon, silicon oxide, silicon nitride or the like is present on the wafer surface, or those in which at least a part of the uneven pattern on the wafer surface is formed of silicon element-containing component such as silicon, silicon oxide, silicon nitride or the like. It is herein noted that the area of the wafer where the protective film can be formed from the chemical liquid is a surface of silicon element-containing part of the uneven pattern.

The surface of the wafer may contain any element other than silicon element as long as the protective film is formed on the pattern surface.

In general, the wafer having on the surface thereof the fine uneven pattern is obtained by the following procedure. First, a resist with a desired uneven pattern is formed by applying a resist to the smooth surface of the wafer, exposing the applied resist to light through a resist mask and removing by etching an exposed portion or unexposed portion of the resist. The resist with the uneven pattern may alternatively be formed by pressing a mold with a pattern against the resist. Next, the wafer is subjected to etching. In this etching step, portions of the wafer surface corresponding to the recess portions of the resist pattern is selectively etched. Finally, the resist is removed whereby the wafer with the fine uneven pattern is obtained.

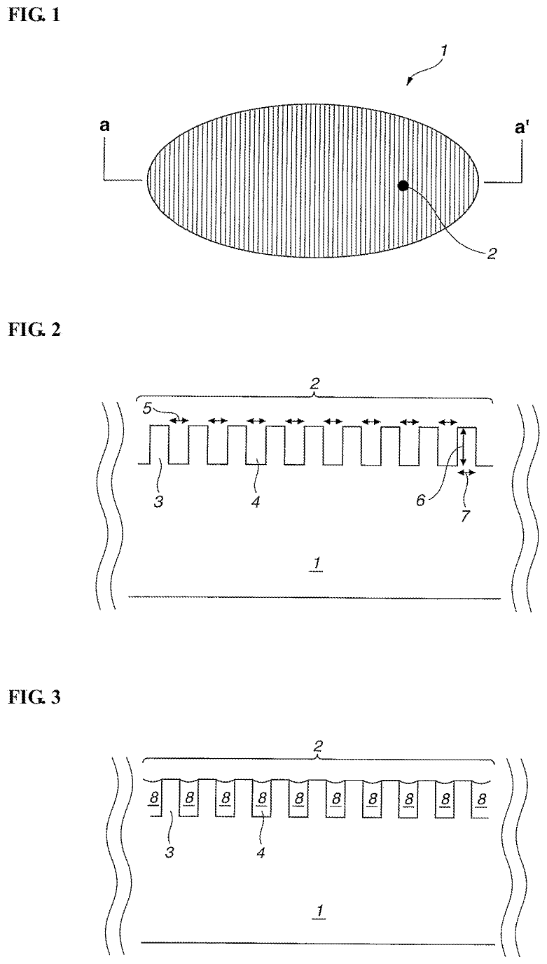

After the formation of the fine uneven pattern on the wafer surface, the wafer surface is cleaned with a water-based cleaning liquid; and then the water-based cleaning liquid is removed by drying or the like. During this cleaning process, collapse of the pattern is likely to occur when the width of the recess portions of the pattern is small and the aspect ratio of the projection portions of the pattern is high. The dimensions of the uneven pattern are defined as shown in FIGS. 1 and 2. FIG. 1 is a schematic perspective view of the wafer 1 having on the surface thereof the fine uneven pattern 2. FIG. 2 is a view showing a part of a-a′ cross section of FIG. 1. As shown in FIG. 2, a width 5 of the recess portions is determined as an interval between adjacent projection portions 3; and an aspect ratio of the projection portions is determined by dividing a height 6 of the projection portions by a width 7 of the projection portions. The pattern collapse tends to occur during the cleaning process when the width of the recess portions is 70 nm or smaller, particularly 45 nm or smaller, and the aspect ratio of the projection portions is 4 or higher, particularly 6 or higher.

4. Wafer Cleaning Method

The wafer, which has the fine uneven pattern formed on the surface thereof by etching as mentioned above, may be cleaned with a water-based cleaning liquid so as to remove etching residues in advance of the wafer cleaning method according to the present invention. The wafer may be further cleaned by replacing the water-based cleaning liquid remaining in the recess portions after the above cleaning step with a cleaning liquid different from the water-based cleaning liquid (hereinafter referred to as “cleaning liquid A”).

As the water-based cleaning liquid, there can be used water or an aqueous solution containing in water at least one kind selected from organic solvent, hydrogen peroxide, ozone, acid, alkali and surfactant (e.g. with a water content of 10 mass % or more).

As the cleaning liquid A, there can be used an organic solvent, a mixture of the organic solvent with a water-based cleaning liquid, or a cleaning liquid containing at least one kind selected from acid, alkali and surfactant in the organic solvent or in the mixture of the organic solvent with the water-based cleaning liquid.

In the present invention, there is no particular limitation on the wafer cleaning technique as long as the cleaning is performed by means of a cleaning machine capable of retaining the chemical liquid or the cleaning liquid at least in the recess portions of the uneven pattern of the wafer. It is feasible to adopt a single wafer process such as a cleaning process using a spin washing machine in which wafers are cleaned one by one by rotating the wafer in a nearly horizontal position while supplying the liquid to the vicinity of the rotation center, or a batch process using a washing machine in which a plurality of wafers are cleaned together by immersion in the liquid within a cleaning chamber. There is also no particular limitation on the forms of the chemical liquid and the cleaning liquid supplied to at least the recess portions of the uneven pattern of the wafer as long as the liquid is in a liquid state when retained in the recess portions. The chemical liquid and the cleaning liquid can be each supplied in e.g. liquid form, vapor form or the like.

Examples of the organic solvent preferably usable as the cleaning liquid A are hydrocarbons, esters, ethers, ketones, halogen-containing solvents, sulfoxide-based solvents, lactone-based solvents, carbonate-based solvents, alcohols, polyol derivatives, nitrogen-containing solvents and the like. Among others, hydrocarbons, ethers, alcohols and polyol derivatives without OH groups and acetate groups are preferred because each of these solvents is unlikely to cause deterioration of vinyl chloride resin. In the case of using the organic solvent as the cleaning liquid A, it is preferable that 80 mass % or more of the total amount of the organic solvent is occupied by the above preferable solvent such as hydrocarbon, ether, alcohol and polyol derivative without OH group and acetate group.

The protective film-forming chemical liquid according to the present invention is used by replacing the water-based cleaning liquid or the cleaning liquid A with the chemical liquid. The replaced chemical liquid may be replaced with a cleaning liquid different from the chemical liquid (hereinafter referred to as “cleaning liquid B”).

After the cleaning of the wafer with the water-based cleaning liquid or the cleaning liquid A, the cleaning liquid is replaced with the protective film-forming chemical liquid. While the chemical liquid is retained at least in the recess portions of the uneven pattern, the protective film is formed on at least the surfaces of the recess portions of the uneven pattern. (This step is referred to as a water-repellent protective film forming step.) In the present invention, the protective film is not necessarily continuously formed and is not necessarily uniformly formed. It is however preferable that the protective film is continuously and uniformly formed to impart higher water repellency.

FIG. 3 is a schematic view showing a state where the protective film-forming chemical liquid 8 is retained in the recess portions 4. The schematic view of FIG. 3 corresponds to a part of a-a′ cross section of FIG. 1. In this state, the protective film is formed on the surfaces of the recess portions 4 so as to impart water repellency to the surfaces of the recess portions 4.

When the temperature of the protective film-forming chemical liquid is increased, it becomes easy to form the protective film in a shorter time. The temperature at which the uniform protective film can be easily formed is higher than or equal to 10° C. and lower than a boiling point of the chemical liquid. In particular, the chemical liquid is preferably retained at a temperature higher than or equal to 15° C. and lower than or equal to a temperature 10° C. lower than the boiling point of the chemical liquid. It is preferable to maintain the temperature of the chemical liquid at the above-mentioned temperature when the chemical liquid is retained at least in the recess portions of the uneven pattern (i.e. during the water-repellent protective film forming step). Herein, the boiling point of the chemical liquid means a boiling point of any component present in the largest amount by mass ratio among the components of the protective film-forming chemical liquid.

After the formation of the protective film, the protective film may be subjected to drying after replacing the chemical liquid remaining at least in the recess portions of the uneven pattern with the cleaning liquid B. As the cleaning liquid B, there can be used a water-based cleaning liquid, an organic solvent, a mixture of the water-based cleaning liquid and the organic solvent, a mixture thereof with at least one kind selected from acid, alkali and surfactant, a mixture thereof with the protective film-forming chemical liquid or the like. From the viewpoint of removal of particles and metal impurities, the cleaning liquid B is preferably water, an organic solvent or a mixture of the organic solvent with water.

Examples of the organic solvent preferably usable as the cleaning liquid B are hydrocarbons, esters, ethers, ketones, halogen-containing solvents, sulfoxide-based solvents, alcohols, polyol derivatives, nitrogen-containing solvents and the like. Among others, hydrocarbons, ethers, alcohols and polyol derivatives without OH groups and acetate groups are preferred because each of these solvents is unlikely to cause deterioration of vinyl chloride resin. In the case of using the organic solvent as the cleaning liquid B, it is preferable that 80 mass % or more of the total amount of the organic solvent is occupied by the above preferable solvent such as hydrocarbon, ether, alcohol and polyol derivative without OH group and acetate group.

There are cases where, when an organic solvent is used as the cleaning liquid B, the protective film formed on the wafer surface from the chemical liquid according to the present invention is less likely to be lowered in water repellency by cleaning with the chemical liquid B.

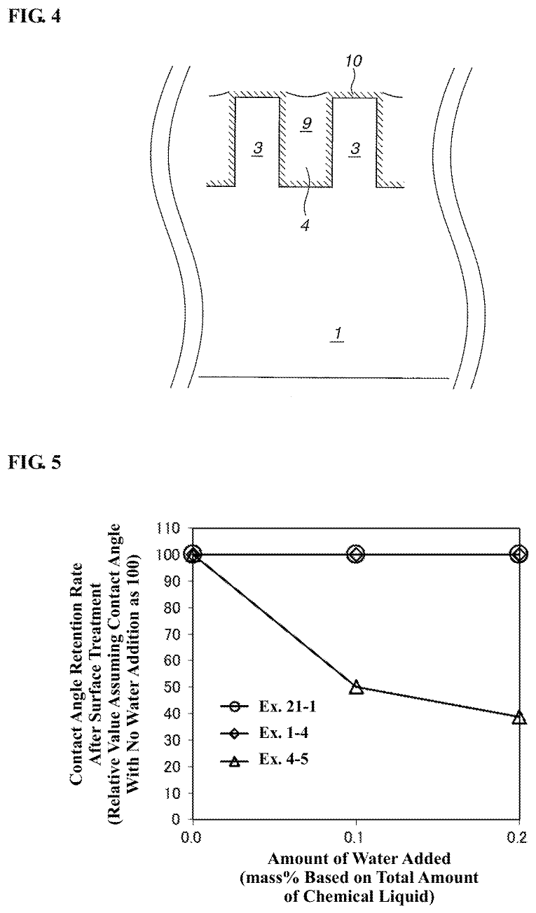

FIG. 4 is a schematic view showing a state where a liquid is retained in the recess portions 4 to which water repellency has been imparted by the protective film-forming chemical liquid. The schematic view of FIG. 4 corresponds to a part of a-a′ cross section of FIG. 1. The surface of the uneven pattern is made water repellent as the protective film 10 is formed from the chemical liquid. Even when the liquid 9 is removed from the uneven pattern, the protective film 10 is maintained on the wafer surface.

It is herein assumed that, in a state where the protective film 10 has been formed from the protective film-forming chemical liquid at least on the surfaces of the recess portions of the uneven pattern of the wafer, water is retained on the surfaces of the recess portion. In this case, the contact angle of water to the pattern is preferably 70 to 130° so that collapse of the pattern is made less unlikely to occur. The larger the contact angle, the higher the water repellency. The contact angle is more preferably 80 to 130°, still more preferably 85 to 130°. Further, it is preferable that a decrease of the contact angle before and after the cleaning with the cleaning liquid B (i.e. the contact angle before the cleaning with the cleaning liquid B—the contact angle after the cleaning with the cleaning liquid B) is 10° or smaller.

Then, the liquid retained in the recess portions 4 of the uneven pattern on which the protective film 10 has been formed from the chemical liquid is removed from the uneven pattern by drying. The liquid retained in the recess portions may be the chemical liquid, the cleaning liquid B or a mixed liquid thereof. The mixed liquid is a liquid in which the respective components of the protective film-forming chemical liquid are lower in concentration than those in the chemical liquid. In other words, the mixed liquid may be a liquid in the middle of replacing the chemical liquid with the cleaning liquid B, or may be a liquid prepared in advance by mixing the respective components of the chemical liquid with the cleaning liquid B. In terms of the wafer cleanliness, water, the organic solvent or a mixture thereof is preferred. After the liquid is once removed from the surface of the uneven pattern, the cleaning liquid B may be retained on the surface of the uneven pattern and then removed by drying.

In the case of cleaning the surface of the uneven pattern with the cleaning liquid B after the formation of the protective film, the cleaning time, that is, the time of retaining the cleaning liquid B is preferably 10 seconds or longer, more preferably 20 seconds or longer, from the viewpoint of removing particles or impurities from the surface of the uneven pattern. In terms of the water repellency maintaining effect of the protective film on the surface of the uneven pattern, there is a tendency that the water repellency of the wafer surface can be easily maintained even after the cleaning when the organic solvent is used as the cleaning liquid B. On the other hand, the productivity of the wafer is deteriorated when the cleaning time is too long. The cleaning time is thus preferably 15 minutes or shorter.

By the drying, the liquid retained in the uneven pattern is removed. It is preferable to perform the drying by a known drying technique such as spin drying, IPA (2-propanol) steam drying, Marangoni drying, heat drying, hot-air drying, air-blow drying or vacuum drying.

The protective film 10 may be removed after the drying. For removal of the water-repellent protective film, it is effective to cleave C—C bond and C—F bond in the water-repellent protective film. There is no particular limitation on the bond cleavage technique as long as it is capable of cleaving the above-mentioned bond. For example, the wafer surface may be treated by light irradiation, heating, ozone exposure, plasma irradiation, corona discharge or the like.

In the case of removing the protective film 10 by light irradiation, it is preferable to irradiate the wafer surface with an ultraviolet light of wavelengths shorter than 340 nm and 240 nm which respectively correspond to 83 kcal/mol and 116 kcal/mol, i.e., the bond energies of C—C bond and C—F bond in the protective film 10. As a light source, there can be used a metal halide lamp, a low-pressure mercury lamp, a high-pressure mercury lamp, an excimer lamp, a carbon arc lamp or the like. In the case of using a metal halide lamp as the light source, the irradiation intensity of the ultraviolet light is preferably 100 mW/cm² or higher, more preferably 200 mW/cm² or higher, as measured by an illuminometer (such as an irradiation intensity meter UM-10 manufactured by Konica Minolta Sensing, Inc. with a light receptor UM-360 [peak sensitivity wavelength: 365 nm, measurement wavelength range: 310 to 400 nm]). When the irradiation intensity is lower than 100 mW/cm², it takes a long time to remove the protective film 10. It is preferable to use the low-pressure mercury lamp because the low-pressure mercury lamp enables irradiation of the wafer surface with an ultraviolet light of shorter wavelengths so as to, even if the irradiation intensity is low, remove the protective film 10 in a short time.

In the case of removing the protective film 10 by light irradiation, it is preferable to generate ozone in parallel with decomposing components of the protective film 10 by irradiation with an ultraviolet light and then induce oxidation volatilization of the components of the protective film 10 by the ozone for shortening of treatment time. As a light source, there can be used a low-pressure mercury lamp, an excimer lamp or the like. The wafer may be heated while being subjected to light irradiation. As a light source, there can be used a low-pressure mercury lamp, an excimer lamp or the like. The wafer may be heated while being subjected to light irradiation.

In the case of heating the wafer, the heating temperature of the wafer is preferably 400 to 1000° C., more preferably 500 to 900° C.; and the heating time of the wafer is preferably 10 seconds to 60 minutes, more preferably 30 seconds to 10 minutes. The heating may be performed in combination with ozone exposure, plasma irradiation, corona discharge or the like. The wafer may be subjected to light irradiation while heating.

In the case of removing the protective film 10 by heating, it is feasible to bring the wafer into a heat source or place the wafer in a heated atmosphere such as heat treatment furnace. Even in the case of treating a plurality of wafers, energy for removal of the protective film 10 can be applied uniformly to the wafer surface by placement of the wafers in the heated atmosphere. Thus, the placement of the wafer in the heated atmosphere is industrially advantageous in terms of easy operation, short treatment time and high treatment capability.

In the case of exposing the wafer ozone, it is preferable to supply the wafer surface with ozone generated by ultraviolet radiation from a low-pressure mercury lamp etc., low-temperature discharge under high voltage application, or the like. The wafer may be subjected to light irradiation or heating while being exposed to ozone. The wafer may be subjected to light irradiation or heating while being exposed to ozone.

The protective film on the wafer surface can be efficiently removed by any combination of the light irradiation treatment, the heating treatment, the ozone exposure treatment, the plasma irradiation treatment and the corona discharge treatment.

### EXAMPLES

The embodiments of the present invention will be described in more detail below by way of the following examples. It should be understood that the present invention is not limited to these examples.

The technique of forming an uneven pattern on a surface of a wafer and the technique of replacing a cleaning liquid retained at least in recess portions of the uneven pattern with another cleaning liquid have been variously studied as discussed in other literatures and have already been established. Accordingly, the water repellency imparting effect of the protective film-forming chemical liquid as well as the resistance of a vinyl chloride resin to the chemical liquid and the unlikelihood of solid matter deposition caused in the chemical liquid due to the mixing of a protic solvent (water) into the chemical liquid were evaluated in the present invention. In the respective examples of the present invention, water, which is a typical water-based cleaning liquid, was used as the liquid brought into contact with the wafer surface for contact angle measurement.

In the case of a wafer having an unevenly patterned surface, it is not possible to exactly evaluate the angle of contact of water with a protective film 10 itself formed on the unevenly patterned surface of the wafer.

The contact angle of a water drop is generally evaluated by dropping several microliters of water on a surface of a sample (substrate) and then measuring an angle between the water drop and the substrate surface according to JIS R 3257 “Testing Method of Wettability of Glass Substrate Surface”. In the case of a wafer having a pattern, however, the contact angle is enormously large. This is due to the Wenzel's effect or Cassie's effect by which the apparent contact angle of the water drop becomes increased under the influence of the surface shape (roughness) of the substrate on the contact angle.

In view of the above facts, the respective examples were each implemented by providing a wafer with a smooth surface, supplying a chemical liquid to the smooth surface of the wafer to form a protective film on the wafer surface, and then, making various evaluations on the assumption of the thus-formed protective film as a protective film formed on an unevenly patterned surface of a wafer. In each example, a silicon wafer having a smooth surface coated with a SiO₂ layer, called a “SiO₂-coated wafer”, was used as the wafer with the smooth surface.

The details of the respective examples will be explained below. In the following, explanations will be given of methods for evaluations, a method for preparing a protective film-forming chemical liquid, a method for cleaning a wafer with the use of a protective film-forming chemical liquid, and results of the evaluations.

[Methods of Evaluation Tests]

The following evaluation tests (A) to (E) were conducted.

(A) Unlikelihood of Solid Matter Deposition in Chemical Liquid by Mixing of Protic Solvent (Water)

To 20 g of a protective film-forming chemical liquid prepared in the after-mentioned example, water was added in an amount of 2 μL (that is, about 100 mass ppm relative to the chemical liquid) or 4 μL (that is, about 200 mass ppm relative to the chemical liquid) at 25° C. Then, the chemical liquid was stirred for 1 minute. After that, the presence or absence of deposited solid matter in the chemical liquid was visually checked. When the solid matter was deposited with the addition of 2 μL (about 100 mass ppm relative to the chemical liquid) of water, the sample was evaluated as “fail” upon judging that solid matter deposition was likely to occur in the chemical liquid. As a matter of course, it can be said that the deposition of solid matter in the chemical liquid is less likely to occur in the case where there is no solid mater deposited even with the addition of a larger amount of water. The use of such a chemical liquid is preferred in terms of the stability of the chemical liquid. Further, the case where solid matter deposition is slightly observed is more preferable than the case where solid matter deposition is clearly observed because it can be said that the deposition of solid matter in the chemical liquid is less likely to occur in the former case than in the latter case.

(B) Contact Angle relative to Protective Film on Wafer Surface

About 2 μl of pure water was dropped on a surface of a wafer on which a protective film was formed. Then, the angle between the water drop and the wafer surface (as a contact angle) was measured with a contact angle meter (manufactured by Kyowa Interface Science Co., Ltd.: CA-X Model).

(C) Decrease of Contact Angle by Contact with Water

After the wafer on which the protective film was formed was immersed in hot water of 60° C. for 10 minutes, a decrease of the contact angle by contact with (immersion in) water was evaluated. The smaller the decrease of the contact angle, the more unlikely the contact angle to be decreased by the cleaning step after the formation of the protective film. It is particularly preferable that the decrease of the contact angle is 10° or smaller.

(D) Discoloring of Vinyl Chloride Resin by Contact with Water-Repellent Protective Film-Forming Chemical Liquid

In each example of the present invention, the resistance of a vinyl chloride resin was evaluated by immersing a sample of vinyl chloride resin in a protective film-forming chemical liquid and then checking the occurrence or non-occurrence of discoloring of the vinyl chloride resin sample in place of, after cleaning a wafer by means of a wafer cleaning machine with a vinyl chloride resin-containing liquid contact part, checking the occurrence or non-occurrence of a deterioration of the liquid contact part. More specifically, the vinyl chloride resin sample was kept immersed in the protective film-forming chemical liquid at 40° C. for 4 weeks. After the immersion, the vinyl chloride resin sample was visually observed to examine the occurrence of discoloring of the vinyl chloride resin sample. As a matter of course, it is preferable that there occurs no discoloring of the vinyl chloride resin (i.e. it is preferable that the degree of discoloring of the vinyl chloride resin is as low as possible). The sample was judged as “pass” when there occurred no discoloration of the sample.

(E) Evaluation of Swelling of Vinyl Chloride Resin by Contact with Water-Repellent Protective Film-Forming Chemical Liquid

In each example of the present invention, the resistance of a vinyl chloride resin was also evaluated by immersing a sample of vinyl chloride resin in a protective film-forming chemical liquid and then checking the occurrence or non-occurrence of swelling (dimensional change) of the vinyl chloride resin sample in place of, after cleaning a wafer by means of a wafer cleaning machine with a vinyl chloride resin-containing liquid contact part, checking the occurrence or non-occurrence of a deterioration of the liquid contact part. More specifically, the vinyl chloride resin sample was kept immersed in the protective film-forming chemical liquid at 40° C. for 4 weeks. The degree of swelling of the vinyl chloride resin sample was determined based on a difference in dimension of the sample before and after the immersion. The smaller the difference in dimension of the vinyl chloride resin, the lower the degree of swelling of the vinyl chloride resin. It is preferable that the degree of swelling of the vinyl chloride resin is as low as possible. The sample was judged as “pass” when the dimensional change of the sample was within the range of 1%.

### Example 1-1

(1) Preparation of Protective Film-Forming Chemical Liquid

A protective film-forming chemical liquid was prepared by mixing 9.2 g of hexamethyldisilazane ([(H₃C)₃Si]₂NH; HMDS) as a silicon compound, 11.3 g of trifluoroacetic anhydride ((CF₃CO)₂O) as a fluorine-containing carboxylic acid anhydride, 78.0 g of diisoamyl ether ((CH₃)₂CHCH₂CH₂—O—CH₂CH₂CH(CH₃)₂; DiAE) and 1.5 g of tripropylene glycol dimethyl ether (TPGDME) together and reacting HMDS with trifluoroacetic anhydride. The thus-prepared protective film-forming chemical liquid contained trimethylsilyl trifluoroacetate as a silylation agent, HMDS as a base, DiAE as a first solvent and TPGDME as a second solvent. In this Example, the HMDS base component of the protective film-forming chemical liquid was a residual amount of HMDS remaining unconsumed by the aforementioned silylation agent forming reaction.

(2) Cleaning of Silicon Wafer

A silicon wafer with a smooth thermal oxide film (more specifically, a silicon wafer having on its surface a thermal oxide film of 1 μm thickness) was immersed in an aqueous solution of 1 mass % hydrogen fluoride at room temperature for 10 minutes, immersed in pure water at room temperature for 1 minute, and then, immersed in 2-propanol (iPA) at room temperature for 1 minute.

(3) Surface Treatment of Silicon Wafer with Protective Film-Forming Chemical Liquid

The cleaned silicon wafer was immersed in the protective film-forming chemical liquid, which was prepared in the above section “(1) Preparation of Protective Film-Forming Chemical Liquid”, at room temperature for 60 seconds. After that, the silicon wafer was immersed in iPA at room temperature for 1 minute and immersed in pure water at room temperature for 1 minute. Finally, the silicon wafer was taken out from the pure water and dried by air blowing to remove the pure water from the surface of the silicon wafer.

The evaluation tests (A) to (E) were performed as mentioned above. As shown in TABLE 1, the initial contact angle before the surface treatment was smaller than 10°; and the contact angle after the surface treatment was 90°. As is apparent from these results, the chemical liquid had the effect of imparting water repellency. As the decrease of the contact angle was 2°, the water repellency was favorably easily maintained. Further, the resistance of the vinyl chloride resin to the chemical liquid was good without solid matter deposited in the chemical liquid by the addition of 2 μL of water and without discoloring or swelling of the vinyl chloride resin after the immersion in the chemical liquid at 40° C. for 4 weeks.

TABLE 1

| | Protective Film-Forming Chemical liquid | | | | | | | | |
|---|---|---|---|---|---|---|---|---|---|
| | Starting Materials for | | | | | | | | |
| | Silylation Agent and Base | | | | | | | | |
| | | | | Fluorine- | | | | | |
| | | | | Containing | Composition after Liquid Preparation | | | | |
| | | | | Carboxylic | (III) | | (IV) | | |
| | | | | Acid or | Silylation Agent | | Base | | (III)/(IV) |
| | Silylation | | Silicon | Anhydrate | | Conc. | | Conc. | Mass |
| | Agent | Base | Compound | thereof | Kind | [mass %] | Kind | [mass %] | Ratio |
| Comp. | none | none | HMDS | (CF₃CO)₂O | (CH₃)₃Si—OCOCF₃ | 10.0 | HMDS | 0.5 | 20.0 |
| Ex. 1-1 | | | | | | | | | |
| Comp. | none | none | HMDS | (CF₃CO)₂O | (CH₃)₃Si—OCOCF₃ | 10.0 | HMDS | 0.5 | 20.0 |
| Ex. 1-2 | | | | | | | | | |
| Ex. 1-1 | none | none | HMDS | (CF₃CO)₂O | (CH₃)₃Si—OCOCF₃ | 10.0 | HMDS | 0.5 | 20.0 |
| Ex. 1-2 | none | none | HMDS | (CF₃CO)₂O | (CH₃)₃Si—OCOCF₃ | 10.0 | HMDS | 0.5 | 20.0 |
| Ex. 1-3 | none | none | HMDS | (CF₃CO)₂O | (CH₃)₃Si—OCOCF₃ | 10.0 | HMDS | 0.5 | 20.0 |
| Ex. 1-4 | none | none | HMDS | (CF₃CO)₂O | (CH₃)₃Si—OCOCF₃ | 10.0 | HMDS | 0.5 | 20.0 |
| Ex. 1-5 | none | none | HMDS | (CF₃CO)₂O | (CH₃)₃Si—OCOCF₃ | 10.0 | HMDS | 0.5 | 20.0 |
| Ex. 1-6 | none | none | HMDS | (CF₃CO)₂O | (CH₃)₃Si—OCOCF₃ | 10.0 | HMDS | 0.5 | 20.0 |
| Comp. | none | none | HMDS | (CF₃CO)₂O | (CH₃)₃Si—OCOCF₃ | 10.0 | HMDS | 0.5 | 20.0 |
| Ex. 1-3 | | | | | | | | | |

| | Protective Film-Forming | | | | | | | | |
|---|---|---|---|---|---|---|---|---|---|
| | Chemical liquid | | | | | | | | |
| | Composition after | | | | | | | | |
| | Liquid Preparation | | | Evaluation Results | | | | | |
| | | (II) | | Deposition of | | | | | |
| | (I) | Second | | Solid Matter by | | Contact Angle [°] | | | Resistance |
| | First | Solvent | | Addition of Given | | | After | Decrease by | of Vinyl |
| | Solvent | | Conc. | Amount of Water | | | Surface | Immersion | Chloride |
| | Kind | Kind | [mass %] | 2 μL | 4 μL | Initial | Treat. | in Hot Water | Resin |
| Comp. | DiAE | none | 0.0 | observed | observed | <10 | 90 | 0 | pass |
| Ex. 1-1 | | | | | | | | | |
| Comp. | DiAE | TPGDME | 0.1 | observed | observed | <10 | 90 | 1 | pass |
| Ex. 1-2 | | | | | | | | | |
| Ex. 1-1 | DiAE | TPGDME | 1.5 | not | observed | <10 | 90 | 0 | pass |
| | | | | observed | | | | | |
| Ex. 1-2 | DiAE | TPGDME | 2.5 | not | slightly | <10 | 90 | 1 | pass |
| | | | | observed | observed | | | | |
| Ex. 1-3 | DiAE | TPGDME | 5.0 | not | not | <10 | 90 | 0 | pass |
| | | | | observed | observed | | | | |
| Ex. 1-4 | DiAE | TPGDME | 10.0 | not | not | <10 | 90 | 0 | pass |
| | | | | observed | observed | | | | |
| Ex. 1-5 | DiAE | TPGDME | 17.0 | not | not | <10 | 90 | 1 | pass |
| | | | | observed | observed | | | | |
| Ex. 1-6 | DiAE | TPGDME | 25.0 | not | not | <10 | 90 | 0 | pass |
| | | | | observed | observed | | | | |
| Comp. | DiAE | TPGDME | 35.0 | not | not | <10 | 90 | 0 | fail |
| Ex. 1-3 | | | | observed | observed | | | | (swelling) |

### Examples 1-2 to 1-6 and Comparative Examples 1-1 to 1-3

The wafer surface treatment was performed in the same manner as in Example 1-1, except that the concentration of the second solvent in the chemical liquid was changed. After that, the evaluation tests were conducted in the same manner as above. In each of Examples 1-2 to 1-6 and Comparative Examples 1-1 to 1-3, trimethylsilyl trifluoroacetate as the silylation agent and HMDS as the base were provided through reaction of HMDS and trifluoroacetic anhydride used as the starting raw materials; HMDS contained as the base in the protective film-forming chemical liquid was a residual amount of HMDS remaining unconsumed by the aforementioned silylation agent forming reaction. The results are summarized in TABLE 1.

### Examples 2-1 to 2-5 and Comparative Examples 2-1 to 2-3

The wafer surface treatment was performed in the same manner as in Example 1-4, except that the concentrations of the silylation agent (III) and the base (IV) in the chemical liquid and the mass ratio of the silylation agent (III) to the base (IV) were changed by varying the amount of the silicon compound added and the amount of the fluorine-containing carboxylic acid anhydride added. After that, the evaluation tests were conducted in the same manner as above. In each of Examples 2-1 to 2-5 and Comparative Examples 2-2 and 2-3, trimethylsilyl trifluoroacetate as the silylation agent and HMDS as the base were provided through reaction of HMDS and trifluoroacetic anhydride used as the starting raw materials; and HMDS contained in the protective film-forming chemical liquid was a residual amount of HMDS remaining unconsumed by the aforementioned silylation agent forming reaction. The results are summarized in TABLE 2.

TABLE 2

| | Protective Film-Forming Chemical liquid | | | | | | | | |
|---|---|---|---|---|---|---|---|---|---|
| | Starting Materials for | | | | | | | | |
| | Silylation Agent and Base | | | | | | | | |
| | | | | Fluorine- | | | | | |
| | | | | Containing | Composition after Liquid Preparation | | | | |
| | | | | Carboxylic | (III) | | (IV) | | |
| | | | | Acid or | Silylation Agent | | Base | | (III)/(IV) |
| | Silylation | | Silicon | Anhydrate | | Conc. | | Conc. | Mass |
| | Agent | Base | Compound | thereof | Kind | [mass %] | Kind | [mass %] | Ratio |
| Com. | none | none | HMDS | none | none | 0.0 | HMDS | 0.5 | 0.0 |
| Ex. 2-1 | | | | | | | | | |
| Com. | none | none | HMDS | (CF₃CO)₂O | (CH₃)₃Si—OCOCF₃ | 1.0 | HMDS | 0.5 | 2.0 |
| Ex. 2-2 | | | | | | | | | |
| Ex. 2-1 | none | none | HMDS | (CF₃CO)₂O | (CH₃)₃Si—OCOCF₃ | 2.5 | HMDS | 0.5 | 5.0 |
| Ex. 2-2 | none | none | HMDS | (CF₃CO)₂O | (CH₃)₃Si—OCOCF₃ | 3.5 | HMDS | 0.5 | 7.0 |
| Ex. 2-3 | none | none | HMDS | (CF₃CO)₂O | (CH₃)₃Si—OCOCF₃ | 5.0 | HMDS | 0.5 | 10.0 |
| Ex. 1-4 | none | none | HMDS | (CF₃CO)₂O | (CH₃)₃Si—OCOCF₃ | 10.0 | HMDS | 0.5 | 20.0 |
| Ex. 2-4 | none | none | HMDS | (CF₃CO)₂O | (CH₃)₃Si—OCOCF₃ | 11.5 | HMDS | 0.5 | 23.0 |
| Ex. 2-5 | none | none | HMDS | (CF₃CO)₂O | (CH₃)₃Si—OCOCF₃ | 12.5 | HMDS | 0.5 | 25.0 |
| Com. | none | none | HMDS | (CF₃CO)₂O | (CH₃)₃Si—OCOCF₃ | 0.1 | HMDS | 0.01 | 10.0 |
| Ex. 2-3 | | | | | | | | | |

| | | | | | | |
|---|---|---|---|---|---|---|
| Com. | Mix TMSIm and HMDS | none | 0.0 | TMSIm | 10.0 | 0.0 |
| Ex. 2-4 | | | | HMDS | 90.0 | |
| Com. | Mix TMSIm and HMDS | none | 0.0 | TMSIm | 1.0 | 0.0 |
| Ex. 2-5 | | | | HMDS | 9.0 | |

| | Protective Film-Forming | | | | | | | | |
|---|---|---|---|---|---|---|---|---|---|
| | Chemical liquid | | | | | | | | |
| | Composition after | | | | | | | | |
| | Liquid Preparation | | | Evaluation Results | | | | | |
| | | (II) | | Deposition of | | | | | |
| | (I) | Second | | Solid Matter by | | Contact Angle [°] | | | Resistance |
| | First | Solvent | | Addition of Given | | | After | Decrease by | of Vinyl |
| | Solvent | | Conc. | Amount of Water | | | Surface | Immersion | Chloride |
| | Kind | Kind | [mass %] | 2 μL | 4 μL | Initial | Treat. | in Hot Water | Resin |
| Com. | DiAE | TPGDME | 10.0 | not | not | <10 | 5 | 0 | fail |
| Ex. 2-1 | | | | observed | observed | | | | (discoloring) |
| Com. | DiAE | TPGDME | 10.0 | observed | observed | <10 | 84 | 2 | fail |
| Ex. 2-2 | | | | | | | | | (discoloring) |
| Ex. 2-1 | DiAE | TPGDME | 10.0 | not | observed | <10 | 87 | 1 | pass |
| | | | | observed | | | | | |
| Ex. 2-2 | DiAE | TPGDME | 10.0 | not | slightly | <10 | 88 | 0 | pass |
| | | | | observed | observed | | | | |
| Ex. 2-3 | DiAE | TPGDME | 10.0 | not | not | <10 | 89 | 0 | pass |
| | | | | observed | observed | | | | |
| Ex. 1-4 | DiAE | TPGDME | 10.0 | not | not | <10 | 90 | 0 | pass |
| | | | | observed | observed | | | | |
| Ex. 2-4 | DiAE | TPGDME | 10.0 | not | not | <10 | 91 | 1 | pass |
| | | | | observed | observed | | | | |
| Ex. 2-5 | DiAE | TPGDME | 10.0 | not | not | <10 | 91 | 1 | pass |
| | | | | observed | observed | | | | |
| Com. | DiAE | TPGDME | 10.0 | not | not | <10 | 37 | 1 | pass |
| Ex. 2-3 | | | | observed | observed | | | | |
| Com. | none | none | 0.0 | not | not | <10 | 85 | 0 | fail |
| Ex. 2-4 | | | | observed | observed | | | | (discoloring) |
| Com. | n- | none | 0.0 | observed | observed | <10 | 86 | 2 | fail |
| Ex. 2-5 | heptane | | | | | | | | (discoloring) |

### Comparative Example 2-4

A protective film-forming chemical liquid was prepared by mixing 10 g of trimethylsilyl imidazole (TMSIm) represented by the following formula [11] and 90 g of hexamethyldisilazane (HMDS) together. The wafer surface treatment was performed in the same manner as in Example 1-4, except that the above-prepared chemical liquid was used. The evaluation tests were then conducted in the same manner as above. The results are summarized in TABLE 2. Herein, Comparative Example 2-4 corresponds to an experimental example using a surface treatment liquid disclosed in Example 1 of Patent Document 1.

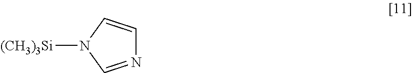

### Comparative Example 2-5

A protective film-forming chemical liquid was prepared by mixing 1 g of trimethylsilyl imidazole (TMSIm), 9 g of hexamethyldisilazane (HMDS) and 90 g of n-heptane (CH₃CH₂CH₂CH₂CH₂CH₂CH₃) together. The wafer surface treatment was performed in the same manner as in Example 1-4, except that the above-prepared chemical liquid was used. The evaluation tests were then conducted in the same manner as above. The results are summarized in TABLE 2. Herein, Comparative Example 2-5 corresponds to an experimental example using a surface treatment liquid disclosed in Example 19 of Patent Document 1.

### Examples 3-1 to 3-6 and Comparative Examples 3-1 to 3-3

The wafer surface treatment was performed in the same manner as in Example 1-4, except that the concentration of the base (IV) in the chemical liquid and the mass ratio of the silylation agent (III) to the base (IV) were changed by varying the amount of the silicon compound added. After that, the evaluation tests were conducted in the same manner as above. In each of Examples 3-1 to 3-6 and Comparative Examples 3-2 and 3-3, trimethylsilyl trifluoroacetate as the silylation agent and HMDS as the base were provided through reaction of HMDS and trifluoroacetic anhydride used as the starting raw materials; and HMDS contained in the protective film-forming chemical liquid was a residual amount of HMDS remaining unconsumed by the aforementioned silylation agent forming reaction. The results are summarized in TABLE 3.

TABLE 3

| | Protective Film-Forming Chemical Liquid | | | | | | | | |
|---|---|---|---|---|---|---|---|---|---|
| | Starting Materials for | | | | | | | | |
| | Silylation Agent and Base | | | | | | | | |
| | | | | Fluorine- | | | | | |
| | | | | Containing | Composition after Liquid Preparation | | | | |
| | | | | Carboxylic | (III) | | (IV) | | |
| | | | | Acid or | Silylation Agent | | Base | | (III)/(IV) |
| | Silylation | | Silicon | Anhydrate | | Conc. | | Conc. | Mass |
| | Agent | Base | Compound | thereof | Kind | [mass %] | Kind | [mass %] | Ratio |
| Com. | none | none | HMDS | (CF₃CO)₂O | (CH₃)₃Si—OCOCF₃ | 10.0 | none | 0.0 | — |
| Ex. 3-1 | | | | | | | | | |
| Com. | none | none | HMDS | (CF₃CO)₂O | (CH₃)₃Si—OCOCF₃ | 10.0 | HMDS | 0.01 | 1000.0 |
| Ex. 3-2 | | | | | | | | | |
| Ex. 3-1 | none | none | HMDS | (CF₃CO)₂O | (CH₃)₃Si—OCOCF₃ | 10.0 | HMDS | 0.06 | 166.7 |
| Ex. 3-2 | none | none | HMDS | (CF₃CO)₂O | (CH₃)₃Si—OCOCF₃ | 10.0 | HMDS | 0.09 | 111.1 |
| Ex. 3-3 | none | none | HMDS | (CF₃CO)₂O | (CH₃)₃Si—OCOCF₃ | 10.0 | HMDS | 0.15 | 66.7 |
| Ex. 1-4 | none | none | HMDS | (CF₃CO)₂O | (CH₃)₃Si—OCOCF₃ | 10.0 | HMDS | 0.5 | 20.0 |
| Ex. 3-4 | none | none | HMDS | (CF₃CO)₂O | (CH₃)₃Si—OCOCF₃ | 10.0 | HMDS | 0.9 | 11.1 |
| Ex. 3-5 | none | none | HMDS | (CF₃CO)₂O | (CH₃)₃Si—OCOCF₃ | 10.0 | HMDS | 1.4 | 7.1 |
| Ex. 3-6 | none | none | HMDS | (CF₃CO)₂O | (CH₃)₃Si—OCOCF₃ | 10.0 | HMDS | 1.8 | 5.6 |
| Com. | none | none | HMDS | (CF₃CO)₂O | (CH₃)₃Si—OCOCF₃ | 10.0 | HMDS | 2.5 | 4.0 |
| Ex. 3-3 | | | | | | | | | |

| | Protective Film-Forming | | | | | | | | |
|---|---|---|---|---|---|---|---|---|---|
| | Chemical Liquid | | | | | | | | |
| | Composition after | | | | | | | | |
| | Liquid Preparation | | | Evaluation Results | | | | | |
| | | (II) | | Deposition of | | | | | |
| | (I) | Second | | Solid Matter by | | Contact Angle [°] | | | Resistance |
| | First | Solvent | | Addition of Given | | | After | Decrease by | of Vinyl |
| | Solvent | | Conc. | Amount of Water | | | Surface | Immersion | Chloride |
| | Kind | Kind | [mass %] | 2 μL | 4 μL | Initial | Treat. | in Hot Water | Resin |
| Com. | DiAE | TPGDME | 10.0 | not | not | <10 | 10 | 0 | pass |
| Ex. 3-1 | | | | observed | observed | | | | |
| Com. | DiAE | TPGDME | 10.0 | not | not | <10 | 48 | 1 | pass |
| Ex. 3-2 | | | | observed | observed | | | | |
| Ex. 3-1 | DiAE | TPGDME | 10.0 | not | not | <10 | 74 | 1 | pass |
| | | | | observed | observed | | | | |
| Ex. 3-2 | DiAE | TPGDME | 10.0 | not | not | <10 | 86 | 0 | pass |
| | | | | observed | observed | | | | |
| Ex. 3-3 | DiAE | TPGDME | 10.0 | not | not | <10 | 89 | 1 | pass |
| | | | | observed | observed | | | | |
| Ex. 1-4 | DiAE | TPGDME | 10.0 | not | not | <10 | 90 | 0 | pass |
| | | | | observed | observed | | | | |
| Ex. 3-4 | DiAE | TPGDME | 10.0 | not | not | <10 | 91 | 0 | pass |
| | | | | observed | observed | | | | |
| Ex. 3-5 | DiAE | TPGDME | 10.0 | not | slightly | <10 | 91 | 0 | pass |
| | | | | observed | observed | | | | |
| Ex. 3-6 | DiAE | TPGDME | 10.0 | not | observed | <10 | 92 | 1 | pass |
| | | | | observed | | | | | |
| Com. | DiAE | TPGDME | 10.0 | observed | observed | <10 | 93 | 0 | fail |
| Ex. 3-3 | | | | | | | | | (discoloring) |

### Examples 4-1 to 4-10

The wafer surface treatment was performed in the same manner as in Example 1-4, except that the kinds and amounts of the starting raw materials used were changed. After that, the evaluation tests were conducted in the same manner as above. In each of Examples 4-1 to 4-4, the silylation agent and the base were provided through reaction of the silicon compound and the base used as the starting raw materials; and the base contained in the protective film-forming chemical liquid was a residual amount of the silicon compound remaining unconsumed by the aforementioned silylation agent forming reaction. In Examples 4-5 and 4-6, the silylation agent and the base were provided as the starting raw materials. In Example 4-8, trimethylsilyl trifluoroacetate as the silylation agent was provided through reaction of HMDS and trifluoroacetic anhydride used as the starting raw materials; and HMDS and TMSIm were used as the base. Herein, HMDS contained in the protective film-forming chemical liquid was a residual amount of HMDS remaining unconsumed by the aforementioned silylation agent forming reaction. In each of Examples 4-7, 4-9 and 4-10, the silicon compound was all consumed by reaction thereof with the fluorine-containing carboxylic acid anhydride and thus was not contained in the protective film-forming chemical liquid. The results are summarized in TABLE 4. In the table, the term “TMDS” refers to tetramethyldisilazane ([CH₃)₂Si(H)]₂NH); the term “DBTMDS” refers to dibutyltetramethyldisilazane ([(C₄H₉)Si(CH₃)₂]₂NH); the term “DOTMDS” refers to dioctyltetramethyldisilazane ([(C₈H₁₇)Si(CH₃)₂]₂NH); and the term “TMSPr” refers to trimethylsilyl pyrrolidine represented by the following formula [12].

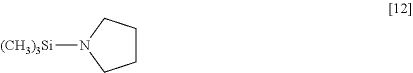

TABLE 4

| | Protective Film-Forming Chemical Liquid | | | | | | | | | | | |
|---|---|---|---|---|---|---|---|---|---|---|---|---|
| | Starting Materials for | | | | | | | | | | | |
| | Silylation Agent and Base | | | | Composition after Liquid Preparation | | | | | | | |
| | | | | Fluorine- | | | | | | | (II) | |
| | | | | Containing | (III) | | (IV) | | | (I) | Second | |
| | | | | Carboxylic | Silylation Agent | | Base | | (III)/ | First | Solvent | |
| | | | Silicon | Acid or | | Conc. | | Conc. | (IV) | Sol- | | Conc. |
| | Silylation | | Com- | Anhydrate | | [mass | | [mass | Mass | vent | | [mass |
| | Agent | Base | pound | thereof | Kind | %] | Kind | %] | Ratio | Kind | Kind | %] |
| Ex. | none | none | HMDS | (CF₃CO)₂O | (CH₃)₃Si—OCOCF₃ | 10.0 | HMDS | 0.5 | 20.0 | DiAE | TPGDME | 10.0 |
| 1-4 | | | | | | | | | | | | |
| Ex. | none | none | TMDS | (CF₃CO)₂O | (H)Si(CH₃)₂—OCOCF₃ | 10.0 | TMDS | 0.5 | 20.0 | DiAE | TPGDME | 10.0 |
| 4-1 | | | | | | | | | | | | |
| Ex. | none | none | DBT- | (CF₃CO)₂O | C₄H₉Si(CH₃)₂—OCOCF₃ | 10.0 | DBTMDS | 0.5 | 20.0 | DiAE | TPGDME | 10.0 |
| 4-2 | | | MDS | | | | | | | | | |
| Ex. | none | none | DOT- | (CF₃CO)₂O | C₈H₁₇Si(CH₃)₂—OCOCF₃ | 10.0 | DOTMDS | 0.5 | 20.0 | DiAE | TPGDME | 10.0 |
| 4-3 | | | MDS | | | | | | | | | |
| Ex. | none | none | HMDS | (C₄F₉CO)₂O | (CH₃)₃Si—OCOC₄F₉ | 10.0 | HMDS | 0.5 | 20.0 | DiAE | TPGDME | 10.0 |
| 4-4 | | | | | | | | | | | | |
| Ex. | (CH₃)₃Si—OCOCF₃ | HMDS | none | none | (CH₃)₃Si—OCOCF₃ | 10.0 | HMDS | 0.5 | 20.0 | DiAE | TPGDME | 10.0 |
| 4-5 | | | | | | | | | | | | |
| Ex. | (CH₃)₃Si—OCOCF₃ | TMSIm | none | none | (CH₃)₃Si—OCOCF₃ | 10.0 | TMSIm | 0.5 | 20.0 | DiAE | TPGDME | 10.0 |
| 4-6 | | | | | | | | | | | | |
| Ex. | none | TMSIm | HMDS | (CF₃CO)₂O | (CH₃)₃Si—OCOCF₃ | 10.0 | TMSIm | 0.15 | 66.7 | DiAE | TPGDME | 10.0 |
| 4-7 | | | | | | | | | | | | |
| Ex. | none | TMSIm | HMDS | (CF₃CO)₂O | (CH₃)₃Si—OCOCF₃ | 10.0 | TMSIm | 0.075 | 66.7 | DiAE | TPGDME | 10.0 |
| 4-8 | | | | | | | HMDS | 0.075 | | | | |
| Ex. | none | TMSPr | HMDS | (CF₃CO)₂O | (CH₃)₃Si—OCOCF₃ | 10.0 | TMSPr | 0.15 | 66.7 | DiAE | TPGDME | 10.0 |
| 4-9 | | | | | | | | | | | | |
| Ex. | none | TMSIm | HMDS | (C₄F₉CO)₂O | (CH₃)₃Si—OCOC₄F₉ | 10.0 | TMSIm | 0.15 | 66.7 | DiAE | TPGDME | 10.0 |
| 4-10 | | | | | | | | | | | | |

| | Evaluation Results | | | | | |
|---|---|---|---|---|---|---|
| | Deposition of | | | | | |
| | Solid Matter by | | Contact Angle [°] | | | |
| | Addition of Given | | | | Decrease by | Resistance of |
| | Amount of Water | | | After | Immersion | Vinyl Chloride |
| | 2 μL | 4 μL | Initial | Surface Treat. | in Hot Water | Resin |
| Ex. 1-4 | not observed | not observed | <10 | 90 | 0 | pass |
| Ex. 4-1 | not observed | not observed | <10 | 99 | 20 | pass |
| Ex. 4-2 | not observed | not observed | <10 | 100 | 2 | pass |
| Ex. 4-3 | not observed | not observed | <10 | 104 | 1 | pass |
| Ex. 4-4 | not observed | not observed | <10 | 89 | 0 | pass |
| Ex. 4-5 | not observed | not observed | <10 | 90 | 0 | pass |
| Ex. 4-6 | not observed | not observed | <10 | 93 | 0 | pass |
| Ex. 4-7 | not observed | not observed | <10 | 93 | 0 | pass |
| Ex. 4-8 | not observed | not observed | <10 | 92 | 1 | pass |
| Ex. 4-9 | not observed | not observed | <10 | 90 | 0 | pass |
| Ex. 4-10 | not observed | not observed | <10 | 92 | 0 | pass |

### Examples 5-1 to 5-5

The wafer surface treatment was performed in the same manner as in Example 1-4, except that the kind of the second solvent used was changed. After that, the evaluation tests were conducted in the same manner as above. The results are summarized in TABLE 5. In the table, the term “DPGMPE” refers to dipropylene glycol methyl propyl ether; the term “DPGDME” refers to dipropylene glycol dimethyl ether; the term “DEGDME” refers to diethylene glycol dimethyl ether; the term “DEGMEE” refers to diethylene glycol methyl ethyl ether; and the term “DEGDEE” refers to diethylene glycol diethyl ether.

TABLE 5

| | Protective Film-Forming Chemical Liquid | | | | | | | | | | | |
|---|---|---|---|---|---|---|---|---|---|---|---|---|
| | Starting Materials for | | | | | | | | | | | |
| | Silylation Agent and Base | | | | Composition after Liquid Preparation | | | | | | | |
| | | | | Fluorine- | | | | | | | (II) | |
| | | | | Containing | (III) | | (IV) | | | | Second | |
| | | | | Carboxylic | Silylation Agent | | Base | | | (I) | Solvent | |
| | | | Silicon | Acid or | | Conc. | | Conc. | (III)/(IV) | First | | Conc. |
| | Silylation | | Com- | Anhydrate | | [mass | | [mass | Mass | Solvent | | [mass |
| | Agent | Base | pound | thereof | Kind | %] | Kind | %] | Ratio | Kind | Kind | %] |
| Ex. 1-4 | none | none | HMDS | (CF₃CO)₂O | (CH₃)₃Si—OCOCF₃ | 10.0 | HMDS | 0.5 | 20.0 | DiAE | TPGDME | 10.0 |
| Ex. 5-1 | none | none | HMDS | (CF₃CO)₂O | (CH₃)₃Si—OCOCF₃ | 10.0 | HMDS | 0.5 | 20.0 | DiAE | DPGMPE | 10.0 |
| Ex. 5-2 | none | none | HMDS | (CF₃CO)₂O | (CH₃)₃Si—OCOCF₃ | 10.0 | HMDS | 0.5 | 20.0 | DiAE | DPGDME | 10.0 |
| Ex. 5-3 | none | none | HMDS | (CF₃CO)₂O | (CH₃)₃Si—OCOCF₃ | 10.0 | HMDS | 0.5 | 20.0 | DiAE | DEGDME | 10.0 |
| Ex. 5-4 | none | none | HMDS | (CF₃CO)₂O | (CH₃)₃Si—OCOCF₃ | 10.0 | HMDS | 0.5 | 20.0 | DiAE | DEGMEE | 10.0 |
| Ex. 5-5 | none | none | HMDS | (CF₃CO)₂O | (CH₃)₃Si—OCOCF₃ | 10.0 | HMDS | 0.5 | 20.0 | DiAE | DEGDEE | 10.0 |

| | Evaluation Results | | | | | |
|---|---|---|---|---|---|---|
| | Deposition of | | | | | |
| | Solid Matter by | | Contact Angle [°] | | | |
| | Addition of Given | | | | Decrease by | Resistance of |
| | Amount of Water | | | After | Immersion | Vinyl Chloride |
| | 2 μL | 4 μL | Initial | Surface Treat. | in Hot Water | Resin |
| Ex. 1-4 | not observed | not observed | <10 | 90 | 0 | pass |
| Ex. 5-1 | not observed | not observed | <10 | 90 | 0 | pass |
| Ex. 5-2 | not observed | not observed | <10 | 90 | 0 | pass |
| Ex. 5-3 | not observed | observed | <10 | 90 | 1 | pass |
| Ex. 5-4 | not observed | observed | <10 | 90 | 0 | pass |
| Ex. 5-5 | not observed | observed | <10 | 90 | 1 | pass |

### Example 6-1

A protective film-forming chemical liquid was prepared by mixing 8.7 g of hexamethyldisilazane (HMDS) as a silicon compound, 11.3 g of trifluoroacetic anhydride ((CF₃CO)₂O) as a fluorine-containing carboxylic acid anhydride, 78.35 g of isododecane ((CH₃)₃CCH₂CH(CH₃)CH₂C(CH₃)₃)) and 1.5 g of tripropylene glycol dimethyl ether (TPGDME), further mixing 0.15 g of trimethylsilyl imidazole (TMSIm) as a base, and reacting HMDS with trifluoroacetic anhydride. The thus-prepared protective film-forming chemical liquid contained trimethylsilyl trifluoroacetate as a silylation agent, TMSIm as a base, isododecane as a first solvent and TPGDME as a second solvent. In this Example, trimethylsilyl trifluoroacetate as the silylation agent was provided through reaction of HMDS and trifluoroacetic anhydride used as the starting raw materials; and HMDS as the silicon compound was all consumed by the aforementioned silylation agent forming reaction and thus was not contained in the protective film-forming chemical liquid. The wafer surface treatment was performed in the same manner as in Example 1-1, except that the above-prepared chemical liquid was used. The evaluation tests were then conducted in the same manner as above. The results are summarized in TABLE 6.

TABLE 6

| | Protective Film-Forming Chemical Liquid | | | | | | | | | | | |
|---|---|---|---|---|---|---|---|---|---|---|---|---|
| | Starting Materials for | | | | | | | | | | | |
| | Silylation Agent and Base | | | | Composition after Liquid Preparation | | | | | | | |
| | | | | Fluorine- | | | | | | | (II) | |
| | | | | Containing | (III) | | (IV) | | | | Second | |
| | | | | Carboxylic | Silylation Agent | | Base | | | (I) | Solvent | |
| | | | | Acid or | | Conc. | | Conc. | (III)/(IV) | First | | Conc. |
| | Silylation | | Silicon | Anhydrate | | [mass | | [mass | Mass | Solvent | | [mass |
| | Agent | Base | Compound | thereof | Kind | %] | Kind | %] | Ratio | Kind | Kind | %] |
| Comp. | none | TMSIm | HMDS | (CF₃CO)₂O | (CH₃)₃Si—OCOCF₃ | 10.0 | TMSIm | 0.15 | 66.7 | isodo- | none | 0.0 |
| Ex. 6-1 | | | | | | | | | | decane | | |
| Comp. | none | TMSIm | HMDS | (CF₃CO)₂O | (CH₃)₃Si—OCOCF₃ | 10.0 | TMSIm | 0.15 | 66.7 | isodo- | TPGDME | 0.1 |
| Ex. 6-2 | | | | | | | | | | decane | | |
| Ex. 6-1 | none | TMSIm | HMDS | (CF₃CO)₂O | (CH₃)₃Si—OCOCF₃ | 10.0 | TMSIm | 0.15 | 66.7 | isodo- | TPGDME | 1.5 |
| | | | | | | | | | | decane | | |
| Ex. 6-2 | none | TMSIm | HMDS | (CF₃CO)₂O | (CH₃)₃Si—OCOCF₃ | 10.0 | TMSIm | 0.15 | 66.7 | isodo- | TPGDME | 2.5 |
| | | | | | | | | | | decane | | |
| Ex. 6-3 | none | TMSIm | HMDS | (CF₃CO)₂O | (CH₃)₃Si—OCOCF₃ | 10.0 | TMSIm | 0.15 | 66.7 | isodo- | TPGDME | 5.0 |
| | | | | | | | | | | decane | | |
| Ex. 6-4 | none | TMSIm | HMDS | (CF₃CO)₂O | (CH₃)₃Si—OCOCF₃ | 10.0 | TMSIm | 0.15 | 66.7 | isodo- | TPGDME | 10.0 |
| | | | | | | | | | | decane | | |
| Ex. 6-5 | none | TMSIm | HMDS | (CF₃CO)₂O | (CH₃)₃Si—OCOCF₃ | 10.0 | TMSIm | 0.15 | 66.7 | isodo- | TPGDME | 17.0 |
| | | | | | | | | | | decane | | |
| Ex. 6-6 | none | TMSIm | HMDS | (CF₃CO)₂O | (CH₃)₃Si—OCOCF₃ | 10.0 | TMSIm | 0.15 | 66.7 | isodo- | TPGDME | 25.0 |
| | | | | | | | | | | decane | | |
| Comp. | none | TMSIm | HMDS | (CF₃CO)₂O | (CH₃)₃Si—OCOCF₃ | 10.0 | TMSIm | 0.15 | 66.7 | isodo- | TPGDME | 35.0 |
| Ex. 6-3 | | | | | | | | | | decane | | |

| | Evaluation Results | | | | | |
|---|---|---|---|---|---|---|
| | Deposition of | | | | | |
| | Solid Matter by | | Contact Angle [°] | | | |
| | Addition of Given | | | | Decrease by | Resistance of |
| | Amount of Water | | | After | Immersion | Vinyl Chloride |
| | 2 μL | 4 μL | Initial | Surface Treat. | in Hot Water | Resin |
| Comp. | observed | observed | <10 | 93 | 0 | pass |
| Ex. 6-1 | | | | | | |
| Comp. | observed | observed | <10 | 93 | 1 | pass |
| Ex. 6-2 | | | | | | |
| Ex. 6-1 | not observed | observed | <10 | 93 | 0 | pass |
| Ex. 6-2 | not observed | slightly observed | <10 | 93 | 0 | pass |
| Ex. 6-3 | not observed | not observed | <10 | 93 | 0 | pass |
| Ex. 6-4 | not observed | not observed | <10 | 93 | 1 | pass |
| Ex. 6-5 | not observed | not observed | <10 | 93 | 0 | pass |
| Ex. 6-6 | not observed | not observed | <10 | 93 | 0 | pass |
| Comp. | not observed | not observed | <10 | 93 | 1 | fail (swelling) |
| Ex. 6-3 | | | | | | |

### Examples 6-2 to 6-6 and Comparative Examples 6-1 to 6-3

The wafer surface treatment was performed in the same manner as in Example 6-1, except that the concentration of the second solvent in the chemical liquid was changed. After that, the evaluation tests were conducted in the same manner as above. In each of Examples 6-2 to 6-6 and Comparative Examples 6-1 to 6-3, trimethylsilyl trifluoroacetate as the silylation agent was provided through reaction of HMDS and trifluoroacetic anhydride used as the starting raw materials; and HMDS was all consumed by the aforementioned silylation agent forming reaction and thus was not contained in the protective film-forming chemical liquid. The results are summarized in TABLE 6.

### Examples 7-1 to 7-7 and Comparative Examples 7-1 to 7-3

The wafer surface treatment was performed in the same manner as in Example 6-4, except that the concentrations of the silylation agent (III) and the base (IV) in the chemical liquid and the mass ratio of the silylation agent (III) to the base (IV) were changed by varying the amount of the base added, the amount of the silicon compound added and the amount of the fluorine-containing carboxylic acid anhydride added. After that, the evaluation tests were conducted in the same manner as above. In each of Examples 7-1 to 7-7 and Comparative Examples 7-2 and 7-3, trimethylsilyl trifluoroacetate as the silylation agent was provided through reaction of HMDS and trifluoroacetic anhydride used as the starting raw materials; and HMDS was all consumed by the aforementioned silylation agent forming reaction and thus was not contained in the protective film-forming chemical liquid. The results are summarized in TABLE 7.

TABLE 7

| | Protective Film-Forming Chemical Liquid | | | | | | | | |
|---|---|---|---|---|---|---|---|---|---|
| | Starting Materials for | | | | | | | | |
| | Silylation Agent and Base | | | | | | | | |
| | | | | Fluorine- | | | | | |
| | | | | Containing | Composition after Liquid Preparation | | | | |
| | | | | Carboxylic | (III) | | (IV) | | |
| | | | | Acid or | Silylation Agent | | Base | | (III)/(IV) |
| | Silylation | | Silicon | Anhydrate | | Conc. | | Conc. | Mass |
| | Agent | Base | Compound | thereof | Kind | [mass %] | Kind | [mass %] | Ratio |
| Comp. | none | TMSIm | none | none | none | 0.0 | TMSIm | 0.15 | 0.0 |
| Ex. 7-1 | | | | | | | | | |
| Comp. | none | TMSIm | HMDS | (CF₃CO)₂O | (CH₃)₃Si—OCOCF₃ | 0.3 | TMSIm | 0.15 | 2.0 |
| Ex. 7-2 | | | | | | | | | |
| Ex. 7-1 | none | TMSIm | HMDS | (CF₃CO)₂O | (CH₃)₃Si—OCOCF₃ | 2.5 | TMSIm | 0.5 | 5.0 |
| Ex. 7-2 | none | TMSIm | HMDS | (CF₃CO)₂O | (CH₃)₃Si—OCOCF₃ | 2.5 | TMSIm | 0.36 | 6.9 |
| Ex. 7-3 | none | TMSIm | HMDS | (CF₃CO)₂O | (CH₃)₃Si—OCOCF₃ | 2.5 | TMSIm | 0.15 | 16.7 |
| Ex. 7-4 | none | TMSIm | HMDS | (CF₃CO)₂O | (CH₃)₃Si—OCOCF₃ | 3.5 | TMSIm | 0.15 | 23.3 |
| Ex. 7-5 | none | TMSIm | HMDS | (CF₃CO)₂O | (CH₃)₃Si—OCOCF₃ | 5.0 | TMSIm | 0.15 | 33.3 |
| Ex. 6-4 | none | TMSIm | HMDS | (CF₃CO)₂O | (CH₃)₃Si—OCOCF₃ | 10.0 | TMSIm | 0.15 | 66.7 |
| Ex. 7-6 | none | TMSIm | HMDS | (CF₃CO)₂O | (CH₃)₃Si—OCOCF₃ | 11.5 | TMSIm | 0.15 | 76.7 |
| Ex. 7-7 | none | TMSIm | HMDS | (CF₃CO)₂O | (CH₃)₃Si—OCOCF₃ | 12.5 | TMSIm | 0.15 | 83.3 |
| Comp. | none | TMSIm | HMDS | (CF₃CO)₂O | (CH₃)₃Si—OCOCF₃ | 0.1 | TMSIm | 0.01 | 10.0 |
| Ex. 7-3 | | | | | | | | | |

| | Protective Film-Forming | | | | | | | | |
|---|---|---|---|---|---|---|---|---|---|
| | Chemical Liquid | | | | | | | | |
| | Composition after | | | | | | | | |
| | Liquid Preparation | | | Evaluation Results | | | | | |
| | | (II) | | Deposition of | | | | | |
| | (I) | Second | | Solid Matter by | | Contact Angle [°] | | | Resistance |
| | First | Solvent | | Addition of Given | | | After | Decrease by | of Vinyl |
| | Solvent | | Conc. | Amount of Water | | | Surface | Immersion | Chloride |
| | Kind | Kind | [mass %] | 2 μL | 4 μL | Initial | Treat. | in Hot Water | Resin |
| Comp. | isododecane | TPGDME | 10.0 | observed | observed | <10 | 45 | 1 | fail |
| Ex. 7-1 | | | | | | | | | (discoloring) |
| Comp. | isododecane | TPGDME | 10.0 | observed | observed | <10 | 81 | 0 | fail |
| Ex. 7-2 | | | | | | | | | (discoloring) |
| Ex. 7-1 | isododecane | TPGDME | 10.0 | not | observed | <10 | 91 | 0 | pass |
| | | | | observed | | | | | |
| Ex. 7-2 | isododecane | TPGDME | 10.0 | not | slightly | <10 | 90 | 1 | pass |
| | | | | observed | observed | | | | |
| Ex. 7-3 | isododecane | TPGDME | 10.0 | not | not | <10 | 89 | 0 | pass |
| | | | | observed | observed | | | | |
| Ex. 7-4 | isododecane | TPGDME | 10.0 | not | not | <10 | 90 | 1 | pass |
| | | | | observed | observed | | | | |
| Ex. 7-5 | isododecane | TPGDME | 10.0 | not | not | <10 | 92 | 0 | pass |
| | | | | observed | observed | | | | |
| Ex. 6-4 | isododecane | TPGDME | 10.0 | not | not | <10 | 93 | 1 | pass |
| | | | | observed | observed | | | | |
| Ex. 7-6 | isododecane | TPGDME | 10.0 | not | not | <10 | 93 | 1 | pass |
| | | | | observed | observed | | | | |
| Ex. 7-7 | isododecane | TPGDME | 10.0 | not | not | <10 | 93 | 0 | pass |
| | | | | observed | observed | | | | |
| Comp. | isododecane | TPGDME | 10.0 | not | not | <10 | 44 | 0 | pass |
| Ex. 7-3 | | | | observed | observed | | | | |

### Examples 8-1 to 8-6 and Comparative Examples 8-1 to 8-3

The wafer surface treatment was performed in the same manner as in Example 6-4, except that the concentration of the base (IV) in the chemical liquid and the mass ratio of the silylation agent (III) to the base (IV) was changed by varying the amount of the base added. After that, the evaluation tests were conducted in the same manner as above. In each of Examples 8-1 to 8-6 and Comparative Examples 8-1 to 8-3, trimethylsilyl trifluoroacetate as the silylation agent was provided through reaction of HMDS and trifluoroacetic anhydride used as the starting raw materials; and HMDS was all consumed by the aforementioned silylation agent forming reaction and thus was not contained in the protective film-forming chemical liquid. The results are summarized in TABLE 8.

TABLE 8

| | Protective Film-Forming Chemical Liquid | | | | | | | | |
|---|---|---|---|---|---|---|---|---|---|
| | Starting Materials for | | | | | | | | |
| | Silylation Agent and Base | | | | | | | | |
| | | | | Fluorine- | | | | | |
| | | | | Containing | Composition after Liquid Preparation | | | | |
| | | | | Carboxylic | (III) | | (IV) | | |
| | | | | Acid or | Silylation Agent | | Base | | (III)/(IV) |
| | Silylation | | Silicon | Anhydrate | | Conc. | | Conc. | Mass |
| | Agent | Base | Compound | thereof | Kind | [mass %] | Kind | [mass %] | Ratio |
| Comp. | none | none | HMDS | (CF₃CO)₂O | (CH₃)₃Si—OCOCF₃ | 10.0 | none | 0.0 | — |
| Ex. 8-1 | | | | | | | | | |
| Comp. | none | TMSIm | HMDS | (CF₃CO)₂O | (CH₃)₃Si—OCOCF₃ | 10.0 | TMSIm | 0.01 | 1000.0 |
| Ex. 8-2 | | | | | | | | | |
| Ex. 8-1 | none | TMSIm | HMDS | (CF₃CO)₂O | (CH₃)₃Si—OCOCF₃ | 10.0 | TMSIm | 0.06 | 166.7 |
| Ex. 8-2 | none | TMSIm | HMDS | (CF₃CO)₂O | (CH₃)₃Si—OCOCF₃ | 10.0 | TMSIm | 0.09 | 111.1 |
| Ex. 6-4 | none | TMSIm | HMDS | (CF₃CO)₂O | (CH₃)₃Si—OCOCF₃ | 10.0 | TMSIm | 0.15 | 66.7 |
| Ex. 8-3 | none | TMSIm | HMDS | (CF₃CO)₂O | (CH₃)₃Si—OCOCF₃ | 10.0 | TMSIm | 0.5 | 20.0 |
| Ex. 8-4 | none | TMSIm | HMDS | (CF₃CO)₂O | (CH₃)₃Si—OCOCF₃ | 10.0 | TMSIm | 0.9 | 11.1 |
| Ex. 8-5 | none | TMSIm | HMDS | (CF₃CO)₂O | (CH₃)₃Si—OCOCF₃ | 10.0 | TMSIm | 1.4 | 7.1 |
| Ex. 8-6 | none | TMSIm | HMDS | (CF₃CO)₂O | (CH₃)₃Si—OCOCF₃ | 10.0 | TMSIm | 1.8 | 5.6 |
| Comp. | none | TMSIm | HMDS | (CF₃CO)₂O | (CH₃)₃Si—OCOCF₃ | 10.0 | TMSIm | 2.5 | 4.0 |
| Ex. 8-3 | | | | | | | | | |

| | Protective Film-Forming | | | | | | | | |
|---|---|---|---|---|---|---|---|---|---|
| | Chemical Liquid | | | | | | | | |
| | Composition after | | | | | | | | |
| | Liquid Preparation | | | Evaluation Results | | | | | |
| | | (II) | | Deposition of | | | | | |
| | (I) | Second | | Solid Matter by | | Contact Angle [°] | | | Resistance |
| | First | Solvent | | Addition of Given | | | After | Decrease by | of Vinyl |
| | Solvent | | Conc. | Amount of Water | | | Surface | Immersion | Chloride |
| | Kind | Kind | [mass %] | 2 μL | 4 μL | Initial | Treat. | in Hot Water | Resin |
| Comp. | isododecane | TPGDME | 10.0 | not | not | <10 | 10 | 0 | pass |
| Ex. 8-1 | | | | observed | observed | | | | |
| Comp. | isododecane | TPGDME | 10.0 | not | not | <10 | 58 | 1 | pass |
| Ex. 8-2 | | | | observed | observed | | | | |
| Ex. 8-1 | isododecane | TPGDME | 10.0 | not | not | <10 | 85 | 1 | pass |
| | | | | observed | observed | | | | |
| Ex. 8-2 | isododecane | TPGDME | 10.0 | not | not | <10 | 90 | 1 | pass |
| | | | | observed | observed | | | | |
| Ex. 6-4 | isododecane | TPGDME | 10.0 | not | not | <10 | 93 | 1 | pass |
| | | | | observed | observed | | | | |
| Ex. 8-3 | isododecane | TPGDME | 10.0 | not | not | <10 | 93 | 0 | pass |
| | | | | observed | observed | | | | |
| Ex. 8-4 | isododecane | TPGDME | 10.0 | not | not | <10 | 93 | 0 | pass |
| | | | | observed | observed | | | | |
| Ex. 8-5 | isododecane | TPGDME | 10.0 | not | slightly | <10 | 94 | 0 | pass |
| | | | | observed | observed | | | | |
| Ex. 8-6 | isododecane | TPGDME | 10.0 | not | observed | <10 | 94 | 0 | pass |
| | | | | observed | | | | | |
| Comp. | isododecane | TPGDME | 10.0 | observed | observed | <10 | 95 | 0 | fail |
| Ex. 8-3 | | | | | | | | | (discoloring) |

### Examples 9-1 to 9-1

The wafer surface treatment was performed in the same manner as in Examples 1-4, 4-1 to 4-10, except that the first solvent was changed to isododedane. After that, the evaluation tests were conducted in the same manner as above. The results are summarized in TABLE 9.

TABLE 9

| | Protective Film-Forming Chemical Liquid | | | | | | | |
|---|---|---|---|---|---|---|---|---|
| | Starting Materials for | | | | | | | |
| | Silylation Agent and Base | | | | | | | |
| | | | | Fluorine- | | | | |
| | | | | Containing | Composition after Liquid Preparation | | | |
| | | | | Carboxylic | (III) | | (IV) | |
| | | | | Acid or | Silylation Agent | | Base | |
| | Silylation | | Silicon | Anhydrate | | Conc. | | Conc. |
| | Agent | Base | Compound | thereof | Kind | [mass %] | Kind | [mass %] |
| Ex. 9-1 | none | none | HMDS | (CF₃CO)₂O | (CH₃)₃Si—OCOCF₃ | 10.0 | HMDS | 0.5 |
| Ex. 9-2 | none | none | TMDS | (CF₃CO)₂O | (H)Si(CH₃)₂—OCOCF₃ | 10.0 | TMDS | 0.5 |
| Ex. 9-3 | none | none | DBTMDS | (CF₃CO)₂O | C₄H₉Si(CH₃)₂—OCOCF₃ | 10.0 | DBTMDS | 0.5 |
| Ex. 9-4 | none | none | DOTMDS | (CF₃CO)₂O | C₈H₁₇Si(CH₃)₂—OCOCF₃ | 10.0 | DOTMDS | 0.5 |
| Ex. 9-5 | none | none | HMDS | (C₄F₉CO)₂O | (CH₃)₃Si—OCOCF₄F₉ | 10.0 | HMDS | 0.5 |
| Ex. 9-6 | (CH₃)₃Si—OCOCF₃ | HMDS | none | none | (CH₃)₃Si—OCOCF₃ | 10.0 | HMDS | 0.5 |
| Ex. 9-7 | (CH₃)₃Si—OCOCF₃ | TMSIm | none | none | (CH₃)₃Si—OCOCF₃ | 10.0 | TMSIm | 0.5 |
| Ex. 6-4 | none | TMSIm | HMDS | (CF₃CO)₂O | (CH₃)₃Si—OCOCF₃ | 10.0 | TMSIm | 0.15 |
| Ex. 9-8 | none | TMSIm | HMDS | (CF₃CO)₂O | (CH₃)₃Si—OCOCF₃ | 10.0 | TMSIm | 0.075 |
| | | | | | | | HMDS | 0.075 |
| Ex. 9-9 | none | TMSPr | HMDS | (CF₃CO)₂O | (CH₃)₃Si—OCOCF₃ | 10.0 | TMSPr | 0.15 |
| Ex. 9-10 | none | TMSIm | HMDS | (C₄F₉CO)₂O | (CH₃)₃Si—OCOCF₄F₉ | 10.0 | TMSIm | 0.15 |

| | Protective | | | | | | | | | |
|---|---|---|---|---|---|---|---|---|---|---|
| | Film-Forming Chemical Liquid | | | | | | | | | |
| | Composition after Liquid Preparation | | | | Evaluation Results | | | | | |
| | | | (II) | | Deposition of | | | | | |
| | | (I) | Second | | Solid Matter by | | Contact Angle [°] | | | Resistance |
| | (III)/(IV) | First | Solvent | | Addition of Given | | | After | Decrease by | of Vinyl |
| | Mass | Solvent | | Conc. | Amount of Water | | | Surface | Immersion | Chloride |
| | Ratio | Kind | Kind | [mass %] | 2 μL | 4 μL | Initial | Treat. | in Hot Water | Resin |
| Ex. 9-1 | 20.0 | isododecane | TPGDME | 10.0 | not | not | <10 | 90 | 0 | pass |
| | | | | | observed | observed | | | | |
| Ex. 9-2 | 20.0 | isododecane | TPGDME | 10.0 | not | not | <10 | 99 | 20 | pass |
| | | | | | observed | observed | | | | |
| Ex. 9-3 | 20.0 | isododecane | TPGDME | 10.0 | not | not | <10 | 100 | 2 | pass |
| | | | | | observed | observed | | | | |
| Ex. 9-4 | 20.0 | isododecane | TPGDME | 10.0 | not | not | <10 | 104 | 1 | pass |
| | | | | | observed | observed | | | | |
| Ex. 9-5 | 20.0 | isododecane | TPGDME | 10.0 | not | not | <10 | 89 | 0 | pass |
| | | | | | observed | observed | | | | |
| Ex. 9-6 | 20.0 | isododecane | TPGDME | 10.0 | not | not | <10 | 90 | 0 | pass |
| | | | | | observed | observed | | | | |
| Ex. 9-7 | 20.0 | isododecane | TPGDME | 10.0 | not | not | <10 | 93 | 0 | pass |
| | | | | | observed | observed | | | | |
| Ex. 6-4 | 66.7 | isododecane | TPGDME | 10.0 | not | not | <10 | 93 | 1 | pass |
| | | | | | observed | observed | | | | |
| Ex. 9-8 | 66.7 | isododecane | TPGDME | 10.0 | not | not | <10 | 92 | 1 | pass |
| | | | | | observed | observed | | | | |
| Ex. 9-9 | 66.7 | isododecane | TPGDME | 10.0 | not | not | <10 | 90 | 0 | pass |
| | | | | | observed | observed | | | | |
| Ex. 9-10 | 66.7 | isododecane | TPGDME | 10.0 | not | not | <10 | 92 | 0 | pass |
| | | | | | observed | observed | | | | |

### Examples 10-1 to 10-5

The wafer surface treatment was performed in the same manner as in Example 6-4, except that the kind of the second solvent used was changed. After that, the evaluation tests were conducted in the same manner as above. The results are summarized in TABLE 10.

TABLE 10

| | Protective Film-Forming Chemical Liquid | | | | | | | | | | | |
|---|---|---|---|---|---|---|---|---|---|---|---|---|
| | Starting Materials for | | | | | | | | | | | |
| | Silylation Agent and Base | | | | Composition after Liquid Preparation | | | | | | | |
| | | | | Fluorine- | | | | | | | (II) | |
| | | | | Containing | (III) | | (IV) | | | | Second | |
| | | | | Carboxylic | Silylation Agent | | Base | | | (I) | Solvent | |
| | | | | Acid or | | Conc. | | Conc. | (III)/(IV) | First | | Conc. |
| | Silylation | | Silicon | Anhydrate | | [mass | | [mass | Mass | Solvent | | [mass |
| | Agent | Base | Compound | thereof | Kind | %] | Kind | %] | Ratio | Kind | Kind | %] |
| Ex. 6-4 | none | TMSIm | HMDS | (CF₃CO)₂O | (CH₃)₃Si—OCOCF₃ | 10.0 | TMSIm | 0.15 | 66.7 | isodo- | TPGDME | 10.0 |
| | | | | | | | | | | decane | | |
| Ex. 10-1 | none | TMSIm | HMDS | (CF₃CO)₂O | (CH₃)₃Si—OCOCF₃ | 10.0 | TMSIm | 0.15 | 66.7 | isodo- | DPGMPE | 10.0 |
| | | | | | | | | | | decane | | |
| Ex. 10-2 | none | TMSIm | HMDS | (CF₃CO)₂O | (CH₃)₃Si—OCOCF₃ | 10.0 | TMSIm | 0.15 | 66.7 | isodo- | DPGDME | 10.0 |
| | | | | | | | | | | decane | | |
| Ex. 10-3 | none | TMSIm | HMDS | (CF₃CO)₂O | (CH₃)₃Si—OCOCF₃ | 10.0 | TMSIm | 0.15 | 66.7 | isodo- | DEGDME | 10.0 |
| | | | | | | | | | | decane | | |
| Ex. 10-4 | none | TMSIm | HMDS | (CF₃CO)₂O | (CH₃)₃Si—OCOCF₃ | 10.0 | TMSIm | 0.15 | 66.7 | isodo- | DEGMEE | 10.0 |
| | | | | | | | | | | decane | | |
| Ex. 10-5 | none | TMSIm | HMDS | (CF₃CO)₂O | (CH₃)₃Si—OCOCF₃ | 10.0 | TMSIm | 0.15 | 66.7 | isodo- | DEGDEE | 10.0 |
| | | | | | | | | | | decane | | |

| | Evaluation Results | | | | | |
|---|---|---|---|---|---|---|
| | Deposition | | | | | |
| | of Solid | | | | | |
| | Matter by | | | | | |
| | Addition of | | Contact Angle [°] | | | |
| | Given Amount | | | | Decrease by | Resistance of |
| | of Water | | | After | Immersion | Vinyl Chloride |
| | 2 μL | 4 μL | Initial | Surface Treat. | in Hot Water | Resin |
| Ex. 6-4 | not observed | not observed | <10 | 93 | 1 | pass |
| Ex. 10-1 | not observed | not observed | <10 | 93 | 0 | pass |
| Ex. 10-2 | not observed | not observed | <10 | 93 | 0 | pass |
| Ex. 10-3 | not observed | observed | <10 | 93 | 0 | pass |
| Ex. 10-4 | not observed | observed | <10 | 93 | 1 | pass |
| Ex. 10-5 | not observed | observed | <10 | 93 | 1 | pass |

### Examples 11-1 to 11-5 and Comparative Examples 11-1 to 11-3

The wafer surface treatment was performed in the same manner as in Examples 1-1 to 1-3, 1-5, 1-6 and Comparative Examples 1-1 to 1-3, except that the first solvent was changed to isododedane. After that, the evaluation tests were conducted in the same manner as above. The results are summarized in TABLE 11.

TABLE 11

| | Protective Film-Forming Chemical Liquid | | | | | | | | | | | |
|---|---|---|---|---|---|---|---|---|---|---|---|---|
| | Starting Materials for | | | | | | | | | | | |
| | Silylation Agent and Base | | | | Composition after Liquid Preparation | | | | | | | |
| | | | | Fluorine- | | | | | | | (II) | |
| | | | | Containing | (III) | | (IV) | | | | Second | |
| | | | | Carboxylic | Silylation Agent | | Base | | | (I) | Solvent | |
| | | | | Acid or | | Conc. | | Conc. | (III)/(IV) | First | | Conc. |
| | Silylation | | Silicon | Anhydrate | | [mass | | [mass | Mass | Solvent | | [mass |
| | Agent | Base | Compound | thereof | Kind | %] | Kind | %] | Ratio | Kind | Kind | %] |
| Comp. | none | none | HMDS | (CF₃CO)₂O | (CH₃)₃Si—OCOCF₃ | 10.0 | HMDS | 0.5 | 20.0 | isodo- | none | 0.0 |
| Ex. 11-1 | | | | | | | | | | decane | | |
| Comp. | none | none | HMDS | (CF₃CO)₂O | (CH₃)₃Si—OCOCF₃ | 10.0 | HMDS | 0.5 | 20.0 | isodo- | TPGDME | 0.1 |
| Ex. 11-2 | | | | | | | | | | decane | | |
| Ex. 11-1 | none | none | HMDS | (CF₃CO)₂O | (CH₃)₃Si—OCOCF₃ | 10.0 | HMDS | 0.5 | 20.0 | isodo- | TPGDME | 1.5 |
| | | | | | | | | | | decane | | |
| Ex. 11-2 | none | none | HMDS | (CF₃CO)₂O | (CH₃)₃Si—OCOCF₃ | 10.0 | HMDS | 0.5 | 20.0 | isodo- | TPGDME | 2.5 |
| | | | | | | | | | | decane | | |
| Ex. 11-3 | none | none | HMDS | (CF₃CO)₂O | (CH₃)₃Si—OCOCF₃ | 10.0 | HMDS | 0.5 | 20.0 | isodo- | TPGDME | 5.0 |
| | | | | | | | | | | decane | | |
| Ex. 9-1 | none | none | HMDS | (CF₃CO)₂O | (CH₃)₃Si—OCOCF₃ | 10.0 | HMDS | 0.5 | 20.0 | isodo- | TPGDME | 10.0 |
| | | | | | | | | | | decane | | |
| Ex. 11-4 | none | none | HMDS | (CF₃CO)₂O | (CH₃)₃Si—OCOCF₃ | 10.0 | HMDS | 0.5 | 20.0 | isodo- | TPGDME | 17.0 |
| | | | | | | | | | | decane | | |
| Ex. 11-5 | none | none | HMDS | (CF₃CO)₂O | (CH₃)₃Si—OCOCF₃ | 10.0 | HMDS | 0.5 | 20.0 | isodo- | TPGDME | 25.0 |
| | | | | | | | | | | decane | | |
| Comp. | none | none | HMDS | (CF₃CO)₂O | (CH₃)₃Si—OCOCF₃ | 10.0 | HMDS | 0.5 | 20.0 | isodo- | TPGDME | 35.0 |
| Ex. 11-3 | | | | | | | | | | decane | | |

| | Evaluation Results | | | | | |
|---|---|---|---|---|---|---|
| | Deposition | | | | | |
| | of Solid Matter by | | Contact angle [°] | | | |
| | Addition of Given Amount | | | | Decrease by | Resistance of |
| | of Water | | | After | Immersion | Vinyl Chloride |
| | 2 μL | 4 μL | Initial | Surface Treat. | in Hot Water | Resin |
| Comp. | observed | observed | <10 | 90 | 1 | pass |
| Ex. 11-1 | | | | | | |
| Comp. | observed | observed | <10 | 90 | 0 | pass |
| Ex. 11-2 | | | | | | |
| Ex. 11-1 | not observed | observed | <10 | 90 | 1 | pass |
| Ex. 11-2 | not observed | slightly observed | <10 | 90 | 1 | pass |
| Ex. 11-3 | not observed | not observed | <10 | 90 | 0 | pass |
| Ex. 9-1 | not observed | not observed | <10 | 90 | 0 | pass |
| Ex. 11-4 | not observed | not observed | <10 | 90 | 0 | pass |
| Ex. 11-5 | not observed | not observed | <10 | 90 | 1 | pass |
| Comp. | not observed | not observed | <10 | 90 | 0 | fail (swelling) |
| Ex. 11-3 | | | | | | |

### Examples 12-1 to 12-5 and Comparative Examples 12-1 to 12-3

The wafer surface treatment was performed in the same manner as in Examples 2-1 to 2-5 and Comparative Examples 2-1 to 2-3, except that the first solvent was changed to isododedane. After that, the evaluation tests were conducted in the same manner as above. The results are summarized in TABLE 12.

TABLE 12

| | Protective Film-Forming Chemical Liquid | | | | | | | | | | | |
|---|---|---|---|---|---|---|---|---|---|---|---|---|
| | Starting Materials for | | | | | | | | | | | |
| | Silylation Agent and Base | | | | Composition after Liquid Preparation | | | | | | | |
| | | | | Fluorine- | | | | | | | (II) | |
| | | | | Containing | (III) | | (IV) | | | | Second | |
| | | | | Carboxylic | Silylation Agent | | Base | | | (I) | Solvent | |
| | | | | Acid or | | Conc. | | Conc. | (III)/(IV) | First | | Conc. |
| | Silylation | | Silicon | Anhydrate | | [mass | | [mass | Mass | Solvent | | [mass |
| | Agent | Base | Compound | thereof | Kind | %] | Kind | %] | Ratio | Kind | Kind | %] |
| Comp. | none | none | HMDS | none | none | 0.0 | HMDS | 0.5 | 0.0 | isodo- | TPGDME | 10.0 |
| Ex. 12-1 | | | | | | | | | | decane | | |
| Comp. | none | none | HMDS | (CF₃CO)₂O | (CH₃)₃Si—OCOCF₃ | 1.0 | HMDS | 0.5 | 2.0 | isodo- | TPGDME | 10.0 |
| Ex. 12-2 | | | | | | | | | | decane | | |
| Ex. 12-1 | none | none | HMDS | (CF₃CO)₂O | (CH₃)₃Si—OCOCF₃ | 2.5 | HMDS | 0.5 | 5.0 | isodo- | TPGDME | 10.0 |
| | | | | | | | | | | decane | | |
| Ex. 12-2 | none | none | HMDS | (CF₃CO)₂O | (CH₃)₃Si—OCOCF₃ | 3.5 | HMDS | 0.5 | 7.0 | isodo- | TPGDME | 10.0 |
| | | | | | | | | | | decane | | |
| Ex. 12-3 | none | none | HMDS | (CF₃CO)₂O | (CH₃)₃Si—OCOCF₃ | 5.0 | HMDS | 0.5 | 10.0 | isodo- | TPGDME | 10.0 |
| | | | | | | | | | | decane | | |
| Ex. 9-1 | none | none | HMDS | (CF₃CO)₂O | (CH₃)₃Si—OCOCF₃ | 10.0 | HMDS | 0.5 | 20.0 | isodo- | TPGDME | 10.0 |
| | | | | | | | | | | decane | | |
| Ex. 12-4 | none | none | HMDS | (CF₃CO)₂O | (CH₃)₃Si—OCOCF₃ | 11.5 | HMDS | 0.5 | 23.0 | isodo- | TPGDME | 10.0 |
| | | | | | | | | | | decane | | |
| Ex. 12-5 | none | none | HMDS | (CF₃CO)₂O | (CH₃)₃Si—OCOCF₃ | 12.5 | HMDS | 0.5 | 25.0 | isodo- | TPGDME | 10.0 |
| | | | | | | | | | | decane | | |
| Comp. | none | none | HMDS | (CF₃CO)₂O | (CH₃)₃Si—OCOCF₃ | 0.1 | HMDS | 0.01 | 10.0 | isodo- | TPGDME | 10.0 |
| Ex. 12-3 | | | | | | | | | | decane | | |

| | Evaluation results | | | | | |
|---|---|---|---|---|---|---|
| | Deposition | | | | | |
| | of Solid Matter by | | Contact angle [°] | | | |
| | Addition of Given Amount | | | | Decrease by | Resistance of |
| | of Water | | | After | Immersion | Vinyl Chloride |
| | 2 μL | 4 μL | Initial | Surface Treat. | in Hot Water | Resin |
| Comp. | not observed | not observed | <10 | 5 | 0 | fail (discoloring) |
| Ex. 12-1 | | | | | | |
| Comp. | observed | observed | <10 | 84 | 2 | fail (discoloring) |
| Ex. 12-2 | | | | | | |
| Ex. 12-1 | not observed | observed | <10 | 87 | 1 | pass |
| Ex. 12-2 | not observed | slightly observed | <10 | 88 | 0 | pass |
| Ex. 12-3 | not observed | not observed | <10 | 89 | 0 | pass |
| Ex. 9-1 | not observed | not observed | <10 | 90 | 0 | pass |
| Ex. 12-4 | not observed | not observed | <10 | 91 | 1 | pass |
| Ex. 12-5 | not observed | not observed | <10 | 91 | 1 | pass |
| Comp. | not observed | not observed | <10 | 37 | 1 | pass |
| Ex. 12-3 | | | | | | |

### Examples 13-1 to 13-6 and Comparative Examples 13-1 to 13-3

The wafer surface treatment was performed in the same manner as in Examples 3-1 to 3-6 and Comparative Examples 3-1 to 3-3, except that the first solvent was changed to isododedane. After that, the evaluation tests were conducted in the same manner as above. The results are summarized in TABLE 13.

TABLE 13

| | Protective Film-Forming Chemical Liquid | | | | | | | | |
|---|---|---|---|---|---|---|---|---|---|
| | Starting Materials for | | | | | | | | |
| | Silylation Agent and Base | | | | | | | | |
| | | | | Fluorine- | Composition after | | | | |
| | | | | Containing | Liquid Preparation | | | | |
| | | | | Carboxylic | (III) | | (IV) | | |
| | | | | Acid or | Silylation Agent | | Base | | (III)/(IV) |
| | Silylation | | Silicon | Anhydrate | | Conc. | | Conc. | Mass |
| | Agent | Base | Compound | thereof | Kind | [mass %] | Kind | [mass %] | Ratio |
| Comp. | none | none | HMDS | (CF₃CO)₂O | (CH₃)₃Si—OCOCF₃ | 10.0 | none | 0.0 | — |
| Ex. 13-1 | | | | | | | | | |
| Comp. | none | none | HMDS | (CF₃CO)₂O | (CH₃)₃Si—OCOCF₃ | 10.0 | HMDS | 0.01 | 1000.0 |
| Ex. 13-2 | | | | | | | | | |
| Ex. 13-1 | none | none | HMDS | (CF₃CO)₂O | (CH₃)₃Si—OCOCF₃ | 10.0 | HMDS | 0.06 | 166.7 |
| Ex. 13-2 | none | none | HMDS | (CF₃CO)₂O | (CH₃)₃Si—OCOCF₃ | 10.0 | HMDS | 0.09 | 111.1 |
| Ex. 13-3 | none | none | HMDS | (CF₃CO)₂O | (CH₃)₃Si—OCOCF₃ | 10.0 | HMDS | 0.15 | 66.7 |
| Ex. 9-1 | none | none | HMDS | (CF₃CO)₂O | (CH₃)₃Si—OCOCF₃ | 10.0 | HMDS | 0.5 | 20.0 |
| Ex. 13-4 | none | none | HMDS | (CF₃CO)₂O | (CH₃)₃Si—OCOCF₃ | 10.0 | HMDS | 0.9 | 11.1 |
| Ex. 13-5 | none | none | HMDS | (CF₃CO)₂O | (CH₃)₃Si—OCOCF₃ | 10.0 | HMDS | 1.4 | 7.1 |
| Ex. 13-6 | none | none | HMDS | (CF₃CO)₂O | (CH₃)₃Si—OCOCF₃ | 10.0 | HMDS | 1.8 | 5.6 |
| Comp. | none | none | HMDS | (CF₃CO)₂O | (CH₃)₃Si—OCOCF₃ | 10.0 | HMDS | 2.5 | 4.0 |
| Ex. 13-3 | | | | | | | | | |

| | Protective Film-Forming | | | | | | | | |
|---|---|---|---|---|---|---|---|---|---|
| | Chemical Liquid | | | | | | | | |
| | Composition after | | | | | | | | |
| | Liquid Preparation | | | Evaluation Results | | | | | |
| | | (II) | | Deposition of | | | | | |
| | (I) | Second | | Solid Matter by | | Contact Angle [°] | | | Resistance |
| | First | Solvent | | Addition of Given | | | After | Decrease by | of Vinyl |
| | Solvent | | Conc. | Amount of Water | | | Surface | Immersion | Chloride |
| | Kind | Kind | [mass %] | 2 μL | 4 μL | Initial | Treat. | in Hot Water | Resin |
| Comp. | isododecane | TPGDME | 10.0 | not | not | <10 | 10 | 0 | pass |
| Ex. 13-1 | | | | observed | observed | | | | |
| Comp. | isododecane | TPGDME | 10.0 | not | not | <10 | 48 | 1 | pass |
| Ex. 13-2 | | | | observed | observed | | | | |
| Ex. 13-1 | isododecane | TPGDME | 10.0 | not | not | <10 | 74 | 1 | pass |
| | | | | observed | observed | | | | |
| Ex. 13-2 | isododecane | TPGDME | 10.0 | not | not | <10 | 86 | 0 | pass |
| | | | | observed | observed | | | | |
| Ex. 13-3 | isododecane | TPGDME | 10.0 | not | not | <10 | 89 | 1 | pass |
| | | | | observed | observed | | | | |
| Ex. 9-1 | isododecane | TPGDME | 10.0 | not | not | <10 | 90 | 0 | pass |
| | | | | observed | observed | | | | |
| Ex. 13-4 | isododecane | TPGDME | 10.0 | not | not | <10 | 91 | 0 | pass |
| | | | | observed | observed | | | | |
| Ex. 13-5 | isododecane | TPGDME | 10.0 | not | slightly | <10 | 91 | 0 | pass |
| | | | | observed | observed | | | | |
| Ex. 13-6 | isododecane | TPGDME | 10.0 | not | observed | <10 | 92 | 1 | pass |
| | | | | observed | | | | | |
| Comp. | isododecane | TPGDME | 10.0 | observed | observed | <10 | 93 | 0 | fail |
| Ex. 13-3 | | | | | | | | | (discoloring) |

### Examples 14-1 to 14-5

The wafer surface treatment was performed in the same manner as in Examples 5-1 to 5-5, except that the first solvent was changed to isododedane. After that, the evaluation tests were conducted in the same manner as above. The results are summarized in TABLE 14.

TABLE 14

| | Protective Film-Forming Chemical Liquid | | | | | | | | |
|---|---|---|---|---|---|---|---|---|---|
| | Starting Materials for | | | | | | | | |
| | Silylation Agent and Base | | | | | | | | |
| | | | | Fluorine- | Composition after | | | | |
| | | | | Containing | Liquid Preparation | | | | |
| | | | | Carboxylic | (III) | | (IV) | | |
| | | | | Acid or | Silylation Agent | | Base | | (III)/(IV) |
| | Silylation | | Silicon | Anhydrate | | Conc. | | Conc. | Mass |
| | Agent | Base | Compound | thereof | Kind | [mass %] | Kind | [mass %] | Ratio |
| Ex. 9-1 | none | none | HMDS | (CF₃CO)₂O | (CH₃)₃Si—OCOCF₃ | 10.0 | HMDS | 0.5 | 20.0 |
| Ex. 14-1 | none | none | HMDS | (CF₃CO)₂O | (CH₃)₃Si—OCOCF₃ | 10.0 | HMDS | 0.5 | 20.0 |
| Ex. 14-2 | none | none | HMDS | (CF₃CO)₂O | (CH₃)₃Si—OCOCF₃ | 10.0 | HMDS | 0.5 | 20.0 |
| Ex. 14-3 | none | none | HMDS | (CF₃CO)₂O | (CH₃)₃Si—OCOCF₃ | 10.0 | HMDS | 0.5 | 20.0 |
| Ex. 14-4 | none | none | HMDS | (CF₃CO)₂O | (CH₃)₃Si—OCOCF₃ | 10.0 | HMDS | 0.5 | 20.0 |
| Ex. 14-5 | none | none | HMDS | (CF₃CO)₂O | (CH₃)₃Si—OCOCF₃ | 10.0 | HMDS | 0.5 | 20.0 |

| | Protective Film-Forming | | | | | | | | |
|---|---|---|---|---|---|---|---|---|---|
| | Chemical Liquid | | | | | | | | |
| | Composition after | | | | | | | | |
| | Liquid Preparation | | | Evaluation Results | | | | | |
| | | (II) | | Deposition of | | | | | |
| | (I) | Second | | Solid Matter by | | Contact Angle [°] | | | Resistance |
| | First | Solvent | | Addition of Given | | | After | Decrease by | of Vinyl |
| | Solvent | | Conc. | Amount of Water | | | Surface | Immersion | Chloride |
| | Kind | Kind | [mass %] | 2 μL | 2 μL | Initial | Treat. | in Hot Water | Resin |
| Ex. 9-1 | isododecane | TPGDME | 10.0 | not | not | <10 | 90 | 0 | pass |
| | | | | observed | observed | | | | |
| Ex. 14-1 | isododecane | DPGMPE | 10.0 | not | not | <10 | 90 | 0 | pass |
| | | | | observed | observed | | | | |
| Ex. 14-2 | isododecane | DPGDME | 10.0 | not | not | <10 | 90 | 0 | pass |
| | | | | observed | observed | | | | |
| Ex. 14-3 | isododecane | DEGDME | 10.0 | not | observed | <10 | 90 | 1 | pass |
| | | | | observed | | | | | |
| Ex. 14-4 | isododecane | DEGMEE | 10.0 | not | observed | <10 | 90 | 0 | pass |
| | | | | observed | | | | | |
| Ex. 14-5 | isododecane | DEGDEE | 10.0 | not | observed | <10 | 90 | 1 | pass |
| | | | | observed | | | | | |

### Example 15-1

A protective film-forming chemical liquid was prepared by mixing 19.7 g of dioctyltetramethyldisilazane (DOTMDS) as a silicon compound, 11.3 g of trifluoroacetic anhydride ((CF₃CO)₂O) as a fluorine-containing carboxylic acid anhydride, 67.5 g of n-decane (CH₃CH₂CH₂CH₂CH₂CH₂CH₂CH₂CH₂CH₃) and 1.5 g of tripropylene glycol dimethyl ether (TPGDME) and reacting DOTMDS and trifluoroacetic anhydride. The thus-prepared protective film-forming chemical liquid contained octyldimethylsilyl trifluoroacetate as a silylation agent, DOTMDS as a base, n-decane as a first solvent and TPGDME as a second solvent. In this Example, DOTMDS contained as the base in the protective film-forming chemical liquid was a residual amount of DOTMDS remaining unconsumed by the aforementioned silylation agent forming reaction. The wafer surface treatment was performed in the same manner as in Example 1-1, except that the above-prepared chemical liquid was used. The evaluation tests were then conducted in the same manner as above. The results are summarized in TABLE 15.

### Examples 15-2 to 15-6 and Comparative Examples 15-1 to 15-3

The wafer surface treatment was performed in the same manner as in Example 15-1, except that the concentration of the second solvent in the chemical liquid was changed. After that, the evaluation tests were conducted in the same manner as above. In each of Examples 15-2 to 15-6 and Comparative Examples 15-1 to 15-3, octyldimethylsilyl trifluoroacetate as the silylation agent and DOTMDS as the base were provided through reaction of DOTMDS and trifluoroacetic anhydride used as the starting raw materials; and DOTMDS contained in the protective film-forming chemical liquid was a residual amount of DOTMDS remaining unconsumed by the aforementioned silylation agent forming reaction. The results are summarized in TABLE 15.

TABLE 15

| | Protective Film-Forming Chemical Liquid | | | | | | | | |
|---|---|---|---|---|---|---|---|---|---|
| | Starting Materials for | | | | | | | | |
| | Silylation Agent and Base | | | | | | | | |
| | | | | Fluorine- | Composition after | | | | |
| | | | | Containing | Liquid Preparation | | | | |
| | | | | Carboxylic | (III) | | (IV) | | |
| | | | | Acid or | Silylation Agent | | Base | | (III)/(IV) |
| | Silylation | | Silicon | Anhydrate | | Conc. | | Conc. | Mass |
| | Agent | Base | Compound | thereof | Kind | [mass %] | Kind | [mass %] | Ratio |
| Comp. | none | none | DOTMDS | (CF₃CO)₂O | C₈H₁₇Si(CH₃)₂—OCOCF₃ | 10.0 | DOTMDS | 0.5 | 20.0 |
| Ex. 15-1 | | | | | | | | | |
| Comp. | none | none | DOTMDS | (CF₃CO)₂O | C₈H₁₇Si(CH₃)₂—OCOCF₃ | 10.0 | DOTMDS | 0.5 | 20.0 |
| Ex. 15-2 | | | | | | | | | |
| Ex. 15-1 | none | none | DOTMDS | (CF₃CO)₂O | C₈H₁₇Si(CH₃)₂—OCOCF₃ | 10.0 | DOTMDS | 0.5 | 20.0 |
| Ex. 15-2 | none | none | DOTMDS | (CF₃CO)₂O | C₈H₁₇Si(CH₃)₂—OCOCF₃ | 10.0 | DOTMDS | 0.5 | 20.0 |
| Ex. 15-3 | none | none | DOTMDS | (CF₃CO)₂O | C₈H₁₇Si(CH₃)₂—OCOCF₃ | 10.0 | DOTMDS | 0.5 | 20.0 |
| Ex. 15-4 | none | none | DOTMDS | (CF₃CO)₂O | C₈H₁₇Si(CH₃)₂—OCOCF₃ | 10.0 | DOTMDS | 0.5 | 20.0 |
| Ex. 15-5 | none | none | DOTMDS | (CF₃CO)₂O | C₈H₁₇Si(CH₃)₂—OCOCF₃ | 10.0 | DOTMDS | 0.5 | 20.0 |
| Ex. 15-6 | none | none | DOTMDS | (CF₃CO)₂O | C₈H₁₇Si(CH₃)₂—OCOCF₃ | 10.0 | DOTMDS | 0.5 | 20.0 |
| Comp. | none | none | DOTMDS | (CF₃CO)₂O | C₈H₁₇Si(CH₃)₂—OCOCF₃ | 10.0 | DOTMDS | 0.5 | 20.0 |
| Ex. 15-3 | | | | | | | | | |

| | Protective Film-Forming | | | | | | | | |
|---|---|---|---|---|---|---|---|---|---|
| | Chemical Liquid | | | | | | | | |
| | Composition after | | | | | | | | |
| | Liquid Preparation | | | Evaluation Results | | | | | |
| | | (II) | | Deposition of | | | | | |
| | (I) | Second | | Solid Matter by | | Contact Angle [°] | | | Resistance |
| | First | Solvent | | Addition of Given | | | After | Decrease by | of Vinyl |
| | Solvent | | Conc. | Amount of Water | | | Surface | Immersion | Chloride |
| | Kind | Kind | [mass %] | 2 μL | 4 μL | Initial | Treat. | in Hot Water | Resin |
| Comp. | n-decane | none | 0.0 | observed | observed | <10 | 104 | 0 | pass |
| Ex. 15-1 | | | | | | | | | |
| Comp. | n-decane | TPGDME | 0.1 | observed | observed | <10 | 104 | 0 | pass |
| Ex. 15-2 | | | | | | | | | |
| Ex. 15-1 | n-decane | TPGDME | 1.5 | not | observed | <10 | 104 | 1 | pass |
| | | | | observed | | | | | |
| Ex. 15-2 | n-decane | TPGDME | 2.5 | not | slightly | <10 | 104 | 1 | pass |
| | | | | observed | observed | | | | |
| Ex. 15-3 | n-decane | TPGDME | 5.0 | not | not | <10 | 104 | 0 | pass |
| | | | | observed | observed | | | | |
| Ex. 15-4 | n-decane | TPGDME | 10.0 | not | not | <10 | 104 | 0 | pass |
| | | | | observed | observed | | | | |
| Ex. 15-5 | n-decane | TPGDME | 17.0 | not | not | <10 | 104 | 0 | pass |
| | | | | observed | observed | | | | |
| Ex. 15-6 | n-decane | TPGDME | 25.0 | not | not | <10 | 104 | 1 | pass |
| | | | | observed | observed | | | | |
| Comp. | n-decane | TPGDME | 35.0 | not | not | <10 | 104 | 1 | fail |
| Ex. 15-3 | | | | observed | observed | | | | (swelling) |

### Examples 16-1 to 16-5 and Comparative Examples 16-1 to 16-3

The wafer surface treatment was performed in the same manner as in Example 15-4, except that the concentrations of the silylation agent (III) and the base (IV) in the chemical liquid and the mass ratio of the silylation agent (III) to the base (IV) were changed by varying the amount of the silicon compound added and the amount of the fluorine-containing carboxylic acid anhydride added. After that, the evaluation tests were conducted in the same manner as above. In each of Examples 16-1 to 16-5 and Comparative Examples 16-2 and 16-3, octyldimethylsilyl trifluoroacetate as the silylation agent and DOTMDS as the base were provided through reaction of DOTMDS and trifluoroacetic anhydride used as the starting raw materials; and DOTMDS contained in the protective film-forming chemical liquid was a residual amount of DOTMDS remaining unconsumed by the aforementioned silylation agent forming reaction. The results are summarized in TABLE 16.

TABLE 16

| | Protective Film-Forming Chemical Liquid | | | | | | | | |
|---|---|---|---|---|---|---|---|---|---|
| | Starting Naterials for | | | | | | | | |
| | Silylation Agent and Base | | | | | | | | |
| | | | | Fluorine- | | | | | |
| | | | | Containing | Composition after Liquid Preparation | | | | |
| | | | | Carboxylic | (III) | | (IV) | | |
| | | | | Acid or | Silylation Agent | | Base | | (III)/(IV) |
| | Silylation | | Silicon | Anhydrate | | Conc. | | Conc. | Mass |
| | Agent | Base | Compound | thereof | Kind | [mass %] | Kind | [mass %] | Ratio |
| Comp. | none | none | DOTMDS | none | none | 0.0 | DOTMDS | 0.5 | 0.0 |
| Ex. 16-1 | | | | | | | | | |
| Comp. | none | none | DOTMDS | (CF₃CO)₂O | C₈H₁₇Si(CH₃)₂—OCOCF₃ | 1.0 | DOTMDS | 0.5 | 2.0 |
| Ex. 16-2 | | | | | | | | | |
| Ex. 16-1 | none | none | DOTMDS | (CF₃CO)₂O | C₈H₁₇Si(CH₃)₂—OCOCF₃ | 2.5 | DOTMDS | 0.5 | 5.0 |
| Ex. 16-2 | none | none | DOTMDS | (CF₃CO)₂O | C₈H₁₇Si(CH₃)₂—OCOCF₃ | 3.5 | DOTMDS | 0.5 | 7.0 |
| Ex. 16-3 | none | none | DOTMDS | (CF₃CO)₂O | C₈H₁₇Si(CH₃)₂—OCOCF₃ | 5.0 | DOTMDS | 0.5 | 10.0 |
| Ex. 15-4 | none | none | DOTMDS | (CF₃CO)₂O | C₈H₁₇Si(CH₃)₂—OCOCF₃ | 10.0 | DOTMDS | 0.5 | 20.0 |
| Ex. 16-4 | none | none | DOTMDS | (CF₃CO)₂O | C₈H₁₇Si(CH₃)₂—OCOCF₃ | 11.5 | DOTMDS | 0.5 | 23.0 |
| Ex. 16-5 | none | none | DOTMDS | (CF₃CO)₂O | C₈H₁₇Si(CH₃)₂—OCOCF₃ | 12.5 | DOTMDS | 0.5 | 25.0 |
| Comp. | none | none | DOTMDS | (CF₃CO)₂O | C₈H₁₇Si(CH₃)₂—OCOCF₃ | 0.1 | DOTMDS | 0.01 | 10.0 |
| Ex. 16-3 | | | | | | | | | |

| | Protective Film-Forming | | | | | | | | |
|---|---|---|---|---|---|---|---|---|---|
| | Chemical Liquid | | | | | | | | |
| | Composition after | | | | | | | | |
| | Liquid Preparation | | | Evaluation Results | | | | | |
| | | (II) | | Deposition of | | | | | |
| | (I) | Second | | Solid Matter by | | Contact Angle [°] | | | Resistance |
| | First | Solvent | | Addition of Given | | | After | Decrease by | of Vinyl |
| | Solvent | Kind | Conc. | Amount of Water | | | Surface | Immersion | Chloride |
| | Kind | Kind | [mass %] | 2 μL | 4 μL | Initial | Treat. | in Hot Water | resin |
| Comp. | n-decane | TPGDME | 10.0 | observed | observed | <10 | 19 | 1 | fail |
| Ex. 16-1 | | | | | | | | | (discoloring) |
| Comp. | n-decane | TPGDME | 10.0 | observed | observed | <10 | 100 | 0 | fail |
| Ex. 16-2 | | | | | | | | | (discoloring) |
| Ex. 16-1 | n-decane | TPGDME | 10.0 | not | observed | <10 | 101 | 0 | pass |
| | | | | observed | | | | | |
| Ex. 16-2 | n-decane | TPGDME | 10.0 | not | slightly | <10 | 102 | 1 | pass |
| | | | | observed | observed | | | | |
| Ex. 16-3 | n-decane | TPGDME | 10.0 | not | not | <10 | 103 | 0 | pass |
| | | | | observed | observed | | | | |
| Ex. 15-4 | n-decane | TPGDME | 10.0 | not | not | <10 | 104 | 13 | pass |
| | | | | observed | observed | | | | |
| Ex. 16-4 | n-decane | TPGDME | 10.0 | not | not | <10 | 104 | 1 | pass |
| | | | | observed | observed | | | | |
| Ex. 16-5 | n-decane | TPGDME | 10.0 | not | not | <10 | 105 | 1 | pass |
| | | | | observed | observed | | | | |
| Comp. | n-decane | TPGDME | 10.0 | not | riot | <10 | 46 | 1 | pass |
| Ex. 16-3 | | | | observed | observed | | | | |

### Examples 17-1 to 17-6 and Comparative Examples 17-1 to 17-3

The wafer surface treatment was performed in the same manner as in Example 15-4, except that the concentration of the base (IV) in the chemical liquid and the mass ratio of the silylation agent (III) to the base (IV) were changed by varying the amount of the silicon compound added. After that, the evaluation tests were conducted in the same manner as above. In each of Examples 17-1 to 17-6 and Comparative Examples 17-2 and 17-3, octyldimethylsilyl trifluoroacetate as the silylation agent and DOTMDS as the base were provided through reaction of DOTMDS and trifluoroacetic anhydride used as the starting raw materials; and DOTMDS contained in the protective film-forming chemical liquid was a residual amount of DOTMDS remaining unconsumed by the aforementioned silylation agent forming reaction. The results are summarized in TABLE 17.

TABLE 17

| | Protective Film-Forming Chemical Liquid | | | | | | | | |
|---|---|---|---|---|---|---|---|---|---|
| | Starting Materials for | | | | | | | | |
| | Silylation Agent and Base | | | | | | | | |
| | | | | Fluorine- | | | | | |
| | | | | Containing | Composition after Liquid Preparation | | | | |
| | | | | Carboxylic | (III) | | (IV) | | |
| | | | | Acid or | Silylation Agent | | Base | | (III)/(IV) |
| | Silylation | | Silicon | Anhydrate | | Conc. | | Conc. | Mass |
| | Agent | Base | Compound | thereof | Kind | [mass %] | Kind | [mass %] | Ratio |
| Comp. | none | none | DOTMDS | (CF₃CO)₂O | C₈H₁₇Si(CH₃)₂—OCOCF₃ | 10.0 | none | 0.0 | — |
| Ex. 17-1 | | | | | | | | | |
| Comp. | none | none | DOTMDS | (CF₃CO)₂O | C₈H₁₇Si(CH₃)₂—OCOCF₃ | 10.0 | DOTMDS | 0.01 | 1000.0 |
| Ex. 17-2 | | | | | | | | | |
| Ex. 17-1 | none | none | DOTMDS | (CF₃CO)₂O | C₈H₁₇Si(CH₃)₂—OCOCF₃ | 10.0 | DOTMDS | 0.06 | 166.7 |
| Ex. 17-2 | none | none | DOTMDS | (CF₃CO)₂O | C₈H₁₇Si(CH₃)₂—OCOCF₃ | 10.0 | DOTMDS | 0.09 | 111.1 |
| Ex. 17-3 | none | none | DOTMDS | (CF₃CO)₂O | C₈H₁₇Si(CH₃)₂—OCOCF₃ | 10.0 | DOTMDS | 0.15 | 66.7 |
| Ex. 15-4 | none | none | DOTMDS | (CF₃CO)₂O | C₈H₁₇Si(CH₃)₂—OCOCF₃ | 10.0 | DOTMDS | 0.5 | 20.0 |
| Ex. 17-4 | none | none | DOTMDS | (CF₃CO)₂O | C₈H₁₇Si(CH₃)₂—OCOCF₃ | 10.0 | DOTMDS | 0.9 | 11.1 |
| Ex. 17-5 | none | none | DOTMDS | (CF₃CO)₂O | C₈H₁₇Si(CH₃)₂—OCOCF₃ | 10.0 | DOTMDS | 1.4 | 7.1 |
| Ex. 17-6 | none | none | DOTMDS | (CF₃CO)₂O | C₈H₁₇Si(CH₃)₂—OCOCF₃ | 10.0 | DOTMDS | 1.8 | 5.6 |
| Comp. | none | none | DOTMDS | (CF₃CO)₂O | C₈H₁₇Si(CH₃)₂—OCOCF₃ | 10.0 | DOTMDS | 2.5 | 4.0 |
| Ex. 17-3 | | | | | | | | | |

| | Protective Film-Forming | | | | | | | | |
|---|---|---|---|---|---|---|---|---|---|
| | Chemical Liquid | | | | | | | | |
| | Composition after | | | | | | | | |
| | Liquid Preparation | | | Evaluation Results | | | | | |
| | | (II) | | Deposition of | | | | | |
| | (I) | Second | | Solid Matter by | | Contact Angle [°] | | | Resistance |
| | First | Solvent | | Addition of Given | | | After | Decrease by | of Vinyl |
| | Solvent | | Conc. | Amount of Water | | | Surface | Immersion | Chloride |
| | Kind | Kind | [mass %] | 2 μL | 4 μL | Initial | Treat. | in Hot Water | Resin |
| Comp. | n-decane | TPGDME | 10.0 | not | not | <10 | 10 | 0 | pass |
| Ex. 17-1 | | | | observed | observed | | | | |
| Comp. | n-decane | TPGDME | 10.0 | not | not | <10 | 66 | 1 | pass |
| Ex. 17-2 | | | | observed | observed | | | | |
| Ex. 17-1 | n-decane | TPGDME | 10.0 | not | not | <10 | 91 | 1 | pass |
| | | | | observed | observed | | | | |
| Ex. 17-2 | n-decane | TPGDME | 10.0 | not | not | <10 | 95 | 0 | pass |
| | | | | observed | observed | | | | |
| Ex. 17-3 | n-decane | TPGDME | 10.0 | not | not | <10 | 100 | 1 | pass |
| | | | | observed | observed | | | | |
| Ex. 15-4 | n-decane | TPGDME | 10.0 | not | not | <10 | 104 | 0 | pass |
| | | | | observed | observed | | | | |
| Ex. 17-4 | n-decane | TPGDME | 10.0 | not | not | <10 | 105 | 1 | pass |
| | | | | observed | observed | | | | |
| Ex. 17-5 | n-decane | TPGDME | 10.0 | not | slightly | <10 | 106 | 1 | pass |
| | | | | observed | observed | | | | |
| Ex. 17-6 | n-decane | TPGDME | 10.0 | not | observed | <10 | 107 | 0 | pass |
| | | | | observed | | | | | |
| Comp. | n-decane | TPGDME | 10.0 | observed | observed | <10 | 107 | 1 | fail |
| Ex. 17-3 | | | | | | | | | (discoloring) |

### Examples 18-1 to 18-10

The wafer surface treatment was performed in the same manner as in Examples 1-4, 4-1, 4-2, 4-4 to 4-10, except that the first solvent was changed to n-dedane. After that, the evaluation tests were conducted in the same manner as above. The results are summarized in TABLE 18.

TABLE 18

| | Protective Film-Forming Chemical Liquid | | | | | | | |
|---|---|---|---|---|---|---|---|---|
| | Starting Materials for | | | | | | | |
| | Silylation Agent and Base | | | | | | | |
| | | | | Fluorine- | | | | |
| | | | | Containing | Composition after Liquid Preparation | | | |
| | | | | Carboxylic | (III) | | (IV) | |
| | | | | Acid or | Silylation Agent | | Base | |
| | Silylation | | Silicon | Anhydrate | | Conc. | | Conc. |
| | Agent | Base | Compound | thereof | Kind | [mass %] | Kind | [mass %] |
| Ex. 18-1 | none | none | HMDS | (CF₃CO)₂O | (CH₃)₃Si—OCOCF₃ | 10.0 | HMDS | 0.5 |
| Ex. 18-2 | none | none | TMDS | (CF₃CO)₂O | (H)Si(CH₃)₂—OCOCF₃ | 10.0 | TMDS | 0.5 |
| Ex. 18-3 | none | none | DBTMDS | (CF₃CO)₂O | C₄H₉Si(CH₃)₂—OCOCF₃ | 10.0 | DBTMDS | 0.5 |
| Ex. 15-4 | none | none | DOTMDS | (CF₃CO)₂O | C₈H₁₇Si(CH₃)₂—OCOCF₃ | 10.0 | DOTMDS | 0.5 |
| Ex. 18-4 | none | none | HMDS | (C₄F₉CO)₂O | (CH₃)₃Si—OCOC₄F₉ | 10.0 | HMDS | 0.5 |
| Ex. 18-5 | (CH₃)₃Si—OCOCF₃ | HMDS | none | none | (CH₃)₃Si—OCOCF₃ | 10.0 | HMDS | 0.5 |
| Ex. 18-6 | (CH₃)₃Si—OCOCF₃ | TMSIm | none | none | (CH₃)₃Si—OCOCF₃ | 10.0 | TMSIm | 0.5 |
| Ex. 18-7 | none | TMSIm | HMDS | (CF₃CO)₂O | (CH₃)₃Si—OCOCF₃ | 10.0 | TMSIm | 0.15 |
| Ex. 18-8 | none | TMSIm | HMDS | (CF₃CO)₂O | (CH₃)₃Si—OCOCF₃ | 10.0 | TMSIm | 0.075 |
| | | | | | | | HMDS | 0.075 |
| Ex. 18-9 | none | TMSPr | HMDS | (CF₃CO)₂O | (CH₃)₃Si—OCOCF₃ | 10.0 | TMSPr | 0.15 |
| Ex. 18-10 | none | TMSIm | HMDS | (C₄F₉CO)₂O | (CH₃)₃Si—OCOC₄F₉ | 10.0 | TMSIm | 0.15 |

| | Protective Film-Forming | | | | | | | | | |
|---|---|---|---|---|---|---|---|---|---|---|
| | Chemical Liquid | | | | | | | | | |
| | Composition after | | | | | | | | | |
| | Liquid Preparation | | | | Evaluation Results | | | | | |
| | | | (II) | | Deposition of | | | | | |
| | | (I) | Second | | Solid Matter by | | Contact Angle [°] | | | Resistance |
| | (III)/(IV) | First | Solvent | | Addition of Given | | | After | Decrease by | of Vinyl |
| | Mass | Solvent | | Conc. | Amount of Water | | | Surface | Immersion | Chloride |
| | Ratio | Kind | Kind | [mass %] | 2 μL | 4 μL | Initial | Treat. | in Hot Water | Resin |
| Ex. 18-1 | 20.0 | n-decane | TPGDME | 10.0 | not | not | <10 | 90 | 0 | pass |
| | | | | | observed | observed | | | | |
| Ex. 18-2 | 20.0 | n-decane | TPGDME | 10.0 | not | not | <10 | 99 | 20 | pass |
| | | | | | observed | observed | | | | |
| Ex. 18-3 | 20.0 | n-decane | TPGDME | 10.0 | not | not | <10 | 100 | 2 | pass |
| | | | | | observed | observed | | | | |
| Ex. 15-4 | 20.0 | n-decane | TPGDME | 10.0 | not | not | <10 | 104 | 0 | pass |
| | | | | | observed | observed | | | | |
| Ex. 18-4 | 20.0 | n-decane | TPGDME | 10.0 | not | not | <10 | 89 | 0 | pass |
| | | | | | observed | observed | | | | |
| Ex. 18-5 | 20.0 | n-decane | TPGDME | 10.0 | not | not | <10 | 90 | 0 | pass |
| | | | | | observed | observed | | | | |
| Ex. 18-6 | 20.0 | n-decane | TPGDME | 10.0 | not | not | <10 | 93 | 0 | pass |
| | | | | | observed | observed | | | | |
| Ex. 18-7 | 66.7 | n-decane | TPGDME | 10.0 | not | not | <10 | 93 | 0 | pass |
| | | | | | observed | observed | | | | |
| Ex. 18-8 | 66.7 | n-decane | TPGDME | 10.0 | not | not | <10 | 92 | 1 | pass |
| | | | | | observed | observed | | | | |
| Ex. 18-9 | 66.7 | n-decane | TPGDME | 10.0 | not | not | <10 | 90 | 0 | pass |
| | | | | | observed | observed | | | | |
| Ex. 18-10 | 66.7 | n-decane | TPGDME | 10.0 | not | not | <10 | 92 | 0 | pass |
| | | | | | observed | observed | | | | |

### Examples 19-1 to 19-5

The wafer surface treatment was performed in the same manner as in Example 15-4, except that the kind of the second solvent used was changed. After that, the evaluation tests were conducted in the same manner as above. The results are summarized in TABLE 19.

TABLE 19

| | Protective Film-Forming Chemical Liquid | | | | | | | | |
|---|---|---|---|---|---|---|---|---|---|
| | Starting Materials for | | | | | | | | |
| | Silylation Agent and Base | | | | | | | | |
| | | | | Fluorine- | | | | | |
| | | | | Containing | Composition after Liquid Preparation | | | | |
| | | | | Carboxylic | (III) | | (IV) | | |
| | | | | Acid or | Silylation Agent | | Base | | (III)/(IV) |
| | Silylation | | Silicon | Anhydrate | | Conc. | | Conc. | Mass |
| | Agent | Base | Compound | thereof | Kind | [mass %] | Kind | [mass %] | Ratio |
| Ex. 15-4 | none | none | DOTMDS | (CF₃CO)₂O | C₈H₁₇Si(CH₃)₂—OCOCF₃ | 10.0 | DOTMDS | 0.5 | 20.0 |
| Ex. 19-1 | none | none | DOTMDS | (CF₃CO)₂O | C₈H₁₇Si(CH₃)₂—OCOCF₃ | 10.0 | DOTMDS | 0.5 | 20.0 |
| Ex. 19-2 | none | none | DOTMDS | (CF₃CO)₂O | C₈H₁₇Si(CH₃)₂—OCOCF₃ | 10.0 | DOTMDS | 0.5 | 20.0 |
| Ex. 19-3 | none | none | DOTMDS | (CF₃CO)₂O | C₈H₁₇Si(CH₃)₂—OCOCF₃ | 10.0 | DOTMDS | 0.5 | 20.0 |
| Ex. 19-4 | none | none | DOTMDS | (CF₃CO)₂O | C₈H₁₇Si(CH₃)₂—OCOCF₃ | 10.0 | DOTMDS | 0.5 | 20.0 |
| Ex. 19-5 | none | none | DOTMDS | (CF₃CO)₂O | C₈H₁₇Si(CH₃)₂—OCOCF₃ | 10.0 | DOTMDS | 0.5 | 20.0 |

| | Protective Film-Forming | | | | | | | | |
|---|---|---|---|---|---|---|---|---|---|
| | Chemical Liquid | | | | | | | | |
| | omposition after | | | | | | | | |
| | Liquid Preparation | | | Evaluation Results | | | | | |
| | | (II) | | Deposition of | | | | | |
| | (I) | Second | | Solid Matter by | | Contact Angle [°] | | | Resistance |
| | First | Solvent | | Addition of Given | | | After | Decrease by | of Vinyl |
| | Solvent | | Conc. | Amount of Water | | | Surface | Immersion | Chloride |
| | Kind | Kind | [mass %] | 2 μL | 4 μL | Initial | Treat. | in Hot Water | Resin |
| Ex. 15-4 | n-decane | TPGDME | 10.0 | not | not | <10 | 104 | 0 | pass |
| | | | | observed | observed | | | | |
| Ex. 19-1 | n-decane | DPGMPE | 10.0 | not | not | <10 | 104 | 0 | pass |
| | | | | observed | observed | | | | |
| Ex. 19-2 | n-decane | DPGDME | 16.0 | not | not | <10 | 104 | 1 | pass |
| | | | | observed | observed | | | | |
| Ex. 19-3 | n-decane | DEGDME | 10.0 | not | observed | <10 | 104 | 0 | pass |
| | | | | observed | | | | | |
| Ex. 19-4 | n-decane | DEGMEE | 10.0 | not | observed | <10 | 104 | 1 | pass |
| | | | | observed | | | | | |
| Ex. 19-5 | n-decane | DEGDEE | 10.0 | not | observed | <10 | 104 | 1 | pass |
| | | | | observed | | | | | |

### Examples 20-1 to 20-5

The wafer surface treatment was performed in the same manner as in Example 4-7, except that the kind of the first solvent used was changed. After that, the evaluation tests were conducted in the same manner as above. The results are summarized in TABLE 20. In the table, the term “DnHE” refers to di-n-hexyl ether; and the term “EME” refers to ethyl methyl ether.

TABLE 20

| | Protective Film-Forming Chemical Liquid | | | | | | | | |
|---|---|---|---|---|---|---|---|---|---|
| | Starting Materials for | | | | | | | | |
| | Silylation Agent and Base | | | | | | | | |
| | | | | Fluorine- | | | | | |
| | | | | Containing | Composition after Liquid Preparation | | | | |
| | | | | Carboxylic | (III) | | (IV) | | |
| | | | | Acid or | Silylation Agent | | Base | | (III)/(IV) |
| | Silylation | | Silicon | Anhydrate | | Conc. | | Conc. | Mass |
| | Agent | Base | Compound | thereof | Kind | [mass %] | Kind | [mass %] | Ratio |
| Ex. 4-7 | none | TMSIm | HMDS | (CF₃CO)₂O | (CH₃)₃Si—OCOCF₃ | 10.0 | TMSIm | 0.15 | 66.7 |
| Ex. 20-1 | none | TMSIm | HMDS | (CF₃CO)₂O | (CH₃)₃Si—OCOCF₃ | 10.0 | TMSIm | 0.15 | 66.7 |
| Ex. 20-2 | none | TMSIm | HMDS | (CF₃CO)₂O | (CH₃)₃Si—OCOCF₃ | 10.0 | TMSIm | 0.15 | 66.7 |
| Ex. 20-3 | none | TMSIm | HMDS | (CF₃CO)₂O | (CH₃)₃Si—OCOCF₃ | 10.0 | TMSIm | 0.15 | 66.7 |
| Ex. 6-4 | none | TMSIm | HMDS | (CF₃CO)₂O | (CH₃)₃Si—OCOCF₃ | 10.0 | TMSIm | 0.15 | 66.7 |
| Ex. 18-7 | none | TMSIm | HMDS | (CF₃CO)₂O | (CH₃)₃Si—OCOCF₃ | 10.0 | TMSIm | 0.15 | 66.7 |
| Ex. 20-4 | none | TMSIm | HMDS | (CF₃CO)₂O | (CH₃)₃Si—OCOCF₃ | 10.0 | TMSIm | 0.15 | 66.7 |
| Ex. 20-5 | none | TMSIm | HMDS | (CF₃CO)₂O | (CH₃)₃Si—OCOCF₃ | 10.0 | TMSIm | 0.15 | 66.7 |

| | Protective Film-Forming | | | | | | | | |
|---|---|---|---|---|---|---|---|---|---|
| | Chemical Liquid | | | | | | | | |
| | Composition after | | | | | | | | |
| | Liquid Preparation | | | Evaluation Results | | | | | |
| | | (II) | | Deposition of | | | | | |
| | (I) | Second | | Solid Matter by | | Contact Angle [°] | | | Resistance |
| | First | Solvent | | Addition of Given | | | After | Decrease by | of Vinyl |
| | Solvent | | Conc. | Amount of Water | | | Surface | Immersion | Chloride |
| | Kind | Kind | [mass %] | 2 μL | 4 μL | Initial | Treat. | in Hot Water | Resin |
| Ex. 4-7 | DIAE | TPGDME | 10.0 | not | not | <10 | 93 | 0 | pass |
| | | | | observed | observed | | | | |
| Ex. 20-1 | DnAE | TPGDME | 10.0 | not | not | <10 | 93 | 0 | pass |
| | | | | observed | observed | | | | |
| Ex. 20-2 | DnHE | TPGDME | 10.0 | not | not | <10 | 93 | 1 | pass |
| | | | | observed | observed | | | | |
| Ex. 20-3 | EME | TPGDME | 10.0 | not | not | <10 | 93 | 0 | pass |
| | | | | observed | observed | | | | |
| Ex. 6-4 | isododecane | TPGDME | 10.0 | not | not | <10 | 93 | 1 | pass |
| | | | | observed | observed | | | | |
| Ex. 18-7 | n-decane | TPGDME | 10.0 | not | not | <10 | 93 | 0 | pass |
| | | | | observed | observed | | | | |
| Ex. 20-4 | n-dodecane | TPGDME | 10.0 | not | not | <10 | 93 | 0 | pass |
| | | | | observed | observed | | | | |
| Ex. 20-5 | decalin | TPGDME | 10.0 | not | not | <10 | 93 | 1 | pass |
| | | | | observed | observed | | | | |

Examples 1-1 to 1-6, Examples 6-1 to 6-6, Examples 11-1 to 11-5 (including Example 9-1) and Examples 15-1 to 15-6 correspond to the case where the concentration of the second solvent (II) in the chemical liquid fell within the range of 1 to 30 mass %. In these Examples, it was unlikely that the deposition of solid matter in the chemical liquid would be caused with the addition of water; and the resistance of the vinyl chloride resin to the chemical liquid was good.

On the other hand, Comparative Examples 1-1, 1-2, 6-1, 6-2, 11-1, 11-2, 15-1 and 15-2 correspond to the case where the concentration of the second solvent (II) was less than 1 mass %. In these Comparative Examples, the deposition of solid matter in the chemical liquid was caused with the addition of 2 μL of water.

Further, Comparative Examples 1-3, 6-3, 11-3 and 15-3 correspond to the case where the concentration of the second solvent (II) exceeded 30 mass %. In these Comparative Examples, the resistance of the vinyl chloride resin to the chemical liquid was not sufficient.

Examples 2-1 to 2-5 (including Example 1-4), Examples 7-1 to 7-7 (including Example 6-4), Examples 12-1 to 12-5 (including Example 9-1) and Examples 16-1 to 16-5 (including Example 15-4) correspond to the case where: the concentration of the silylation agent (III) in the chemical liquid fell within the range of 2 to 15 mass %; the concentration of the base (IV) in the chemical liquid fell within the range of 0.05 to 2 mass %; and the mass ratio of the silylation agent (III) to the base (IV) fell within the range of 4.5 or greater. In these Examples, the chemical liquid showed a good water repellency imparting effect; it was unlikely that the deposition of solid matter in the chemical liquid would be caused with the addition of water; and the resistance of the vinyl chloride resin to the chemical liquid was good.

On the other hand, Comparative Examples 2-1 to 2-3, 7-1 to 7-3, 12-1 to 12-3 and 16-1 to 16-3 corresponds to the case where at least one of the concentration of the silylation agent (III), the concentration of the base (IV) and the mass ratio of the silylation agent (III) to the base (IV) was less than the lower limit of the above range. In these Comparative Examples, there occurred at least one of the following problems: less water repellency imparting effect, solid matter deposition caused with the addition of 2 μL of water and discoloring of the vinyl chloride resin.

Comparative Examples 2-4 and 2-5 correspond the case where: the second solvent was not used; and the concentration of the base (IV) exceeded the upper limit of the above range. In these Comparative Examples, there occurred at least one of the following problems: solid matter deposition caused with the addition of 2 μL of water and discoloring of the vinyl chloride resin.

Examples 3-1 to 3-6 (including Example 1-4), Examples 8-1 to 8-6 (including Example 6-4), Examples 13-1 to 13-6 (including Example 9-1) and Examples 17-1 to 17-6 (including Example 15-4) correspond to the case where: the concentration of the base (IV) in the chemical liquid fell within the rage of 0.05 to 2 mass %; and the mass ratio of the silylation agent (III) to the base (IV) fell within the range of 4.5 or greater. In these Examples, it was unlikely that the deposition of solid matter in the chemical liquid would be caused with the addition of water; and the resistance of the vinyl chloride resin to the chemical liquid was good.

On the other hand, Comparative Examples 3-1, 3-2, 8-1, 8-2, 13-1, 13-2, 17-1 and 17-2 correspond to the case where the concentration of the base (IV) was less than 0.05 mass %. In these Comparative Examples, the chemical liquid did not show a sufficient water repellency imparting effect.

Comparative Examples 3-3, 8-3, 13-3 and 17-3 correspond to the case where the mass ratio of the silylation agent (III) to the base (IV) was less than 4.5. In these Comparative Examples, there occurred the problem of solid matter deposition caused with the addition of 2 μL of water or discoloring of the vinyl chloride resin.

In Examples 4-1 to 4-10 (including Example 1-4), Examples 9-1 to 9-10 (including Example 6-4) and Examples 18-1 to 18-10 (including Example 15-4), the chemical liquid showed a good water repellency imparting effect; it was unlikely that the deposition of solid matter in the chemical liquid would be caused with the addition of water; and the resistance of the vinyl chloride resin to the chemical liquid was good. The silylation agent used in Examples 4-1, 9-2 and 18-2 had a structure in which one hydrogen atom was bonded to silicon (that is, b in the general formula [1] was 1). The tendency of decrease of the contact angle by contact with water was larger in these Examples than in Examples 1-4, 9-1 and 18-1 in which b in the general formula [1] was 0. It is thus confirmed that, in terms of the ease of maintaining water repellency after the formation of the protective film, the number (b) of —H groups in the silylation agent represented by the general formula [1] is preferably 0.

In Examples 5-1 to 5-5 (including Example 1-4), Examples 10-1 to 10-5 (including Example 6-4), Examples 14-1 to 14-5 (including Example 9-1) and Examples 19-1 to 19-5 (including Example 15-4), the chemical liquid showed a good water repellency imparting effect; it was unlikely that the deposition of solid matter in the chemical liquid would be caused with the addition of water; and the resistance of the vinyl chloride resin to the chemical liquid was good. It is confirmed from these results that it is possible to obtain the same effects of the present invention even when a different kind of glycol ether is used as the second solvent.

In Examples 20-1 to 20-5 (including Examples 4-7, 6-4 and 18-7), the chemical liquid showed a good water repellency imparting effect; it was unlikely that the deposition of solid matter in the chemical liquid would be caused with the addition of water; and the resistance of the vinyl chloride resin to the chemical liquid was good. It is confirmed from these results that it is possible to obtain the same effects of the present invention even when at least one selected from the group consisting of different kinds of ether solvent and hydrocarbon solvent is used as the first solvent.

### Example 21-1

(1) Preparation of Protective Film-Forming Chemical Liquid

A protective film-forming chemical liquid was prepared by mixing 10.0 g of trimethylsilyl trifluoroacetate ((CH₃)₃SiOCOCF₃) as a silylation agent, 0.5 g of hexamethyldisilazane (HMDS) as a base, 10.0 g of N-trimethylsilyl trifluoroacetamide ((CH₃)₃SiN(H)C(═O)CF₃) as an amide compound, 69.5 g of diisoamyl ether (DiAE) as a first solvent and 10.0 g of tripropylene glycol dimethyl ether (TPGDME).

(2) Evaluation of Contact Angle Retention Rate

Using the above-prepared protective film-forming chemical liquid, the surface treatment of a wafer was performed in the same manner as in Example 4-5. After the surface treatment, the contact angle evaluation test was conducted to determine, as a reference contact angle, the contact angle of water with the wafer surface in the case where no water was added to the chemical liquid (i.e. the amount of water added was 0.0 mass %). Subsequently, water was added to the protective film-forming chemical liquid in an amount of 0.1 mass % or 0.2 mass % based on the total amount of the chemical liquid, followed by mixing the chemical liquid at 25° C. for 1 minute. Using the thus-obtained chemical liquid, the surface treatment of a wafer was performed in the same manner as in Example 4-5. The contact angle evaluation test was conducted after the surface treatment. The test results of the contact angle are shown in TABLE 21 and FIG. 5 as relative values assuming the reference contact angle as 100 (that is, the contact angle retention rate after the surface treatment).

The protective film-forming chemical liquid of Example 1-4 was prepared through the reaction of the starting raw materials: HMDS and trifluoroacetic anhydride as mentioned above, and contained not only 10.0 g of trimethylsilyl trifluoroacetate as the silylation agent and 0.5 g of HMDS as the base, but also 10.0 g of N-trimethylsilyl trifluoroacetamide ((CH₃)₃SiN(H)COCF₃) as the amide compound by-produced during the reaction. Using this protective film-forming chemical liquid of Example 1-4, the evaluation of the contact angle retention rate after the surface treatment was made in the same manner as in Example 21-1. The results are shown in TABLE 21 and FIG. 5.

Using the protective film-forming chemical liquid of Example 4-5 which contained trimethylsilyl trifluoroacetate as the silylation agent, HMDS as the base and no amide compound, as a reference example, the evaluation of the contact angle retention rate after the surface treatment was also made in the same manner as in Example 21-1. The results are shown in TABLE 21 and FIG. 5.

As is apparent from the above results, it is preferable that the amide compound represented by the general formula [9] is contained in the chemical liquid according to the present invention because the chemical liquid with such an amide compound can easily maintain its water repellency imparting effect even when water is mixed into the chemical liquid.

TABLE 21

| | Protective Film-Forming Chemical Liquid | | | | | | | | |
|---|---|---|---|---|---|---|---|---|---|
| | Starting Materials for | | | | | | | | |
| | Silylation Agent and Base | | | | | | | | |
| | | | | Fluorine- | | | | | |
| | | | | Containing | | Composition after Liquid Preparation | | | |
| | | | | Carboxylic | | (III) | | (IV) | |
| | | | | Acid or | | Silylation Agent | | Base | |
| | Silylation | | Silicon | Anhydrate | Amide | | Conc. | | Conc. |
| | Agent | Base | Compound | thereof | Compound | Kind | [mass %] | Kind | [mass %] |
| Ex. 21-1 | (CH₃)₃Si—OCOCF₃ | HMDS | none | none | (CH₃)₃Si—NHCOCF₃ | (CH₃)₃Si—OCOCF₃ | 10.0 | HMDS | 0.5 |
| Ex. 1-4 | none | none | HMDS | (CF₃CO)₂O | none | (CH₃)₃Si—OCOCF₃ | 10.0 | HMDS | 0.5 |
| Ex. 4-5 | (CH₃)₃Si—OCOCF₃ | HMDS | none | none | none | (CH₃)₃Si—OCOCF₃ | 10.0 | HMDS | 0.5 |
| Ex. 21-2 | (CH₃)₃Si—OCOCF₃ | HMDS | none | none | (CH₃)₃Si—NHCOCF₃ | (CH₃)₃Si—OCOCF₃ | 10.0 | HMDS | 0.5 |
| Ex. 9-1 | none | none | HMDS | (CF₃CO)₂O | none | (CH₃)₃Si—OCOCF₃ | 10.0 | HMDS | 0.5 |
| Ex. 9-6 | (CH₃)₃Si—OCOCF₃ | HMDS | none | none | none | (CH₃)₃Si—OCOCF₃ | 10.0 | HMDS | 0.5 |
| Ex. 21-3 | (CH₃)₃Si—OCOCF₃ | TMSIm | none | none | (CH₃)₃Si—NHCOCF₃ | (CH₃)₃Si—OCOCF₃ | 10.0 | TMSIm | 0.5 |
| Ex. 8-3 | none | TMSIm | HMDS | (CF₃CO)₂O | none | (CH₃)₃Si—OCOCF₃ | 10.0 | TMSIm | 0.5 |
| Ex. 9-7 | (CH₃)₃Si—OCOCF₃ | TMSIm | none | none | none | (CH₃)₃Si—OCOCF₃ | 10.0 | TMSIm | 0.5 |

| | Protective Film-Forming Chemical Liquid | | | | | | | |
|---|---|---|---|---|---|---|---|---|
| | Composition after Liquid Preparation | | | | | Contact Angle Reflection Rate | | |
| | | | | (II) | | after Surface Treat. | | |
| | | | (I) | Second | | Amount | Amount | Amount |
| | Amide Compound | | First | Solvent | | of Water | of Water | of water |
| | | Conc. | Solvent | | Conc. | 0.0 | 0.1 | 0.2 |
| | Kind | [mass %] | Kind | Kind | [mass %] | mass % | mass % | mass % |
| Ex. 21-1 | (CH₃)₃Si—NHCOCF₃ | 10.0 | DiAE | TPGDME | 10.0 | 100 | 100 | 100 |
| Ex. 1-4 | (CH₃)₃Si—NHCOCF₃ | 10.0 | DiAE | TPGDME | 10.0 | 100 | 100 | 100 |
| Ex. 4-5 | none | 0.0 | DiAE | TPGDME | 10.0 | 100 | 50 | 39 |
| Ex. 21-2 | (CH₃)₃Si—NHCOCF₃ | 10.0 | isododedane | TPGDME | 10.0 | 100 | 100 | 100 |
| Ex. 9-1 | (CH₃)₃Si—NHCOCF₃ | 10.0 | isododedane | TPGDME | 10.0 | 100 | 100 | 100 |
| Ex. 9-6 | none | 0.0 | isododedane | TPGDME | 10.0 | 100 | 51 | 40 |
| Ex. 21-3 | (CH₃)₃Si—NHCOCF₃ | 10.0 | isododedane | TPGDME | 10.0 | 100 | 100 | 100 |
| Ex. 8-3 | (CH₃)₃Si—NHCOCF₃ | 10.0 | isododedane | TPGDME | 10.0 | 100 | 100 | 100 |
| Ex. 9-7 | none | 0.0 | isododedane | TPGDME | 10.0 | 100 | 52 | 41 |

### Example 21-2

A protective film-forming chemical liquid was prepared in the same manner as in Example 21-1, except that the first solvent was changed to isododecane. Using this chemical liquid, the evaluation of the contact angle retention rate after the surface treatment was made in the same manner as in Example 21-1.

The protective film-forming chemical liquid of Example 9-1 was prepared through the reaction of the starting raw materials: HMDS and trifluoroacetic anhydride as mentioned above, and contained not only 10.0 g of trimethylsilyl trifluoroacetate as the silylation agent and 0.5 g of HMDS as the base, but also 10.0 g of N-trimethylsilyl trifluoroacetamide ((CH₃)₃SiN(H)COCF₃) as the amide compound by-produced during the reaction. Using this protective film-forming chemical liquid of Example 9-1, the evaluation of the contact angle retention rate after the surface treatment was made in the same manner as in Example 21-1.

Using, as a reference example, the protective film-forming chemical liquid of Example 9-6 which contained trimethylsilyl trifluoroacetate as the silylation agent, HMDS as the base and no amide compound, the evaluation of the contact angle retention rate after the surface treatment was also made in the same manner as in Example 21-1.

The results are shown in TABLE 21 and FIG. 6.

As is apparent from the above results, it is preferable that the amide compound represented by the general formula [9] is contained in the chemical liquid according to the present invention even in the case where the kind of the first solvent is changed because the chemical liquid with such an amide compound can easily maintain its water repellency imparting effect even when water is mixed into the chemical liquid.

### Example 21-3

A protective film-forming chemical liquid was prepared in the same manner as in Example 21-2, except that the base was changed to TMSIm. Using this chemical liquid, the evaluation of the contact angle retention rate after the surface treatment was made in the same manner as in Example 21-1.

The protective film-forming chemical liquid of Example 8-3 was prepared through the reaction of the starting raw materials: HMDS and trifluoroacetic anhydride as mentioned above, and contained not only 10.0 g of trimethylsilyl trifluoroacetate as the silylation agent and 0.5 g of TMSIm as the base, but also 10.0 g of N-trimethylsilyl trifluoroacetamide ((CH₃)₃SiN(H)COCF₃) as the amide compound by-produced during the reaction. Using this protective film-forming chemical liquid of Example 8-3, the evaluation of the contact angle retention rate after the surface treatment was made in the same manner as in Example 21-1.

Using, as a reference example, the protective film-forming chemical liquid of Example 9-7 which contained trimethylsilyl trifluoroacetate as the silylation agent, TMSIm as the base and no amide compound, the evaluation of the contact angle retention rate after the surface treatment was also made in the same manner as in Example 21-1.

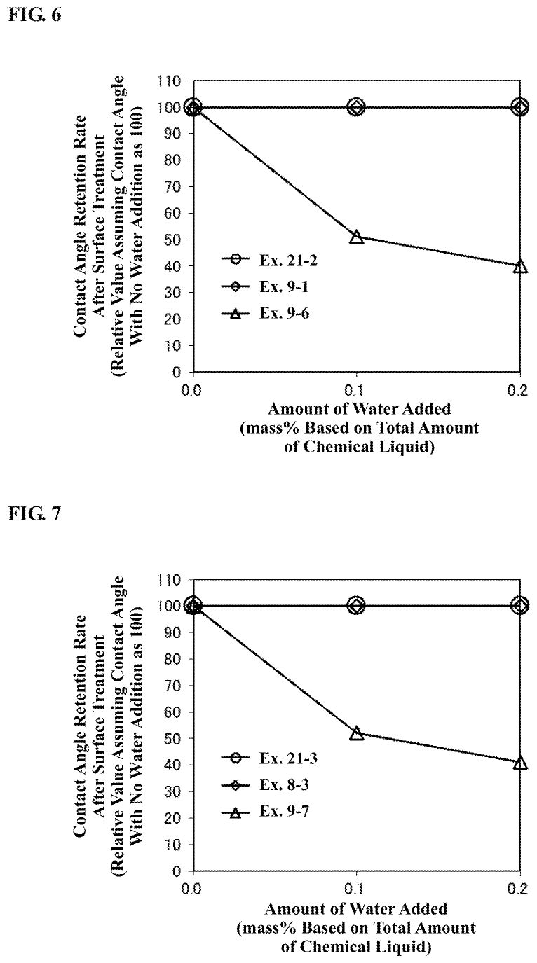

The results are shown in TABLE 21 and FIG. 7.

As is apparent from the above results, it is preferable that the amide compound represented by the general formula [9] is contained in the chemical liquid according to the present invention even in the case where the kind of the base is changed because the chemical liquid with such an amide compound can easily maintain its water repellency imparting effect even when water is mixed into the chemical liquid.

### DESCRIPTION OF REFERENCE NUMERALS

1: Wafer

2: Fine uneven pattern on wafer surface

3: Projection portion of pattern

4: Recess portion of pattern

5: Width of recess portion

6: Height of projection portion

7: Width of projection portion

8: Protective film-forming chemical liquid retained in recess portion 4

9: Liquid retained in recess portion 4

1. A water-repellent protective film-forming chemical liquid used, in a process of cleaning a wafer by means of a wafer cleaning machine, for forming a water-repellent protective film on a surface of the wafer, the wafer having on the surface thereof a fine uneven pattern which at least partially containing a silicon element, the wafer cleaning machine having a liquid contact part which contains a vinyl chloride resin,
the water-repellent protective film-forming chemical liquid comprising:
(I) a first solvent being at least one kind selected from the group consisting of an ether solvent and a hydrocarbon solvent;
(II) a second solvent being a glycol ether;
(III) a silylation agent represented by the following general formula [1]; and
(IV) a base represented by the following general formula [2] and/or the following general formula [3],
wherein a concentration of the second solvent (II) in the chemical liquid is 1 to 30 mass % based on the total amount of the chemical liquid,
wherein a concentration of the silylation agent (III) in the chemical liquid is 2 to 15 mass % based on the total amount of the chemical liquid,
wherein a concentration of the base (IV) in the chemical liquid is 0.05 to 2 mass % based on the total amount of the chemical liquid, and
wherein a mass ratio of the silylation agent (III) to the base (IV) is 4.5 or greater,
(R¹)ₐ(H)_{b}Si(OCOR²)_{4-a-b} [1]
where R¹ is each independently selected from monovalent hydrocarbon groups of 1 to 18 carbon atoms in which a part or all of hydrogen atoms may be substituted with fluorine; R² is an alkyl group of 1 to 6 carbon atoms in which a part or all of hydrogen atoms are substituted with fluorine; a is an integer of 1 to 3; b is an integer of 0 to 2; and the sum of a and b is 1 to 3,
(R³)_{c}(H)_{d}Si(X)_{4-c-d} [2]
where R³ is each independently selected from monovalent hydrocarbon groups of 1 to 18 carbon atoms in which a part or all of hydrogen atoms may be substituted with fluorine; X is an monovalent organic group having a nitrogen atom bonded to silicon; c is an integer of 1 to 3; d is an integer of 0 to 2; the sum of c and d is 1 to 3,
[(R⁴)ₑ(H)_{f}Si]₂NH [3]
where R⁴ is each independently selected from monovalent hydrocarbon groups of 1 to 18 carbon atoms in which a part or all of hydrogen atoms may be substituted with fluorine; e is an integer of 1 to 3; f is an integer of 0 to 2; and the sum of e and f is 3.

2. The water-repellent protective film-forming chemical liquid according to claim 1, wherein the second solvent (II) is a glycol ether represented by the following general formula [4]
R⁵O—(CₘH₂ₘO)ₙ—R⁶ [4]
where R⁵ and R⁶ are each independently selected from alkyl groups of 1 to 4 carbon atoms; m is an integer of 2 to 4; n is an integer of 1 to 4.

3. The water-repellent protective film-forming chemical liquid according to claim 1, wherein the ether solvent used as the first solvent (I) is an ether represented by the following general formula [5]
R⁷—O—R⁸ [5]
where R⁷ and R⁸ are each independently selected from hydrocarbon groups of 1 to 8 carbon atoms; and the total number of carbon atoms in one molecule of the ether is 4 to 16.

4. The water-repellent protective film-forming chemical liquid according to claim 1, wherein the hydrocarbon solvent used as the first solvent (I) is a hydrocarbon of 6 to 14 carbon atoms.

5. The water-repellent protective film-forming chemical liquid according to claim 1, wherein the silylation agent (III) is a silylation agent represented by the following general formula [6]
R⁹Si(CH₃)₂—OCOCₚF₂ₚ₊₁ [6]
where R⁹ is a hydrogen atom, or an alkyl group of 1 to 12 carbon atoms in which a part or all of hydrogen atoms may be substituted with fluorine; and p is an integer of 1 to 6.

6. The water-repellent protective film-forming chemical liquid according to claim 1, wherein X in the general formula [2] is a monovalent cyclic organic group having a nitrogen atom bonded to silicon.

7. The water-repellent protective film-forming chemical liquid according to claim 1, wherein the base (IV) is a base represented by the following general formula [7] and/or the following general formula [8]
R¹⁰Si(CH₃)₂—Y [7]
where R¹⁰ is a hydrogen atom, or an alkyl group of 1 to 12 carbon atoms in which a part or all of hydrogen atoms may be substituted with fluorine; and Y is an imidazole group in which a hydrogen atom may be substituted with methyl, or a pyrrolidyl group,
[R¹¹Si(CH₃)₂]₂NH [8]
where R¹¹ is each independently a hydrogen atom, or an alkyl group of 1 to 12 carbon atoms in which a part or all of hydrogen atoms may be substituted with fluorine.

8. The water-repellent protective film-forming chemical liquid according to claim 1, wherein the concentration of the second solvent (II) in the chemical liquid is 2 to 20 mass % based on the total amount of the chemical liquid.

9. The water-repellent protective film-forming chemical liquid according to claim 1, wherein the concentration of the base (IV) in the chemical liquid is 0.1 to 1.5 mass % based on the total amount of the chemical liquid.

10. The water-repellent protective film-forming chemical liquid according to claim 1, further comprising an amide compound represented by the following general formula [9]
(R¹²)_{g}(H)ₕSi[N(H)—C(═O)—R¹³]_{4-g-h} [9]
where R¹² is each independently selected from hydrocarbon groups of 1 to 18 carbon atoms in which a part or all of hydrogen atoms may be substituted with fluorine; R¹³ is an alkyl group of 1 to 6 carbon atoms in which a part or all of hydrogen atoms are substituted with fluorine; g is an integer of 1 to 3; his an integer of 0 to 2; and the sum of g and h is 1 to 3.

11. A method for cleaning a wafer, comprising: forming a water-repellent protective film by supplying the water-repellent protective film-forming chemical liquid according to claim 1 to a surface of the water and retaining the chemical liquid at least in recess portions of the surface of the wafer.

12. The method for cleaning the wafer according to claim 11, further comprising, after the formation of the water-repellent protective film, remove the water-repellent protective film-forming chemical liquid from the recess portions by drying.

13. The method for cleaning the wafer according to claim 11, further comprising:
after the formation of the water-repellent protective film, replacing the water-repellent protective film-forming chemical liquid in the recess portions with a cleaning liquid which is different from the water-repellent protective film-forming chemical liquid; and
removing the cleaning liquid from the recess portions by drying.

14. The method for cleaning the wafer according to claim 12, further comprising, after the drying, performing at least one treatment selected from the group consisting of heating treatment, light irradiation treatment, ozone exposure treatment, plasma irradiation treatment and corona discharge treatment on the surface of the wafer, thereby removing the water-repellent protective film.

15. The method for cleaning the wafer according to claim 13, further comprising, after the drying, performing at least one treatment selected from the group consisting of heating treatment, light irradiation treatment, ozone exposure treatment, plasma irradiation treatment and corona discharge treatment on the surface of the wafer, thereby removing the water-repellent protective film.
